(19) United States
(12) Patent Application Publication
(10) Pub. No.: US 2024/0423087 A1
(43) Pub. Date: Dec. 19, 2024

(54) COMPOUND AND ORGANIC LIGHT EMITTING DEVICE COMPRISING SAME

(71) Applicant: LG CHEM, LTD., Seoul (KR)

(72) Inventors: Yongbum CHA, Daejeon (KR); Kyunghee KIM, Daejeon (KR); Moung Gon KIM, Daejeon (KR); Woochul LEE, Daejeon (KR); Sunghyun HWANG, Daejeon (KR)

(21) Appl. No.: 18/731,128

(22) Filed: May 31, 2024

(30) Foreign Application Priority Data
Jun. 2, 2023 (KR) 10-2023-0071486

(51) Int. Cl. H10K 85/40; C07F 7/08; C09K 11/06; H10K 50/11; H10K 50/16; H10K 50/17; H10K 50/18; H10K 85/60

(52) U.S. Cl. CPC H10K 85/40; C07F 7/0812; C09K 11/06; H10K 85/654; H10K 85/6572; H10K 85/6574; H10K 85/6576; C07B 2200/05; C09K 2211/1018; H10K 50/11; H10K 50/16; H10K 50/171; H10K 50/18

(57) ABSTRACT

A compound of Chemical Formula 1 and an organic light emitting device including the same:

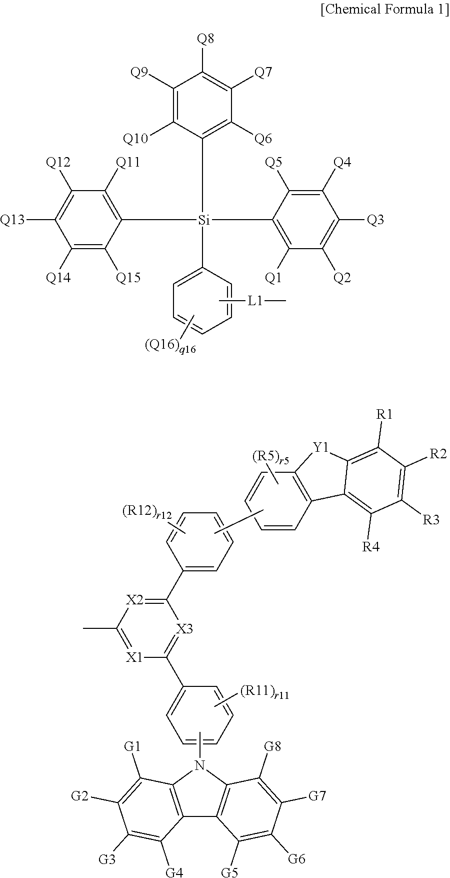

wherein at least one of X1 to X3 is N, and the others are CR13; Y1 is O or S; L1 is a direct bond or a substituted or unsubstituted monocyclic arylene group; R1 to R5, R11 to R13, G1 to G8 and Q1 to Q16 are the same as or different from each other, and are each independently hydrogen or deuterium, and the other substituents are as defined in the specification. When the compound is included in an organic light emitting device, the device exhibits excellent characteristics in terms of efficiency, driving voltage, and stability.

### CROSS-REFERENCE TO RELATED APPLICATIONS

This application claims priority to and the benefit of Korean Patent Application No. 10-2023-0071486 filed in the Korean Intellectual Property Office on Jun. 2, 2023, the entire contents of which are incorporated herein by reference.

### TECHNICAL FIELD

The present specification relates to a compound and an organic light emitting device including the same.

### BACKGROUND ART

An organic light emission phenomenon generally refers to a phenomenon converting electrical energy to light energy using an organic material. An organic light emitting device using an organic light emission phenomenon normally has a structure including a positive electrode, a negative electrode, and an organic material layer therebetween. Here, the organic material layer has in many cases a multi-layered structure composed of different materials in order to improve the efficiency and stability of the organic light emitting device, and for example, may be composed of a hole injection layer, a hole transport layer, a light emitting layer, an electron transport layer, an electron injection layer, and the like. In such a structure of the organic light emitting device, if a voltage is applied between the two electrodes, holes are injected from the positive electrode into the organic material layer and electrons are injected from the negative electrode into the organic material layer, and when the injected holes and electrons meet each other, an exciton is formed, and light is emitted when the exciton falls down again to a ground state.

There is a continuous need for developing a new material for the aforementioned organic light emitting device.

### Related Art Documents

### Patent Document

Korean Patent Application Laid-Open No. 2000-0051826

### SUMMARY OF THE INVENTION

The present invention has been made in an effort to provide a compound and an organic light emitting device including the same.

An exemplary embodiment of the present invention provides a compound of the following Chemical Formula 1.

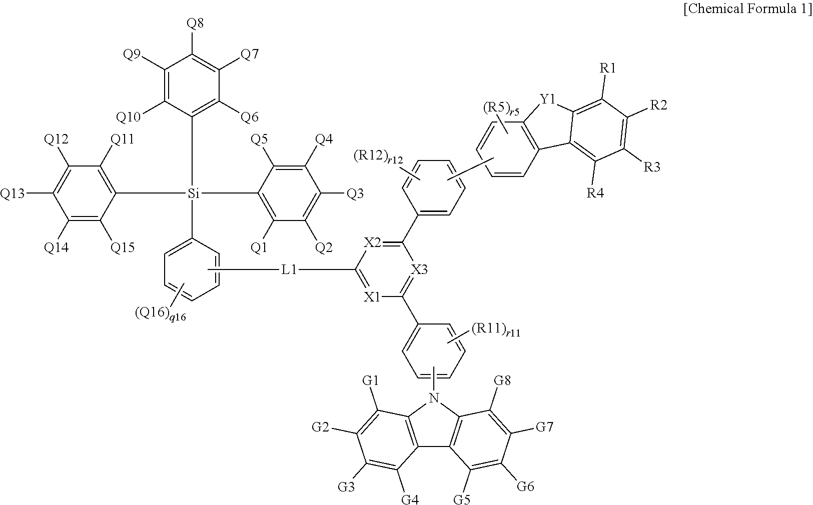

In Chemical Formula 1,
at least one of X1 to X3 is N, and the others are CR13,
Y1 is O or S,
L1 is a direct bond or a substituted or unsubstituted monocyclic arylene group,
R1 to R5, R11 to R13, G1 to G8 and Q1 to Q16 are the same as or different from each other, and are each independently hydrogen or deuterium,
r5 is an integer from 1 to 3, and when r5 is 2 or higher, two or more R5s are the same as or different from each other,
r11 is an integer from 1 to 4, and when r11 is 2 or higher, two or more R11s are the same as or different from each other,
r12 is an integer from 1 to 4, and when r12 is 2 or higher, two or more R12s are the same as or different from each other, and
q16 is an integer from 1 to 4, and when q16 is 2 or higher, two or more Q16's are the same as or different from each other.

Another exemplary embodiment provides an organic light emitting device including: a first electrode; a second electrode; and an organic material layer having one or more layers provided between the first electrode and the second electrode, in which one or more layers of the organic material layer include the above-described compound.

### Advantageous Effects

The compound described in the present specification can be used as a material for an organic material layer of an organic light emitting device. The compound according to at least one exemplary embodiment of the present specification may improve the efficiency, achieve low driving voltage and/or improve service life characteristics in the organic light emitting device. In particular, the compound described in the present specification may be used as a material for a light emitting layer. In addition, the organic light emitting device in which the compound described in the present specification is used has the effects of a low driving voltage, a high efficiency and/or a long service life compared to existing organic light emitting devices.

### BRIEF DESCRIPTION OF THE DRAWINGS

FIGS. 1 and 2 illustrate an example of an organic light emitting device according to an exemplary embodiment of the present specification.

FIG. 3 is an MS graph of Compound A.

### DETAILED DESCRIPTION

Hereinafter, the present specification will be described in more detail.

The present specification provides the compound of Chemical Formula 1.

Chemical formula 1 according to an exemplary embodiment of the present specification is a compound in which a carbazole group is linked through a phenylene group, a dibenzofuran group (or a dibenzothiophene group) is linked through the phenylene group, and a tetraphenylsilane is linked through L1, centered around a N-containing monocyclic heteroaryl group.

The bulky-structured tetraphenylsilane has a structural feature of stabilizing the excited and polaronic states of Chemical Formula 1 above by participating in a conjugation system through the hyperconjugation effect. In addition, the LUMO energy level of a compound may be increased by including a carbazole structure to prevent the host-guest electrostatic bonding state of the organic material layer of an organic light emitting device including the carbazole structure. Therefore, Chemical Formula 1 can be included in an organic material layer of an organic light emitting device to improve the efficiency, lower the driving voltage, and improve the service life characteristics.

Examples of the substituents in the present specification will be described below, but are not limited thereto.

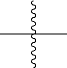

In the present specification, means a moiety to be linked.

The term “substitution” means that a hydrogen atom bonded to a carbon atom of a compound is changed into another substituent, and a position to be substituted is not limited as long as the position is a position at which the hydrogen atom is substituted, that is, a position at which the substituent may be substituted, and when two or more are substituted, the two or more substituents may be the same as or different from each other.

In the present invention, the term “substituted or unsubstituted” means being substituted with one or more substituents selected from the group consisting of deuterium; a halogen group; a cyano group; an alkyl group; a cycloalkyl group; an alkoxy group; an alkenyl group; a haloalkyl group; a silyl group; a boron group; an amine group; an aryl group; a fused ring group of an aromatic hydrocarbon ring and an aliphatic hydrocarbon ring; and a heteroaryl group, being substituted with a substituent to which two or more substituents among the exemplified substituents are linked, or having no substituent.

In the present specification, the fact that two or more substituents are linked indicates that hydrogen of any one substituent is linked to another substituent. For example, when two substituents are linked to each other, a phenyl group and a naphthyl group may be linked to each other to become a substituent of

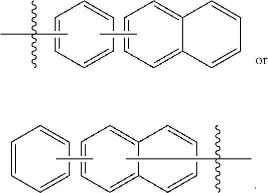

Further, the case where three substituents are linked to one another includes not only a case where (Substituent 1)-(Substituent 2)-(Substituent 3) are consecutively linked to one another, but also a case where (Substituent 2) and (Substituent 3) are linked to (Substituent 1). For example, a phenyl group, a naphthyl group, and an isopropyl group may be linked to one another to become a substituent of

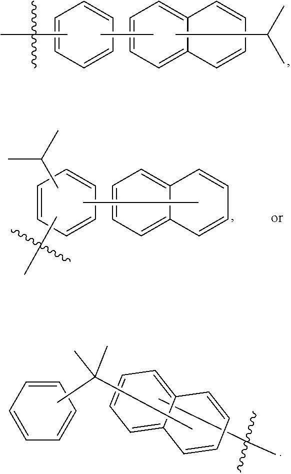

The above-described definition also applies equally to the case where four or more substituents are linked to one another.

In the present specification, examples of a halogen group include a fluoro group, a chloro group, a bromo group or an iodo group.

In the present specification, an alkyl group may be straight-chained or branched, and the number of carbon atoms thereof is not particularly limited, but is preferably 1 to 30. Specific examples thereof include a methyl group, an ethyl group, a propyl group, an n-propyl group, an isopropyl group, a butyl group, an n-butyl group, an isobutyl group, a tert-butyl group, a sec-butyl group, a 1-methyl-butyl group, a 1-ethyl-butyl group, a pentyl group, an n-pentyl group, an isopentyl group, a neopentyl group, a tert-pentyl group, a hexyl group, an n-hexyl group, a 1-methylpentyl group, a 2-methylpentyl group, a 4-methyl-2-pentyl group, a 3,3-dimethylbutyl group, a 2-ethylbutyl group, a heptyl group, an n-heptyl group, a 1-methylhexyl group, a cyclopentylmethyl group, a cyclohexylmethyl group, an octyl group, an n-octyl group, a tert-octyl group, a 1-methylheptyl group, a 2-ethylhexyl group, a 2-propylpentyl group, an n-nonyl group, a 2,2-dimethylheptyl group, a 1-ethyl-propyl group, a 1,1-dimethyl-propyl group, an isohexyl group, a 2-methylpentyl group, a 4-methylhexyl group, a 5-methylhexyl group, and the like, but are not limited thereto.

In the present specification, a cycloalkyl group is not particularly limited, but has preferably 3 to 30 carbon atoms, and specific examples thereof include a cyclopropyl group, a cyclobutyl group, a cyclopentyl group, a 3-methylcyclopentyl group, a 2,3-dimethylcyclopentyl group, a cyclohexyl group, a 3-methylcyclohexyl group, a 4-methylcyclohexyl group, a 2,3-dimethylcyclohexyl group, a 3,4,5-trimethylcyclohexyl group, a 4-tert-butylcyclohexyl group, a cycloheptyl group, a cyclooctyl group, an adamantyl group, and the like, but are not limited thereto.

In the present specification, an alkoxy group may be straight-chained, branched, or cyclic. The number of carbon atoms of the alkoxy group is not particularly limited, but is preferably 1 to 30. Specific examples thereof include a methoxy group, an ethoxy group, an n-propoxy group, an isopropoxy group, an n-butoxy group, an isobutoxy group, a tert-butoxy group, a sec-butoxy group, an n-pentyloxy group, an neopentyloxy group, an isopentyloxy group, an n-hexyloxy group, a 3,3-dimethylbutyloxy group, a 2-ethylbutyloxy group, an n-octyloxy group, an n-nonyloxy group, an n-decyloxy group, a benzyloxy group, a p-methylbenzyloxy group, and the like, but are not limited thereto.

In the present specification, an alkenyl group may be straight-chained or branched, and the number of carbon atoms thereof is not particularly limited, but is preferably 2 to 30. Specific examples thereof include a vinyl group, a 1-propenyl group, an isopropenyl group, a 1-butenyl group, a 2-butenyl group, a 3-butenyl group, a 1-pentenyl group, a 2-pentenyl group, a 3-pentenyl group, a 3-methyl-1-butenyl group, a 1,3-butadienyl group, an allyl group, a 1-phenylvinyl-1-yl group, a 2-phenylvinyl-1-yl group, a 2,2-diphenylvinyl-1-yl group, a 2-phenyl-2-(naphthyl-1-yl) vinyl-1-yl group, a 2,2-bis (diphenyl-1-yl) vinyl-1-yl group, a stilbenyl group, a styrenyl group, and the like, but are not limited thereto.

In the present specification, a haloalkyl group means that at least one halogen group is substituted instead of hydrogen in an alkyl group in the definition of the alkyl group.

In the present specification, an aryl group is not particularly limited, but has preferably 6 to 30 carbon atoms, and the aryl group may be monocyclic or polycyclic.

When the aryl group is a monocyclic aryl group, the number of carbon atoms thereof is not particularly limited, but is preferably 6 to 30. Specific examples of the monocyclic aryl group include a phenyl group, a biphenyl group, a terphenyl group, and the like, but are not limited thereto.

When the aryl group is a polycyclic aryl group, the number of carbon atoms thereof is not particularly limited, but is preferably 10 to 30. Specific examples of the polycyclic aryl group include a naphthyl group, an anthracene group, a phenanthrene group, a triphenylene group, a pyrene group, a phenalene group, a perylene group, a chrysene group, a fluorene group, and the like, but are not limited thereto.

In the present specification, the fluorene group may be substituted, and adjacent groups may be bonded to each other to form a ring.

Examples of the fluorene group include

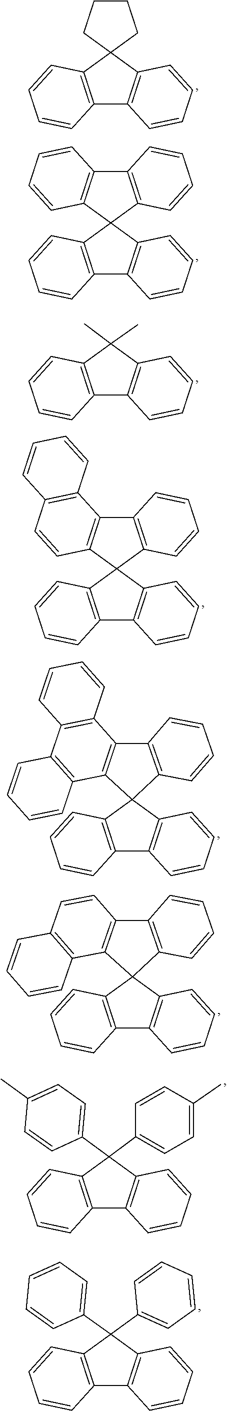

and the like, but are not limited thereto.

In the present specification, an “adjacent” group may mean a substituent substituting an atom directly linked to an atom substituted by the corresponding substituent, a substituent sterically most closely positioned to the corresponding substituent, or another substituent substituting an atom substituted by the corresponding substituent. For example, two substituents substituting ortho positions in a benzene ring, and two substituents substituting the same carbon in an aliphatic ring may be interpreted as groups “adjacent” to each other.

In the present specification, a heteroaryl group includes one or more atoms other than carbon, that is, one or more heteroatoms, and specifically, the heteroatom may include one or more atoms selected from the group consisting of O, N, Se, S, and the like. The number of carbon atoms thereof is not particularly limited, but is preferably 2 to 30, and the heteroaryl group may be monocyclic or polycyclic. Examples of the heteroaryl group include a thiophene group, a furan group, a pyrrole group, an imidazole group, a thiazole group, an oxazole group, an oxadiazole group, a pyridine group, a bipyridine group, a pyrimidine group, a triazine group, a triazole group, an acridine group, a pyridazine group, a pyrazine group, a quinoline group, a quinazoline group, a quinoxaline group, a phthalazine group, a pyridopyrimidine group, a pyridopyrazine group, a pyrazinopyrazine group, an isoquinoline group, an indole group, a carbazole group, a benzoxazole group, a benzimidazole group, a benzothiazole group, a benzocarbazole group, a benzothiophene group, a dibenzothiophene group, a benzofuran group, a phenanthridine group, a phenanthroline group, an isoxazole group, a thiadiazole group, a dibenzofuran group, a dibenzosilole group, a phenoxathiine group, a phenoxazine group, a phenothiazine group, a dihydroindenocarbazole group, a spirofluorenexanthene group, a spirofluorenethioxanthene group, and the like, but are not limited thereto.

In the present specification, a silyl group may be an alkylsilyl group, an arylsilyl group, a heteroarylsilyl group, and the like. The above-described examples of the alkyl group may be applied to the alkyl group in the alkylsilyl group, the above-described examples of the aryl group may be applied to the aryl group in the arylsilyl group, and the examples of the heteroaryl group may be applied to the heteroaryl group in the heteroarylsilyl group.

In the present specification, a boron group may be—BR₁₀₀R₁₀₁, and R₁₀₀ and R₁₀₁ are the same as or different from each other, and may be each independently selected from the group consisting of hydrogen; deuterium; halogen; a nitrile group; a substituted or unsubstituted monocyclic or polycyclic cycloalkyl group having 3 to 30 carbon atoms; a substituted or unsubstituted straight-chained or branched alkyl group having 1 to 30 carbon atoms; a substituted or unsubstituted monocyclic or polycyclic aryl group having 6 to 30 carbon atoms; and a substituted or unsubstituted monocyclic or polycyclic heteroaryl group having 2 to 30 carbon atoms. Specific examples of the boron group include a dimethylboron group, a diethylboron group, a t-butylmethylboron group, a diphenylboron group, and the like, but are not limited thereto.

In the present specification, an amine group may be selected from the group consisting of —NH₂, an alkylamine group, an N-alkylarylamine group, an arylamine group, an N-arylheteroarylamine group, an N-alkylheteroarylamine group, and a heteroarylamine group, and the number of carbon atoms thereof is not particularly limited, but is preferably 1 to 30. Specific examples of the amine group include a methylamine group, a dimethylamine group, an ethylamine group, a diethylamine group, a phenylamine group, a naphthylamine group, a biphenylamine group, an anthracenylamine group, a 9-methyl-anthracenylamine group, a diphenylamine group, a ditolylamine group, an N-phenyltolylamine group, an N-phenylbiphenylamine group, an N-phenylnaphthylamine group, an N-biphenylnaphthylamine group, an N-naphthylfluorenylamine group, an N-phenylphenanthrenylamine group, an N-biphenylphenanthrenylamine group, an N-phenylfluorenylamine group, an N-phenyl terphenylamine group, an N-phenanthrenylfluorenylamine group, an N-biphenylfluorenylamine group, and the like, but are not limited thereto.

In the present specification, an N-alkylarylamine group means an amine group in which an alkyl group and an aryl group are substituted with N of the amine group. The alkyl group and the aryl group in the N-alkylarylamine group are the same as the above-described examples of the alkyl group and the aryl group.

In the present specification, an N-arylheteroarylamine group means an amine group in which an aryl group and a heteroaryl group are substituted with N of the amine group. The aryl group and heteroaryl group in the N-arylheteroarylamine group are the same as the above-described examples of the aryl group and the heteroaryl group.

In the present specification, an N-alkylheteroarylamine group means an amine group in which an alkyl group and a heteroaryl group are substituted with N of the amine group. The alkyl group and the heteroaryl group in the N-alkylheteroarylamine group are the same as the above-described examples of the alkyl group and the heteroaryl group.

In the present specification, examples of an arylamine group include a substituted or unsubstituted monoarylamine group or a substituted or unsubstituted diarylamine group. The arylamine group including two or more aryl groups may include monocyclic aryl groups, polycyclic aryl groups, or both monocyclic aryl groups and polycyclic aryl groups. For example, the aryl group in the arylamine group may be selected from among the examples of the aryl group described above.

In the present specification, examples of a heteroarylamine group include a substituted or unsubstituted monoheteroarylamine group or a substituted or unsubstituted diheteroarylamine group. The heteroarylamine group including two or more heteroaryl groups may include a monocyclic heteroaryl group, a polycyclic heteroaryl group, or both a monocyclic heteroaryl group and a polycyclic heteroaryl group. For example, the heteroaryl group in the heteroarylamine group may be selected from the above-described examples of the heteroaryl group.

In the present specification, a hydrocarbon ring group may be an aromatic hydrocarbon ring group; an aliphatic hydrocarbon ring group; or a fused ring group of an aromatic hydrocarbon ring and an aliphatic hydrocarbon ring, the above-described description on the aryl group is applied to aromatic hydrocarbon ring group, and the above-described description on the cycloalkyl group may be applied to the aliphatic hydrocarbon ring group. Furthermore, a structure in which the above-described aryl group and cycloalkyl group are fused with each other may be applied to the fused ring group of the aromatic hydrocarbon ring and the aliphatic hydrocarbon ring.

In the present specification, an arylene group means a group having two bonding positions in an aryl group, that is, a divalent group. Descriptions on the aryl group provided above may be applied thereto except for each being a divalent group.

Unless otherwise defined in the present specification, all technical and scientific terms used in the present specification have the same meaning as commonly understood by one with ordinary skill in the art to which the present invention pertains. Although methods and materials similar to or equivalent to those described in the present specification may be used in the practice or in the test of exemplary embodiments of the present invention, suitable methods and materials will be described below. All publications, patent applications, patents, and other references mentioned in the present specification are hereby incorporated by reference in their entireties, and in the case of conflict, the present specification, including definitions, will control unless a particular passage is mentioned. Further, the materials, methods, and examples are illustrative only and are not intended to be limiting.

Hereinafter, the compound of Chemical Formula 1 will be described in detail.

According to an exemplary embodiment of the present specification, X1 to X3 are N.

According to an exemplary embodiment of the present specification, X1 and X2 are N, and X3 is CR13.

According to an exemplary embodiment of the present specification, X1 and X3 are N, and X2 is CR13.

According to an exemplary embodiment of the present specification, X2 and X3 are N, and X1 is CR13.

According to an exemplary embodiment of the present specification, X1 is N, and X2 and X3 are each independently CR13.

According to an exemplary embodiment of the present specification, X2 is N, and X1 and X3 are each independently CR13.

According to an exemplary embodiment of the present specification, X3 is N, and X1 and X2 are each independently CR13.

According to an exemplary embodiment of the present specification, Chemical Formula 1 is any one of the following Chemical Formulae 1-1 to 1-7.

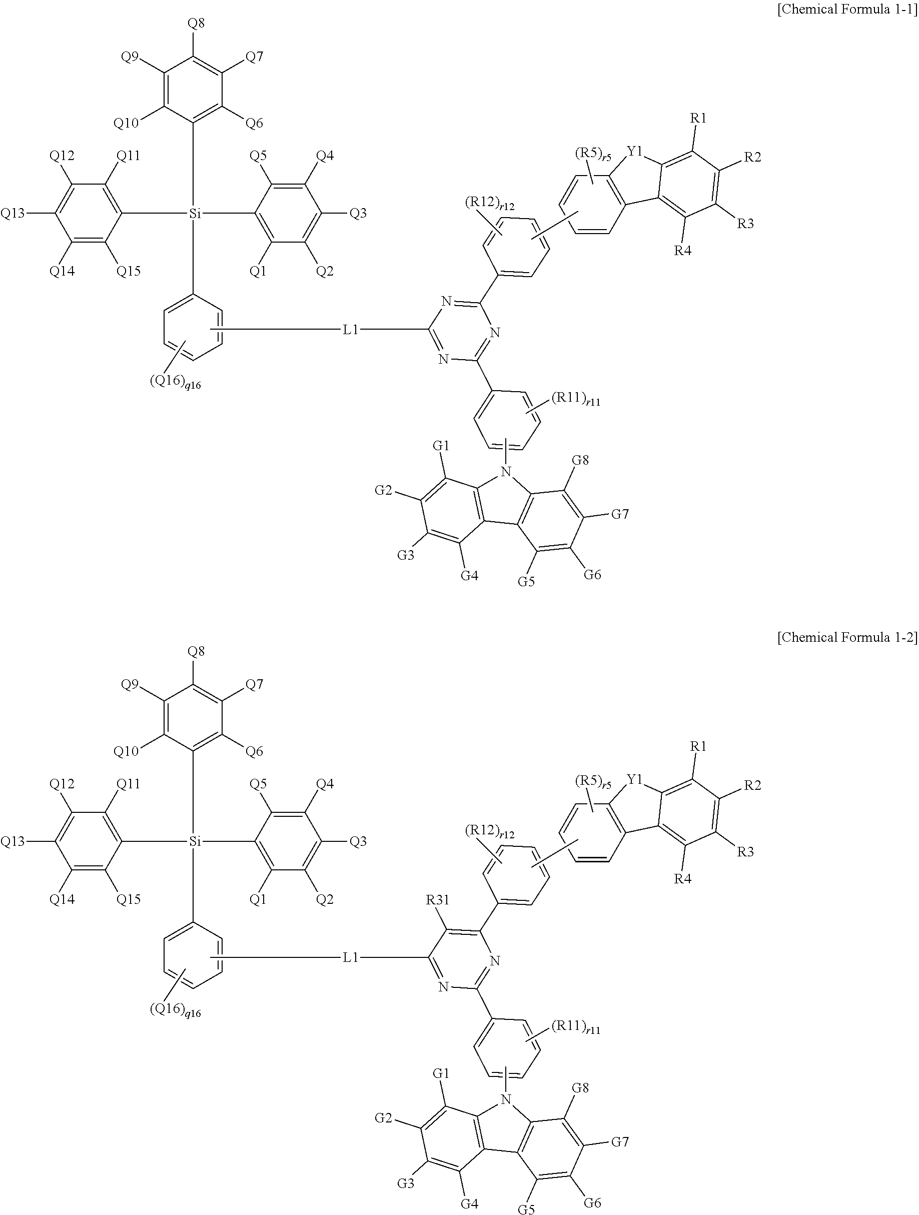

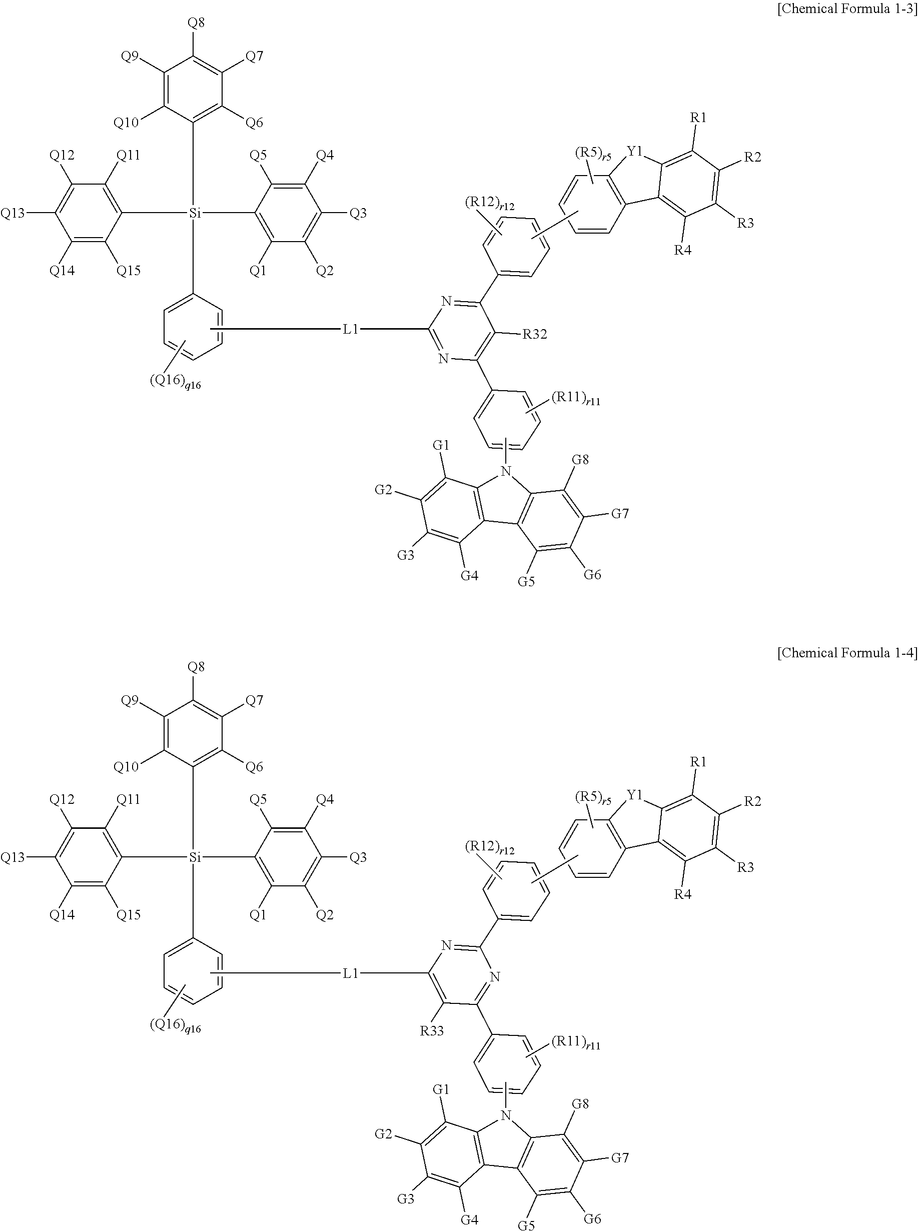

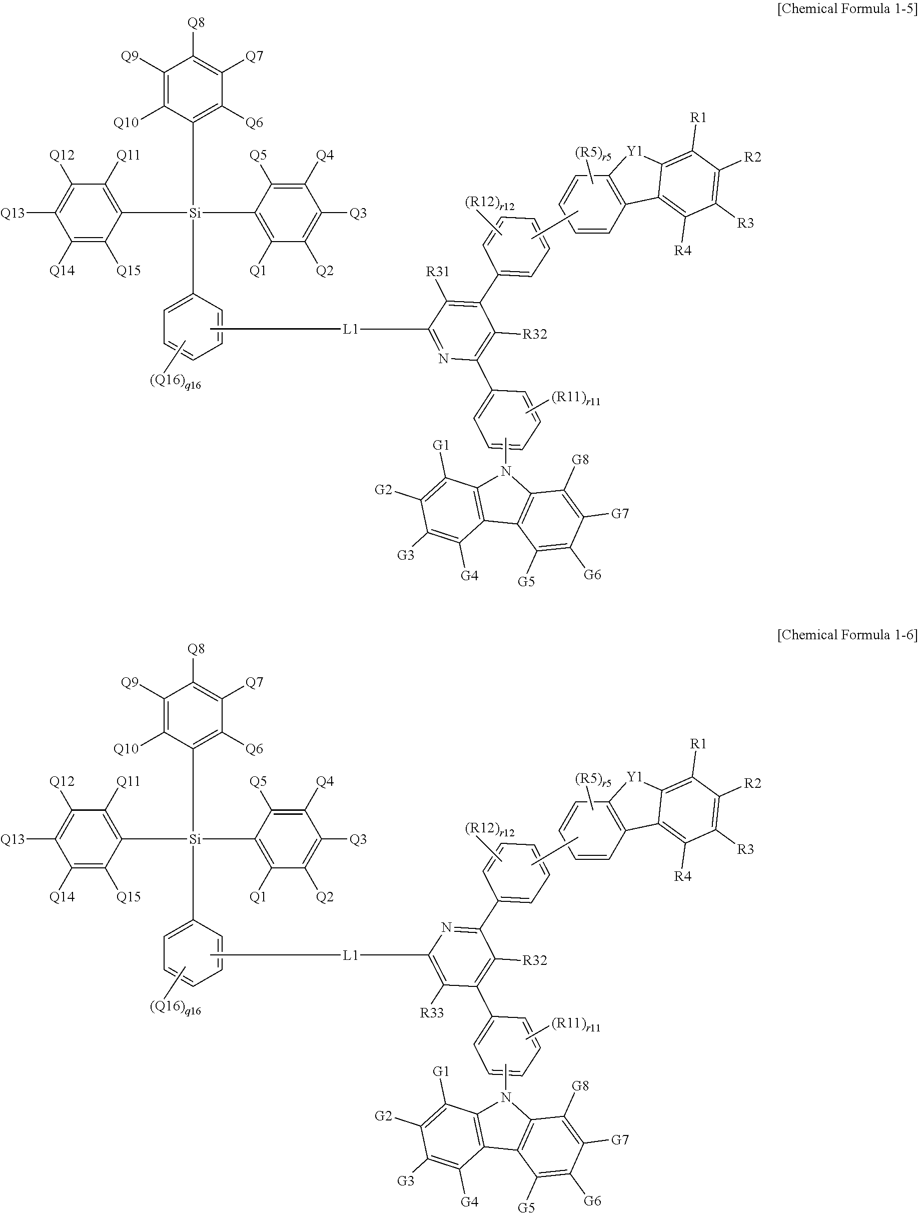

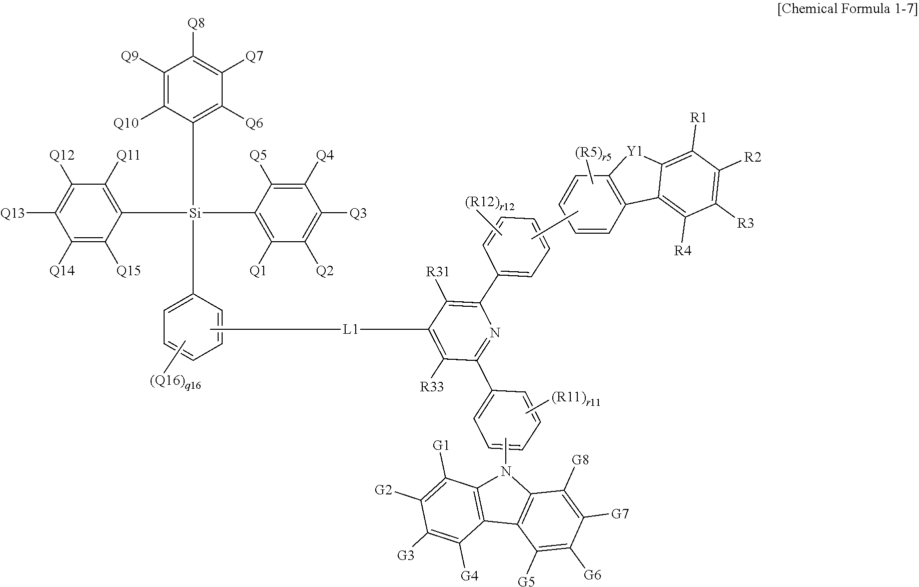

In Chemical Formulae 1-1 to 1-7,
Y1, L1, R1 to R5, R11, R12, G1 to G8, 01 to Q16, r5, r11, r12 and q16 are the same as those defined in Chemical Formula 1, and
R31 to R33 are the same as or different from each other, and are each independently hydrogen; or deuterium.

According to an exemplary embodiment of the present specification, Chemical Formula 1 is the following Chemical Formula 1-8 or 1-9.

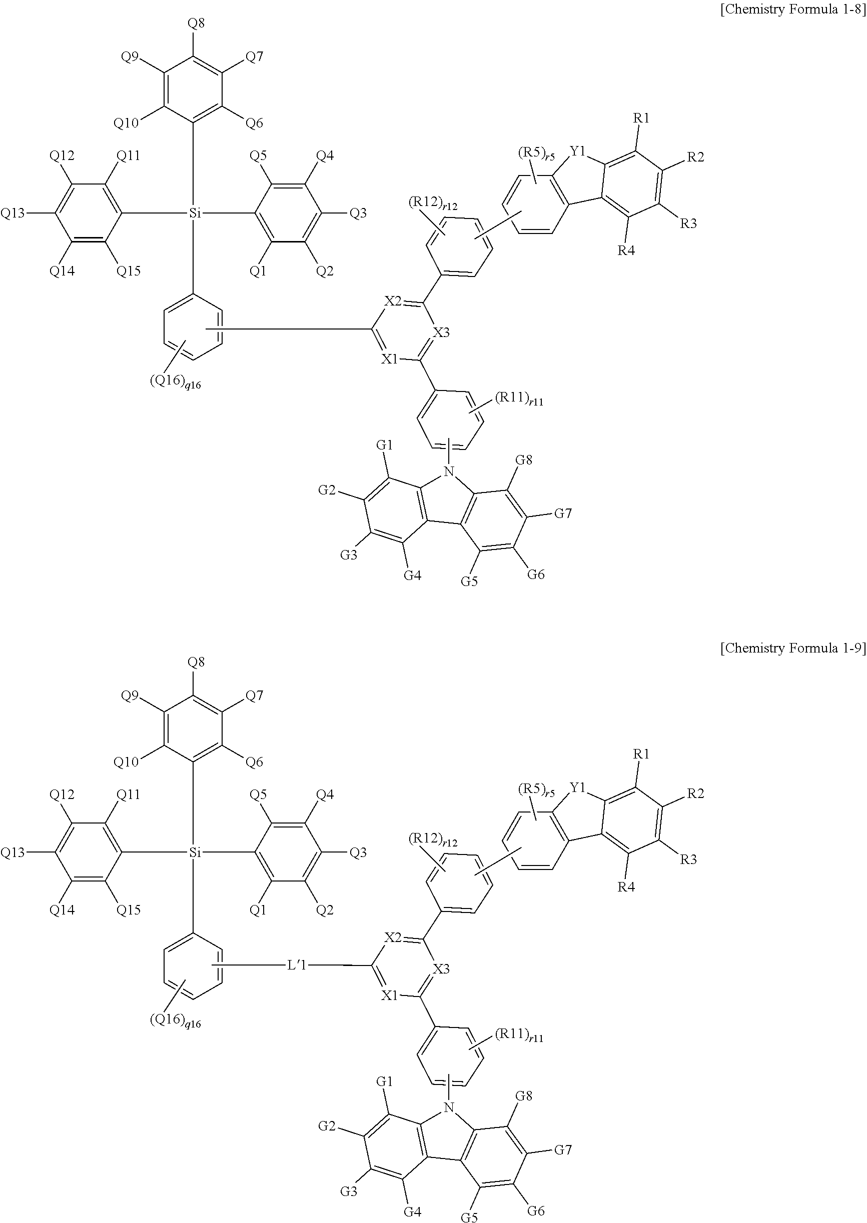

In Chemical Formulae 1-8 and 1-9,
X1 to X3, Y1, R1 to R5, R11, R12, G1 to G8, 01 to 016, r5, r11, r12 and q16 are the same as those defined in Chemical Formula 1, and
L′1 is a substituted or unsubstituted monocyclic arylene group.

According to an exemplary embodiment of the present specification, X1 is O.

According to an exemplary embodiment of the present specification, X1 is S.

According to an exemplary embodiment of the present specification, Chemical Formula 1 is the following Chemical Formula 2 or 3.

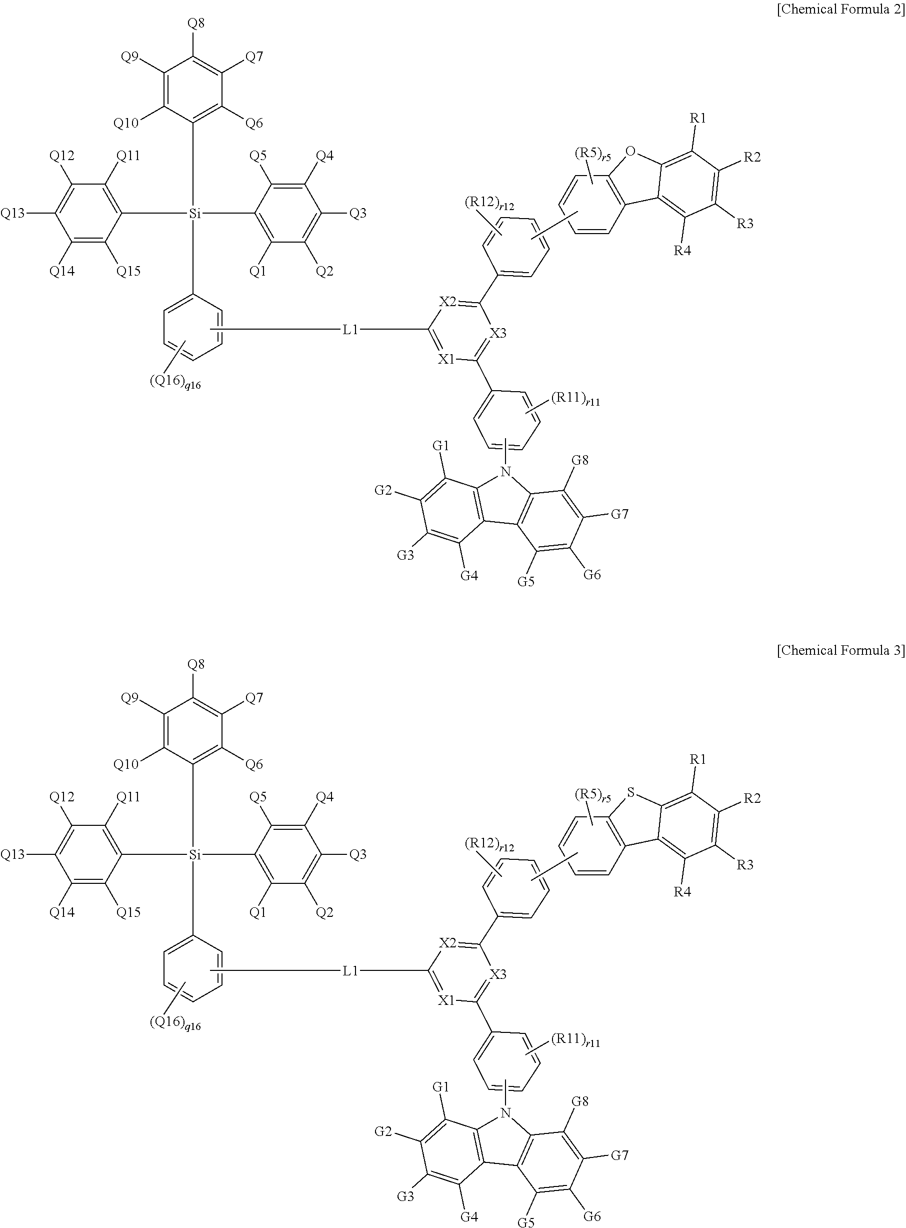

In Chemical Formulae 2 and 3,
L1, X1 to X3, R1 to R5, R11, R12, G1 to G8, Q1 to Q16, r5, r11, r12 and q16 are the same as those defined in Chemical Formula 1.

According to an exemplary embodiment of the present specification, Chemical Formula 1 is any one of Chemical Formulae 1-10 to 1-12.

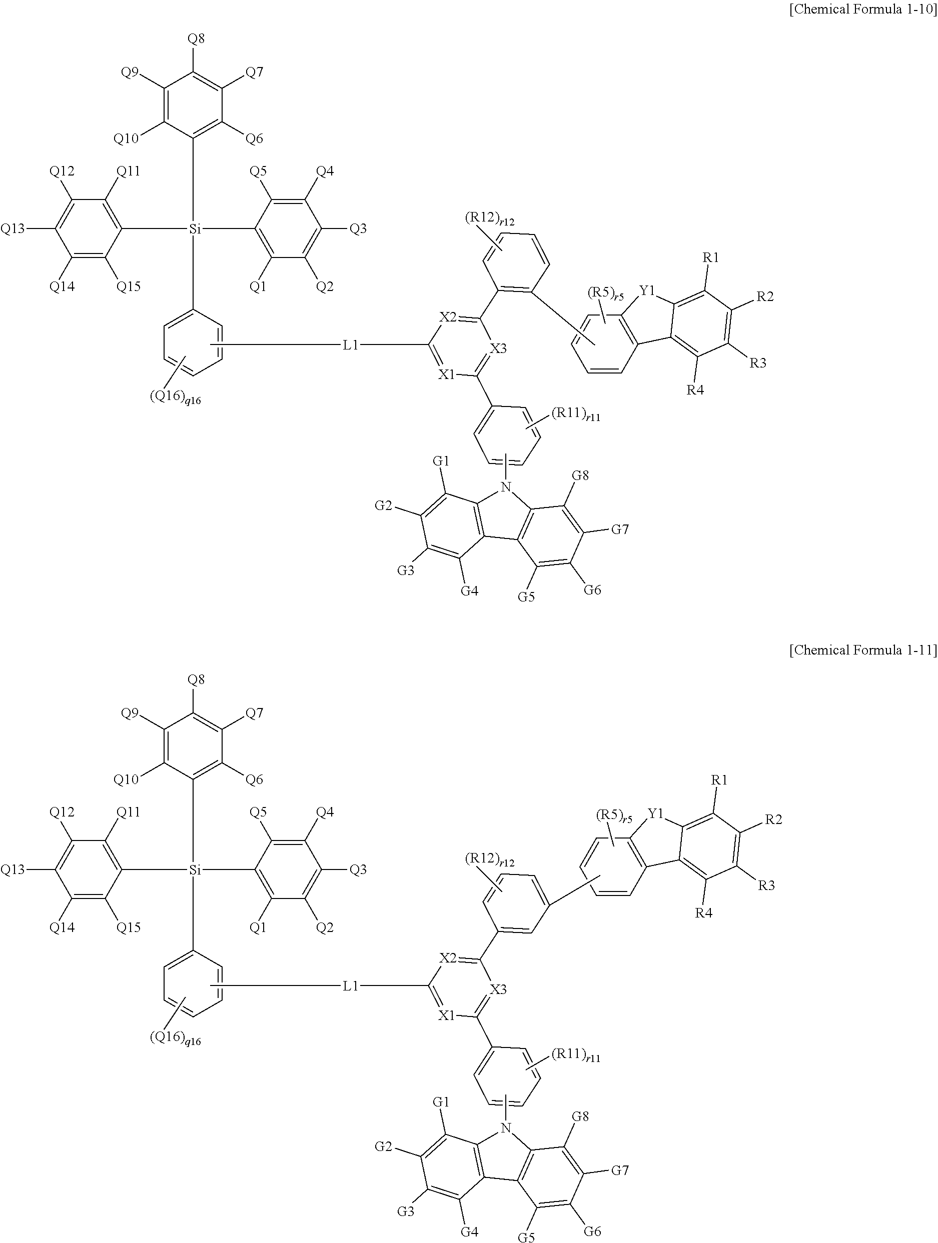

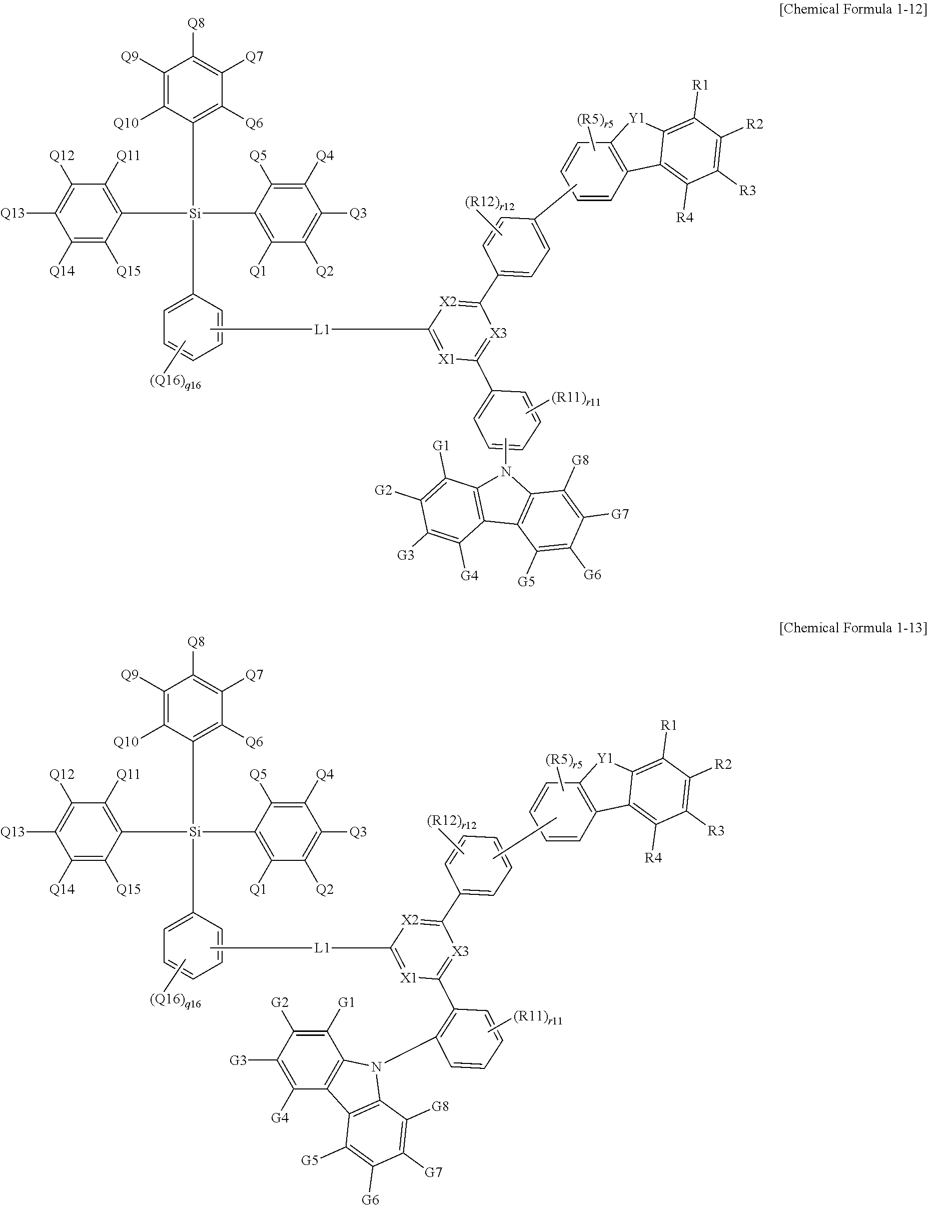

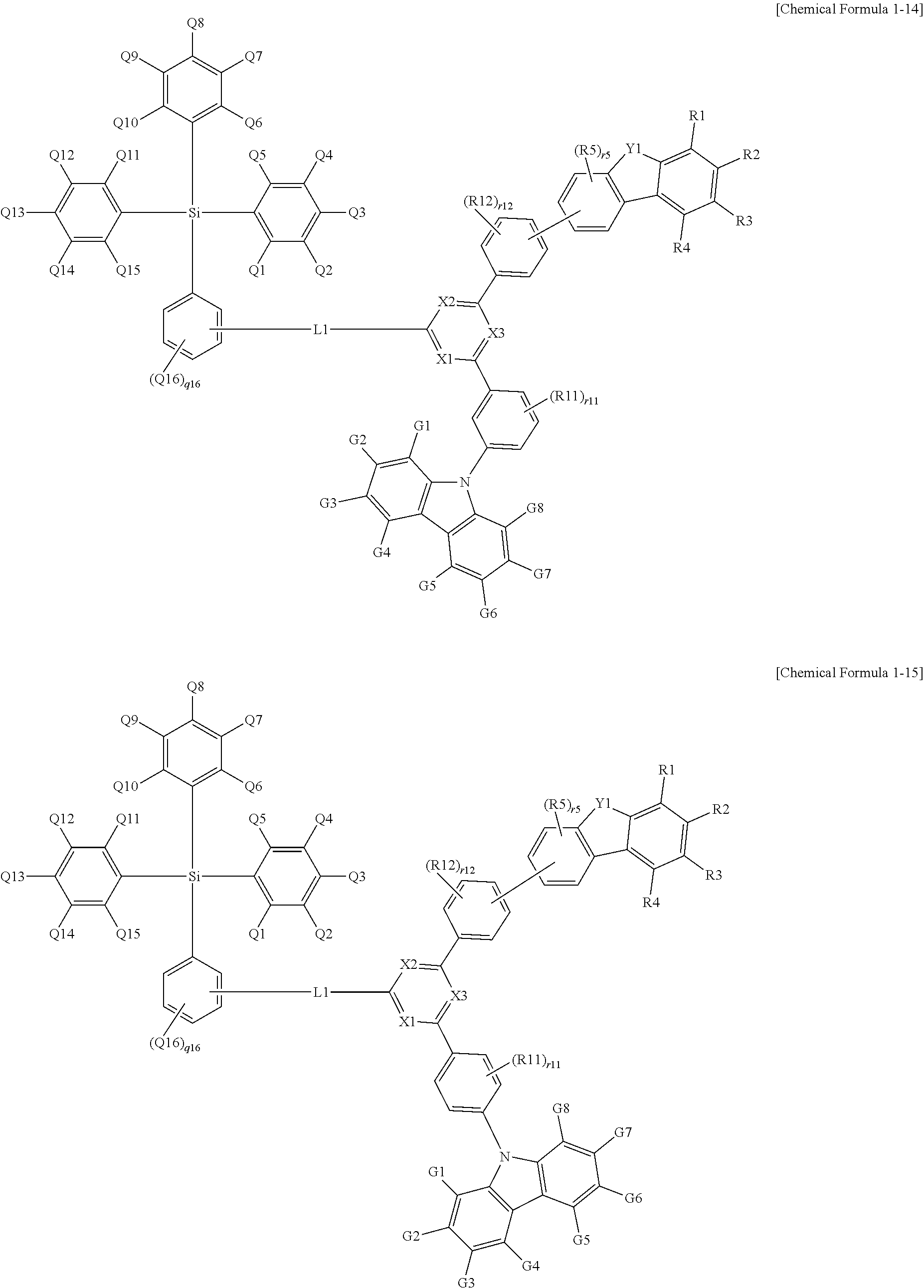

In Chemical Formulae 1-10 to 1-12,
L1, X1 to X3, Y1, R1 to R5, R11, R12, G1 to G8, Q1 to Q16, r5, r11, r12 and q16 are the same as those defined in Chemical Formula 1.

According to an exemplary embodiment of the present specification, Chemical Formula 1 is any one of Chemical Formulae 1-13 to 1-15.

In Chemical Formulae 1-13 to 1-15,
L1, X1 to X3, Y1, R1 to R5, R11, R12, G1 to G8, Q1 to Q16, r5, r11, r12 and q16 are the same as those defined in Chemical Formula 1.

According to an exemplary embodiment of the present specification, Chemical Formula 1 is any one of Chemical Formulae 1-16 to 1-18.

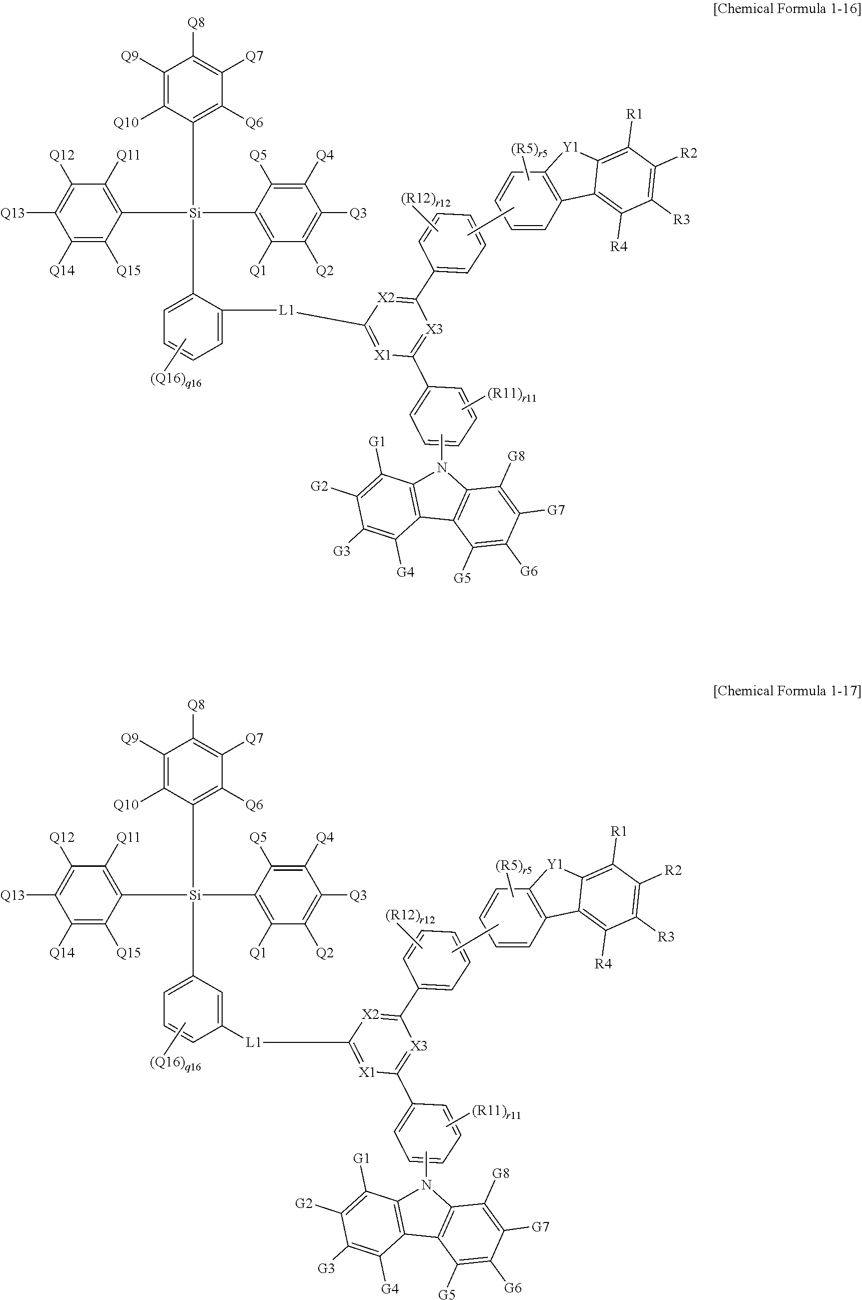

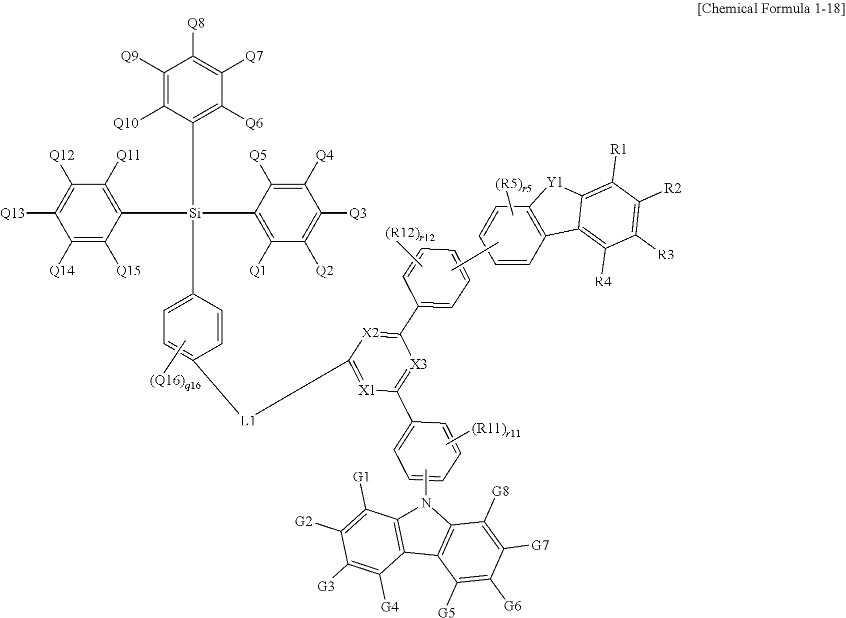

In Chemical Formulae 1-16 to 1-18,
L1, X1 to X3, Y1, R1 to R5, R11, R12, G1 to G8, 01 to Q16, r5, r11, r12 and q16 are the same as those defined in Chemical Formula 1.

According to an exemplary embodiment of the present specification, L1 is a direct bond or a substituted or unsubstituted monocyclic arylene group having 6 to 30 carbon atoms.

According to an exemplary embodiment of the present specification, L1 is a direct bond or a substituted or unsubstituted monocyclic arylene group having 6 to 24 carbon atoms.

According to an exemplary embodiment of the present specification, L1 is a direct bond or a substituted or unsubstituted monocyclic arylene group having 6 to 18 carbon atoms.

According to an exemplary embodiment of the present specification, L1 is a direct bond or a substituted or unsubstituted monocyclic arylene group having 6 to 10 carbon atoms.

According to an exemplary embodiment of the present specification, L1 is a direct bond or a monocyclic arylene group having 6 to 30 carbon atoms, which is unsubstituted or substituted with deuterium.

According to an exemplary embodiment of the present specification, L1 is a direct bond or a monocyclic arylene group having 6 to 24 carbon atoms, which is unsubstituted or substituted with deuterium.

According to an exemplary embodiment of the present specification, L1 is a direct bond or a monocyclic arylene group having 6 to 18 carbon atoms, which is unsubstituted or substituted with deuterium.

According to an exemplary embodiment of the present specification, L1 is a direct bond or a monocyclic arylene group having 6 to 10 carbon atoms, which is unsubstituted or substituted with deuterium.

According to an exemplary embodiment of the present specification, L1 is a direct bond; a phenylene group that is unsubstituted or substituted with deuterium; a biphenylylene group that is unsubstituted or substituted with deuterium; or a divalent terphenyl group that is unsubstituted or substituted with deuterium.

According to an exemplary embodiment of the present specification, L1 is a direct bond.

According to an exemplary embodiment of the present specification, L1 is a phenylene group that is unsubstituted or substituted with deuterium; a biphenylylene group that is unsubstituted or substituted with deuterium; or a divalent terphenyl group that is unsubstituted or substituted with deuterium.

According to an exemplary embodiment of the present specification, L1 is a phenylene group, a biphenylylene group, or a divalent terphenyl group.

According to an exemplary embodiment of the present specification, L′1 is a substituted or unsubstituted monocyclic arylene group having 6 to 30 carbon atoms.

According to an exemplary embodiment of the present specification, L′1 is a substituted or unsubstituted monocyclic arylene group having 6 to 24 carbon atoms.

According to an exemplary embodiment of the present specification, L′1 is a substituted or unsubstituted monocyclic arylene group having 6 to 18 carbon atoms.

According to an exemplary embodiment of the present specification, L′1 is a substituted or unsubstituted monocyclic arylene group having 6 to 12 carbon atoms.

According to an exemplary embodiment of the present specification, L′1 is a monocyclic arylene group having 6 to 30 carbon atoms, which is unsubstituted or substituted with deuterium.

According to an exemplary embodiment of the present specification, L′1 is a monocyclic arylene group having 6 to 24 carbon atoms, which is unsubstituted or substituted with deuterium.

According to an exemplary embodiment of the present specification, L′1 is a monocyclic arylene group having 6 to 18 carbon atoms, which is unsubstituted or substituted with deuterium.

According to an exemplary embodiment of the present specification, L′1 is a monocyclic arylene group having 6 to 12 carbon atoms, which is unsubstituted or substituted with deuterium.

According to an exemplary embodiment of the present specification, L′1 is a phenylene group that is unsubstituted or substituted with deuterium; a biphenylylene group that is unsubstituted or substituted with deuterium; or a divalent terphenyl group that is unsubstituted or substituted with deuterium.

According to an exemplary embodiment of the present specification, L′1 is a phenylene group, a biphenylylene group, or a divalent terphenyl group.

According to an exemplary embodiment of the present specification, L′1 is a phenylene group substituted with deuterium; a biphenylylene group substituted with deuterium; a divalent terphenyl group substituted with deuterium.

According to an exemplary embodiment of the present specification, R1 to R5 are the same as or different from each other, and are each independently hydrogen or deuterium.

According to an exemplary embodiment of the present specification, R1 to R5 are the same as each other.

According to an exemplary embodiment of the present specification, R1 to R5 are different from each other.

According to an exemplary embodiment of the present specification, R1 to R5 are hydrogen.

According to an exemplary embodiment of the present specification, R1 to R5 are deuterium.

According to an exemplary embodiment of the present specification, G1 to G8 are the same as or different from each other, and are each independently hydrogen or deuterium.

According to an exemplary embodiment of the present specification, G1 to G8 are the same as each other.

According to an exemplary embodiment of the present specification, G1 to G8 are different from each other.

According to an exemplary embodiment of the present specification, G1 to G8 are hydrogen.

According to an exemplary embodiment of the present specification, G1 to G8 are deuterium.

According to an exemplary embodiment of the present specification, Q1 to Q16 are the same as or different from each other, and are each independently hydrogen or deuterium.

According to an exemplary embodiment of the present specification, Q1 to Q16 are the same as each other.

According to an exemplary embodiment of the present specification, Q1 to Q16 are different from each other.

According to an exemplary embodiment of the present specification, Q1 to Q16 are hydrogen.

According to an exemplary embodiment of the present specification, Q1 to Q16 are deuterium.

According to an exemplary embodiment of the present specification, R11 is hydrogen or deuterium.

According to an exemplary embodiment of the present specification, R11 is hydrogen.

According to an exemplary embodiment of the present specification, R11 is deuterium.

According to an exemplary embodiment of the present specification, R12 is hydrogen or deuterium.

According to an exemplary embodiment of the present specification, R12 is hydrogen.

According to an exemplary embodiment of the present specification, R12 is deuterium.

According to an exemplary embodiment of the present specification, R13 is hydrogen or deuterium.

According to an exemplary embodiment of the present specification, R13 is hydrogen.

According to an exemplary embodiment of the present specification, R13 is deuterium.

According to an exemplary embodiment of the present specification, R31 to R33 are the same as or different from each other, and are each independently hydrogen or deuterium.

According to an exemplary embodiment of the present specification, R31 to R33 are the same as each other.

According to an exemplary embodiment of the present specification, R31 to R33 are different from each other.

According to an exemplary embodiment of the present specification, R31 to R33 are hydrogen.

According to an exemplary embodiment of the present specification, R31 to R33 are deuterium.

According to an exemplary embodiment of the present specification, r5 is 1.

According to an exemplary embodiment of the present specification, r5 is 2.

According to an exemplary embodiment of the present specification, r5 is 3.

According to an exemplary embodiment of the present specification, q16 is 1.

According to an exemplary embodiment of the present specification, q16 is 2.

According to an exemplary embodiment of the present specification, q16 is 3.

According to an exemplary embodiment of the present specification, q16 is 4.

According to an exemplary embodiment of the present specification, r11 is 1.

According to an exemplary embodiment of the present specification, r11 is 2.

According to an exemplary embodiment of the present specification, r11 is 3.

According to an exemplary embodiment of the present specification, r11 is 4.

According to an exemplary embodiment of the present specification, r12 is 1.

According to an exemplary embodiment of the present specification, r12 is 2.

According to an exemplary embodiment of the present specification, r12 is 3.

According to an exemplary embodiment of the present specification, r12 is 4.

According to an exemplary embodiment of the present specification, Chemical Formula 1 includes at least one deuterium.

According to an exemplary embodiment of the present specification, the “including at least one deuterium” means that one or more of the hydrogens at substitutable positions are substituted with deuterium or with a substituent substituted with deuterium. The substituent includes the substituent defined in “substituted or unsubstituted” above.

According to an exemplary embodiment of the present specification, the deuterium substitution rate of Chemical Formula 1 is 0% to 100%.

According to an exemplary embodiment of the present specification, the deuterium substitution rate of Chemical Formula 1 is 0.01% to 100%.

According to an exemplary embodiment of the present specification, the deuterium substitution rate of Chemical Formula 1 is 0.1% to 100%.

According to an exemplary embodiment of the present specification, the deuterium substitution rate of Chemical Formula 1 is 1% to 100%.

According to an exemplary embodiment of the present specification, the deuterium substitution rate of Chemical Formula 1 is 40% to 99%.

According to an exemplary embodiment of the present specification, when Chemical Formula 1 includes deuterium, there are the following effects. Specifically, the physicochemical properties related to deuterium, such as the chemical bond length, are different from those of hydrogen, the van der Waals radius of deuterium is smaller than that of hydrogen because the stretching amplitude of the C-D bond is smaller than that of the C—H bond, and in general, it can be shown that the C-D bond is shorter and stronger than the C—H bond. Therefore, when hydrogen at a substitutable position in Chemical Formula 1 is substituted with deuterium, the energy of the ground state is reduced and the bond length between deuterium and carbon is shortened, resulting in a reduction in molecular hardcore volume, and accordingly, the electrical polarizability may be reduced, and the thin film volume may be increased by weakening the intermolecular interaction. In addition, these characteristics may have an effect of reducing the crystallinity of the thin film, that is, create an amorphous state, and may be generally effective for increasing the service life and driving characteristics of an organic light emitting device, and the heat resistance may be improved compared to organic light emitting devices in the related art.

In the present specification, “including deuterium, “deuteration” or “deuterated” means that hydrogen at a substitutable position of a compound is substituted with deuterium.

In the present specification, “overdeuterated” means a compound or group in which all hydrogens in the molecule are substituted with deuterium, and has the same meaning as “100% deuterated”.

In the present specification, “X % deuterated”, “X % degree of deuteration”, or “X % deuterium substitution rate” means that X % of the hydrogens at substitutable positions in the corresponding structure are substituted with deuterium. For example, when the corresponding structure is dibenzofuran, the dibenzofuran being “25% deuterated”, “25% degree of deuteration” of the dibenzofuran, or “25% deuterium substitution rate” of the dibenzofuran means that 2 of the 8 hydrogens at the substitutable positions of the dibenzofuran are substituted with deuterium.

In the present specification, the “degree of deuteration” or “deuterium substitution rate” may be confirmed by a known method such as nuclear magnetic resonance spectroscopy (¹H NMR), thin-layer chromatography/mass spectrometry (TLS/MS), or gas chromatography/mass spectrometry (GC/MS).

Specifically, when the “degree of deuteration” or “deuterium substitution rate” is analyzed using nuclear magnetic resonance spectroscopy (¹H NMR), the degree of deuteration or deuterium substitution rate may be calculated from the integral amount of the total peak through the integration ratio on 1H NMR by adding dimethylformamide (DMF) as an internal standard.

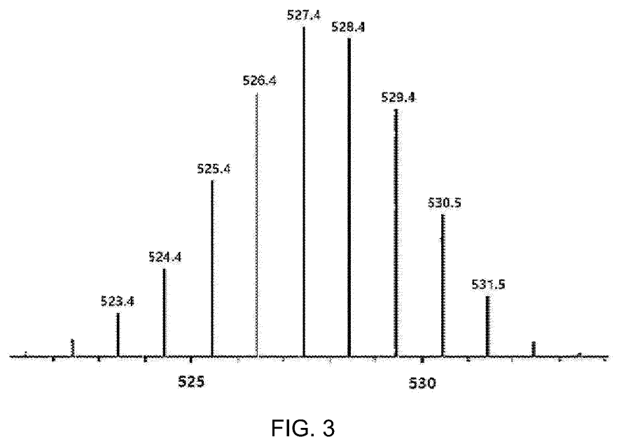

In addition, when the “degree of deuteration” or “deuterium substitution rate” is analyzed by thin-layer chromatography/mass spectrometry (TLS/MS), the substitution rate may be calculated based on the maximum value (median value) of the distribution of molecular weights at the end of the reaction. For example, when the degree of deuteration of the following Compound A is analyzed, the molecular weight of the following starting material is set to 506 and the maximum molecular weight (median value) of the following Compound A is set to 527 in the MS graph of FIG. 3, then it may be calculated that about 81% of the hydrogen has been deuterated because 21 hydrogens of the hydrogens (26 ea) at the substitutable positions in the following starting material have been substituted with deuterium.

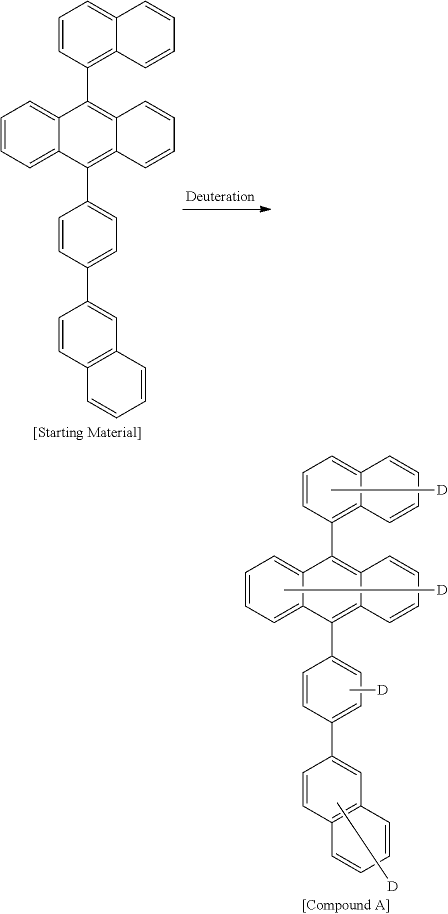

In the present specification, D means deuterium.

According to an exemplary embodiment of the present specification, Chemical Formula 1 is any one of the following compounds.

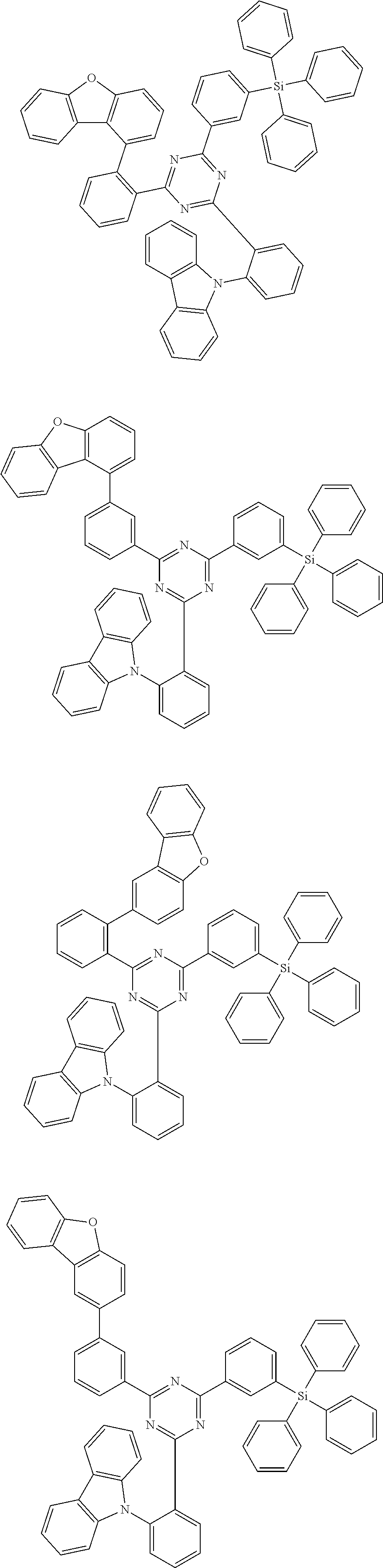 [SMILES: c1ccc([Si](c2ccccc2)(c2ccccc2)c2cccc(-c3nc(-c4ccccc4-c4cccc5oc6ccccc6c45)nc(-c4ccccc4-n4c5ccccc5c5ccccc54)n3)c2)cc1 ; c1ccc([Si](c2ccccc2)(c2ccccc2)c2cccc(-c3nc(-c4cccc(-c5cccc6oc7ccccc7c56)c4)nc(-c4ccccc4-n4c5ccccc5c5ccccc54)n3)c2)cc1 ; c1ccc([Si](c2ccccc2)(c2ccccc2)c2cccc(-c3nc(-c4ccccc4-c4ccc5oc6ccccc6c5c4)nc(-c4ccccc4-n4c5ccccc5c5ccccc54)n3)c2)cc1 ; c1ccc([Si](c2ccccc2)(c2ccccc2)c2cccc(-c3nc(-c4cccc(-c5ccc6oc7ccccc7c6c5)c4)nc(-c4ccccc4-n4c5ccccc5c5ccccc54)n3)c2)cc1]

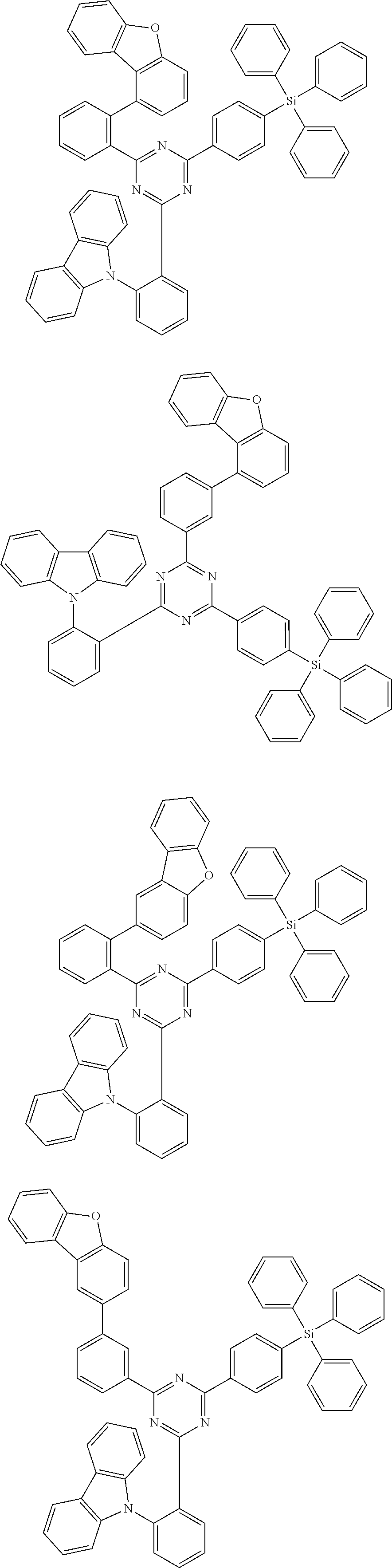 [SMILES: c1ccc([Si](c2ccccc2)(c2ccccc2)c2ccc(-c3nc(-c4ccccc4-c4cccc5oc6ccccc6c45)nc(-c4ccccc4-n4c5ccccc5c5ccccc54)n3)cc2)cc1 ; c1ccc([Si](c2ccccc2)(c2ccccc2)c2ccc(-c3nc(-c4cccc(-c5cccc6oc7ccccc7c56)c4)nc(-c4ccccc4-n4c5ccccc5c5ccccc54)n3)cc2)cc1 ; c1ccc([Si](c2ccccc2)(c2ccccc2)c2ccc(-c3nc(-c4ccccc4-c4ccc5oc6ccccc6c5c4)nc(-c4ccccc4-n4c5ccccc5c5ccccc54)n3)cc2)cc1 ; c1ccc([Si](c2ccccc2)(c2ccccc2)c2ccc(-c3nc(-c4cccc(-c5ccc6oc7ccccc7c6c5)c4)nc(-c4ccccc4-n4c5ccccc5c5ccccc54)n3)cc2)cc1]

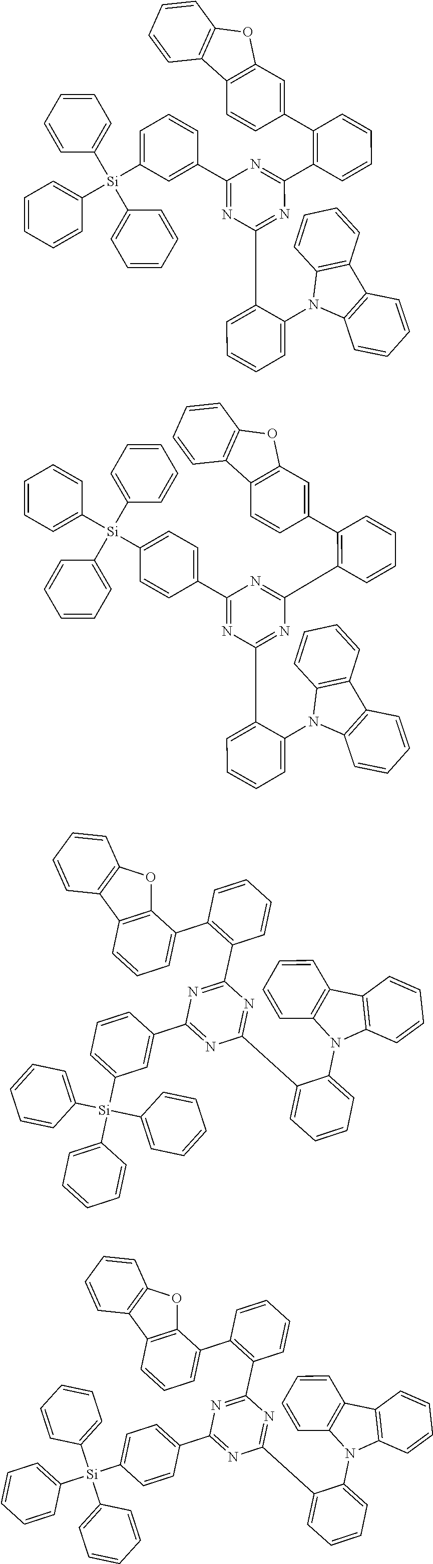 [SMILES: c1ccc([Si](c2ccccc2)(c2ccccc2)c2cccc(-c3nc(-c4ccccc4-c4ccc5c(c4)oc4ccccc45)nc(-c4ccccc4-n4c5ccccc5c5ccccc54)n3)c2)cc1 ; c1ccc([Si](c2ccccc2)(c2ccccc2)c2ccc(-c3nc(-c4ccccc4-c4ccc5c(c4)oc4ccccc45)nc(-c4ccccc4-n4c5ccccc5c5ccccc54)n3)cc2)cc1 ; c1ccc([Si](c2ccccc2)(c2ccccc2)c2cccc(-c3nc(-c4ccccc4-c4cccc5c4oc4ccccc45)nc(-c4ccccc4-n4c5ccccc5c5ccccc54)n3)c2)cc1 ; c1ccc([Si](c2ccccc2)(c2ccccc2)c2ccc(-c3nc(-c4ccccc4-c4cccc5c4oc4ccccc45)nc(-c4ccccc4-n4c5ccccc5c5ccccc54)n3)cc2)cc1]

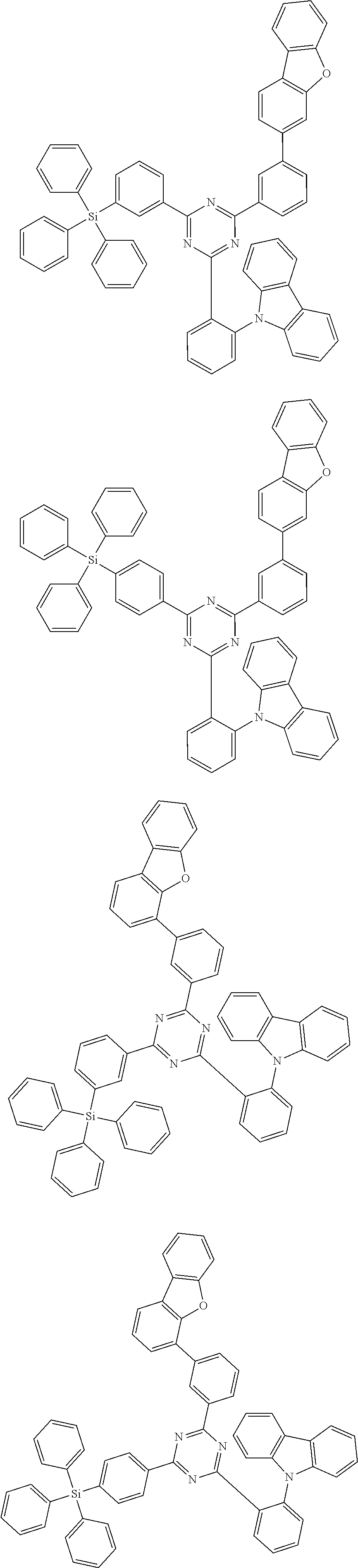 [SMILES: c1ccc([Si](c2ccccc2)(c2ccccc2)c2cccc(-c3nc(-c4cccc(-c5ccc6c(c5)oc5ccccc56)c4)nc(-c4ccccc4-n4c5ccccc5c5ccccc54)n3)c2)cc1 ; c1ccc([Si](c2ccccc2)(c2ccccc2)c2ccc(-c3nc(-c4cccc(-c5ccc6c(c5)oc5ccccc56)c4)nc(-c4ccccc4-n4c5ccccc5c5ccccc54)n3)cc2)cc1 ; c1ccc([Si](c2ccccc2)(c2ccccc2)c2cccc(-c3nc(-c4cccc(-c5cccc6c5oc5ccccc56)c4)nc(-c4ccccc4-n4c5ccccc5c5ccccc54)n3)c2)cc1 ; c1ccc([Si](c2ccccc2)(c2ccccc2)c2ccc(-c3nc(-c4cccc(-c5cccc6c5oc5ccccc56)c4)nc(-c4ccccc4-n4c5ccccc5c5ccccc54)n3)cc2)cc1]

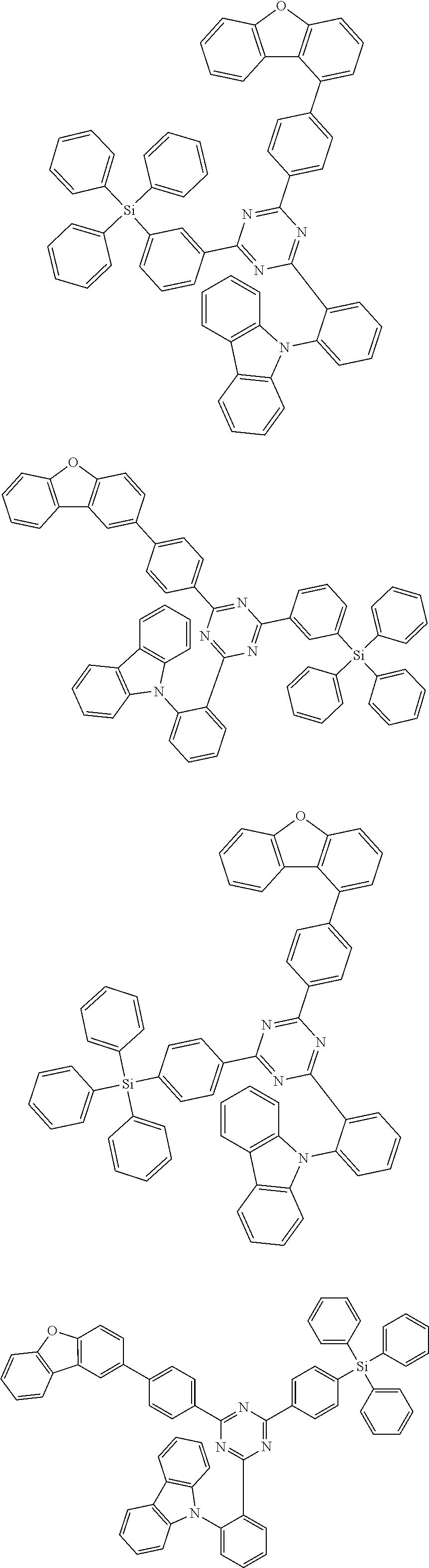 [SMILES: c1ccc([Si](c2ccccc2)(c2ccccc2)c2cccc(-c3nc(-c4ccc(-c5cccc6oc7ccccc7c56)cc4)nc(-c4ccccc4-n4c5ccccc5c5ccccc54)n3)c2)cc1 ; c1ccc([Si](c2ccccc2)(c2ccccc2)c2cccc(-c3nc(-c4ccc(-c5ccc6oc7ccccc7c6c5)cc4)nc(-c4ccccc4-n4c5ccccc5c5ccccc54)n3)c2)cc1 ; c1ccc([Si](c2ccccc2)(c2ccccc2)c2ccc(-c3nc(-c4ccc(-c5cccc6oc7ccccc7c56)cc4)nc(-c4ccccc4-n4c5ccccc5c5ccccc54)n3)cc2)cc1 ; c1ccc([Si](c2ccccc2)(c2ccccc2)c2ccc(-c3nc(-c4ccc(-c5ccc6oc7ccccc7c6c5)cc4)nc(-c4ccccc4-n4c5ccccc5c5ccccc54)n3)cc2)cc1]

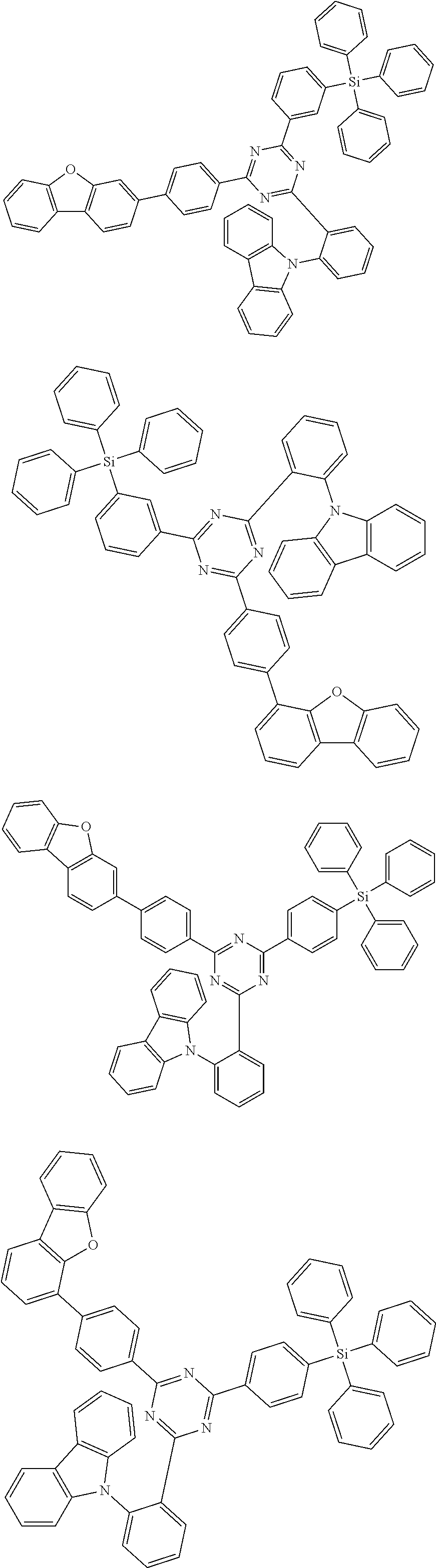 [SMILES: c1ccc([Si](c2ccccc2)(c2ccccc2)c2cccc(-c3nc(-c4ccc(-c5ccc6c(c5)oc5ccccc56)cc4)nc(-c4ccccc4-n4c5ccccc5c5ccccc54)n3)c2)cc1 ; c1ccc([Si](c2ccccc2)(c2ccccc2)c2cccc(-c3nc(-c4ccc(-c5cccc6c5oc5ccccc56)cc4)nc(-c4ccccc4-n4c5ccccc5c5ccccc54)n3)c2)cc1 ; c1ccc([Si](c2ccccc2)(c2ccccc2)c2ccc(-c3nc(-c4ccc(-c5ccc6c(c5)oc5ccccc56)cc4)nc(-c4ccccc4-n4c5ccccc5c5ccccc54)n3)cc2)cc1 ; c1ccc([Si](c2ccccc2)(c2ccccc2)c2ccc(-c3nc(-c4ccc(-c5cccc6c5oc5ccccc56)cc4)nc(-c4ccccc4-n4c5ccccc5c5ccccc54)n3)cc2)cc1]

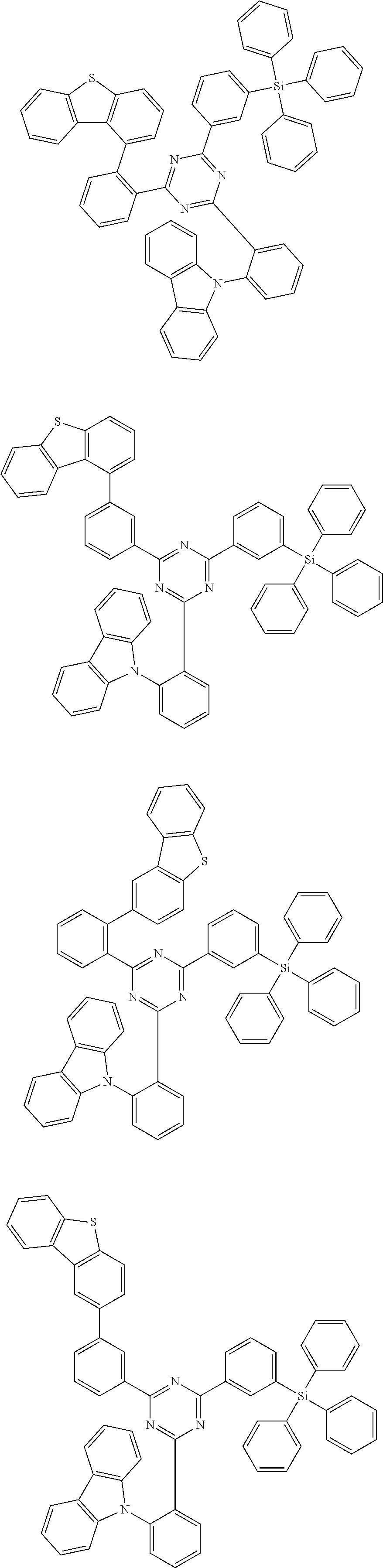 [SMILES: c1ccc([Si](c2ccccc2)(c2ccccc2)c2cccc(-c3nc(-c4ccccc4-c4cccc5sc6ccccc6c45)nc(-c4ccccc4-n4c5ccccc5c5ccccc54)n3)c2)cc1 ; c1ccc([Si](c2ccccc2)(c2ccccc2)c2cccc(-c3nc(-c4cccc(-c5cccc6sc7ccccc7c56)c4)nc(-c4ccccc4-n4c5ccccc5c5ccccc54)n3)c2)cc1 ; c1ccc([Si](c2ccccc2)(c2ccccc2)c2cccc(-c3nc(-c4ccccc4-c4ccc5sc6ccccc6c5c4)nc(-c4ccccc4-n4c5ccccc5c5ccccc54)n3)c2)cc1 ; c1ccc([Si](c2ccccc2)(c2ccccc2)c2cccc(-c3nc(-c4cccc(-c5ccc6sc7ccccc7c6c5)c4)nc(-c4ccccc4-n4c5ccccc5c5ccccc54)n3)c2)cc1]

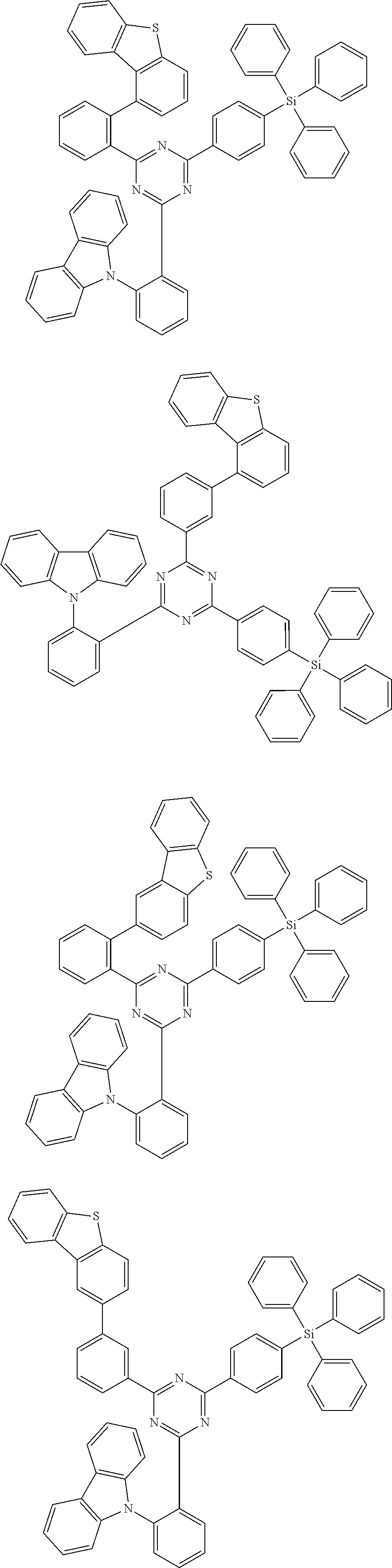 [SMILES: c1ccc([Si](c2ccccc2)(c2ccccc2)c2ccc(-c3nc(-c4ccccc4-c4cccc5sc6ccccc6c45)nc(-c4ccccc4-n4c5ccccc5c5ccccc54)n3)cc2)cc1 ; c1ccc([Si](c2ccccc2)(c2ccccc2)c2ccc(-c3nc(-c4cccc(-c5cccc6sc7ccccc7c56)c4)nc(-c4ccccc4-n4c5ccccc5c5ccccc54)n3)cc2)cc1 ; c1ccc([Si](c2ccccc2)(c2ccccc2)c2ccc(-c3nc(-c4ccccc4-c4ccc5sc6ccccc6c5c4)nc(-c4ccccc4-n4c5ccccc5c5ccccc54)n3)cc2)cc1 ; c1ccc([Si](c2ccccc2)(c2ccccc2)c2ccc(-c3nc(-c4cccc(-c5ccc6sc7ccccc7c6c5)c4)nc(-c4ccccc4-n4c5ccccc5c5ccccc54)n3)cc2)cc1]

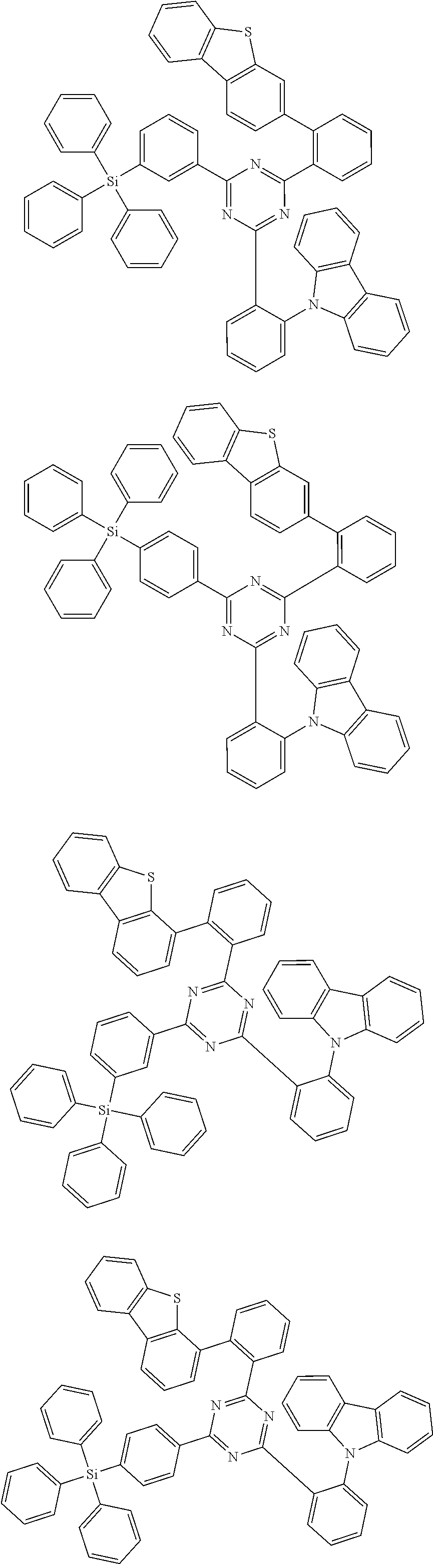 [SMILES: c1ccc([Si](c2ccccc2)(c2ccccc2)c2cccc(-c3nc(-c4ccccc4-c4ccc5c(c4)sc4ccccc45)nc(-c4ccccc4-n4c5ccccc5c5ccccc54)n3)c2)cc1 ; c1ccc([Si](c2ccccc2)(c2ccccc2)c2ccc(-c3nc(-c4ccccc4-c4ccc5c(c4)sc4ccccc45)nc(-c4ccccc4-n4c5ccccc5c5ccccc54)n3)cc2)cc1 ; c1ccc([Si](c2ccccc2)(c2ccccc2)c2cccc(-c3nc(-c4ccccc4-c4cccc5c4sc4ccccc45)nc(-c4ccccc4-n4c5ccccc5c5ccccc54)n3)c2)cc1 ; c1ccc([Si](c2ccccc2)(c2ccccc2)c2ccc(-c3nc(-c4ccccc4-c4cccc5c4sc4ccccc45)nc(-c4ccccc4-n4c5ccccc5c5ccccc54)n3)cc2)cc1]

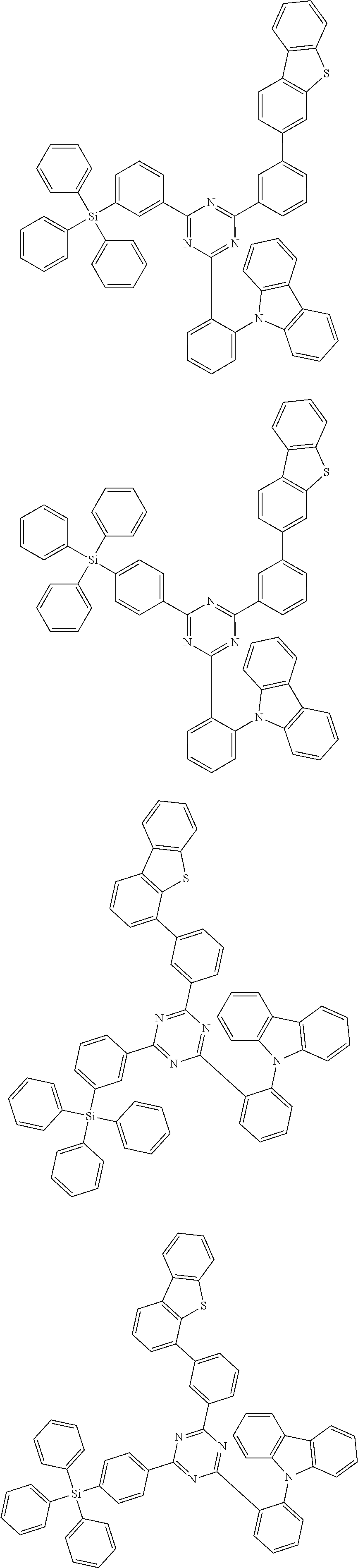 [SMILES: c1ccc([Si](c2ccccc2)(c2ccccc2)c2cccc(-c3nc(-c4cccc(-c5ccc6c(c5)sc5ccccc56)c4)nc(-c4ccccc4-n4c5ccccc5c5ccccc54)n3)c2)cc1 ; c1ccc([Si](c2ccccc2)(c2ccccc2)c2ccc(-c3nc(-c4cccc(-c5ccc6c(c5)sc5ccccc56)c4)nc(-c4ccccc4-n4c5ccccc5c5ccccc54)n3)cc2)cc1 ; c1ccc([Si](c2ccccc2)(c2ccccc2)c2cccc(-c3nc(-c4cccc(-c5cccc6c5sc5ccccc56)c4)nc(-c4ccccc4-n4c5ccccc5c5ccccc54)n3)c2)cc1 ; c1ccc([Si](c2ccccc2)(c2ccccc2)c2ccc(-c3nc(-c4cccc(-c5cccc6c5sc5ccccc56)c4)nc(-c4ccccc4-n4c5ccccc5c5ccccc54)n3)cc2)cc1]

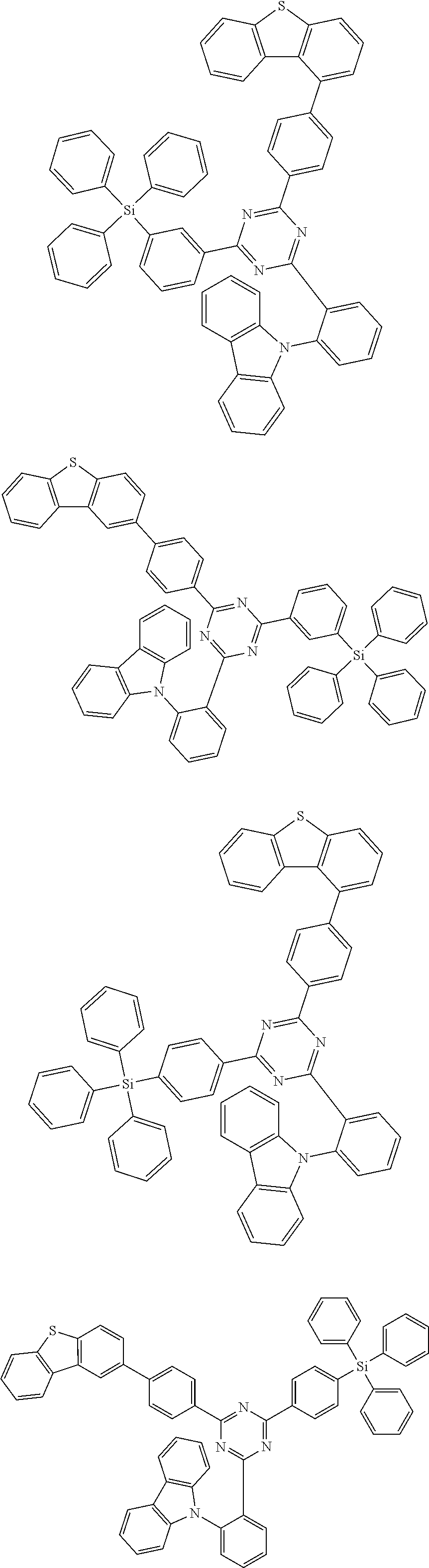 [SMILES: c1ccc([Si](c2ccccc2)(c2ccccc2)c2cccc(-c3nc(-c4ccc(-c5cccc6sc7ccccc7c56)cc4)nc(-c4ccccc4-n4c5ccccc5c5ccccc54)n3)c2)cc1 ; c1ccc([Si](c2ccccc2)(c2ccccc2)c2cccc(-c3nc(-c4ccc(-c5ccc6sc7ccccc7c6c5)cc4)nc(-c4ccccc4-n4c5ccccc5c5ccccc54)n3)c2)cc1 ; c1ccc([Si](c2ccccc2)(c2ccccc2)c2ccc(-c3nc(-c4ccc(-c5cccc6sc7ccccc7c56)cc4)nc(-c4ccccc4-n4c5ccccc5c5ccccc54)n3)cc2)cc1 ; c1ccc([Si](c2ccccc2)(c2ccccc2)c2ccc(-c3nc(-c4ccc(-c5ccc6sc7ccccc7c6c5)cc4)nc(-c4ccccc4-n4c5ccccc5c5ccccc54)n3)cc2)cc1]

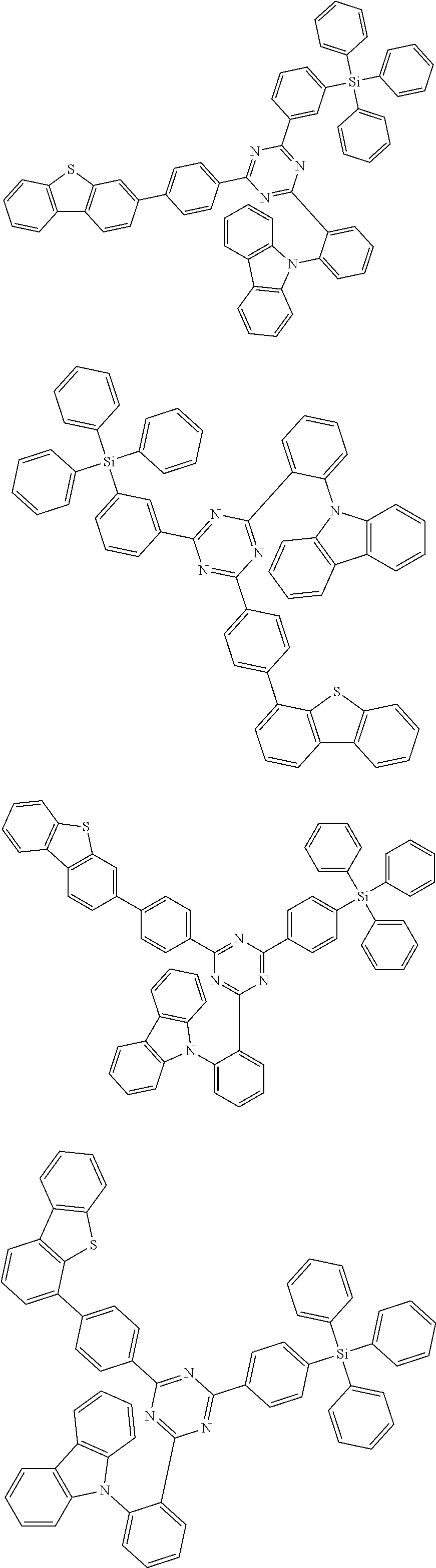 [SMILES: c1ccc([Si](c2ccccc2)(c2ccccc2)c2cccc(-c3nc(-c4ccc(-c5ccc6c(c5)sc5ccccc56)cc4)nc(-c4ccccc4-n4c5ccccc5c5ccccc54)n3)c2)cc1 ; c1ccc([Si](c2ccccc2)(c2ccccc2)c2cccc(-c3nc(-c4ccc(-c5cccc6c5sc5ccccc56)cc4)nc(-c4ccccc4-n4c5ccccc5c5ccccc54)n3)c2)cc1 ; c1ccc([Si](c2ccccc2)(c2ccccc2)c2ccc(-c3nc(-c4ccc(-c5ccc6c(c5)sc5ccccc56)cc4)nc(-c4ccccc4-n4c5ccccc5c5ccccc54)n3)cc2)cc1 ; c1ccc([Si](c2ccccc2)(c2ccccc2)c2ccc(-c3nc(-c4ccc(-c5cccc6c5sc5ccccc56)cc4)nc(-c4ccccc4-n4c5ccccc5c5ccccc54)n3)cc2)cc1]

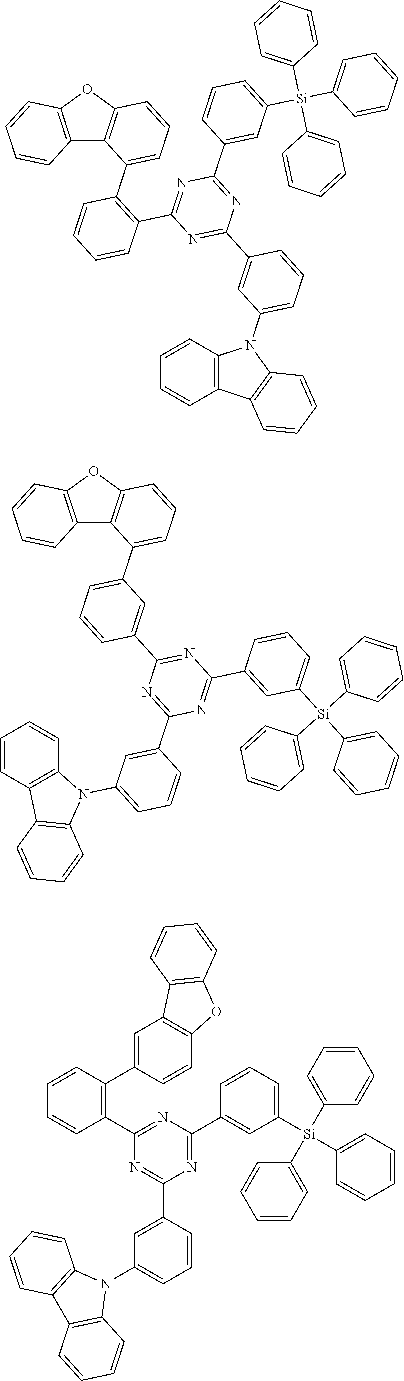 [SMILES: c1ccc([Si](c2ccccc2)(c2ccccc2)c2cccc(-c3nc(-c4cccc(-n5c6ccccc6c6ccccc65)c4)nc(-c4ccccc4-c4cccc5oc6ccccc6c45)n3)c2)cc1 ; c1ccc([Si](c2ccccc2)(c2ccccc2)c2cccc(-c3nc(-c4cccc(-c5cccc6oc7ccccc7c56)c4)nc(-c4cccc(-n5c6ccccc6c6ccccc65)c4)n3)c2)cc1 ; c1ccc([Si](c2ccccc2)(c2ccccc2)c2cccc(-c3nc(-c4cccc(-n5c6ccccc6c6ccccc65)c4)nc(-c4ccccc4-c4ccc5oc6ccccc6c5c4)n3)c2)cc1]

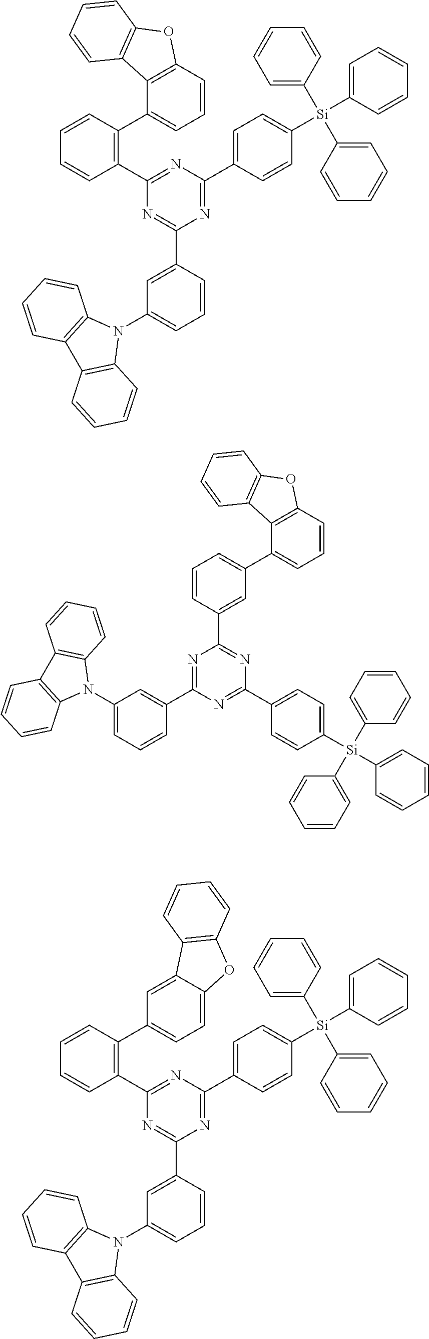 [SMILES: c1ccc([Si](c2ccccc2)(c2ccccc2)c2ccc(-c3nc(-c4cccc(-n5c6ccccc6c6ccccc65)c4)nc(-c4ccccc4-c4cccc5oc6ccccc6c45)n3)cc2)cc1 ; c1ccc([Si](c2ccccc2)(c2ccccc2)c2ccc(-c3nc(-c4cccc(-c5cccc6oc7ccccc7c56)c4)nc(-c4cccc(-n5c6ccccc6c6ccccc65)c4)n3)cc2)cc1 ; c1ccc([Si](c2ccccc2)(c2ccccc2)c2ccc(-c3nc(-c4cccc(-n5c6ccccc6c6ccccc65)c4)nc(-c4ccccc4-c4ccc5oc6ccccc6c5c4)n3)cc2)cc1]

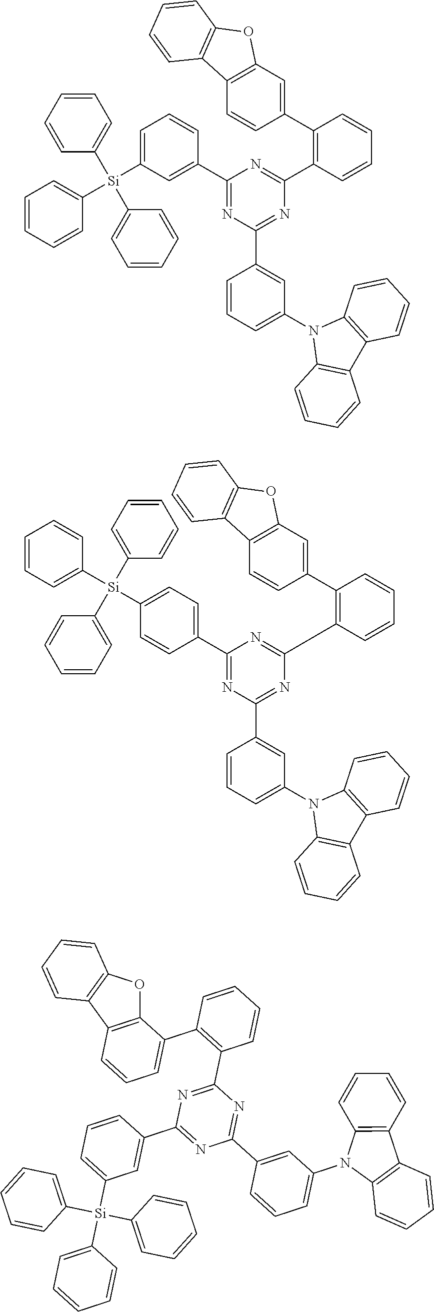 [SMILES: c1ccc([Si](c2ccccc2)(c2ccccc2)c2cccc(-c3nc(-c4cccc(-n5c6ccccc6c6ccccc65)c4)nc(-c4ccccc4-c4ccc5c(c4)oc4ccccc45)n3)c2)cc1 ; c1ccc([Si](c2ccccc2)(c2ccccc2)c2ccc(-c3nc(-c4cccc(-n5c6ccccc6c6ccccc65)c4)nc(-c4ccccc4-c4ccc5c(c4)oc4ccccc45)n3)cc2)cc1 ; c1ccc([Si](c2ccccc2)(c2ccccc2)c2cccc(-c3nc(-c4cccc(-n5c6ccccc6c6ccccc65)c4)nc(-c4ccccc4-c4cccc5c4oc4ccccc45)n3)c2)cc1]

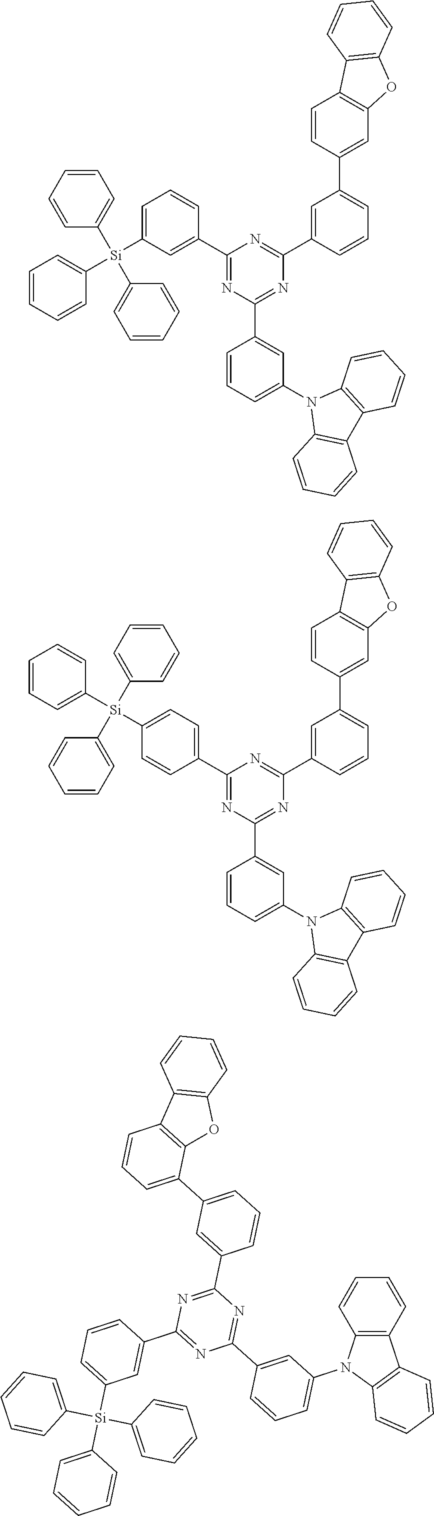

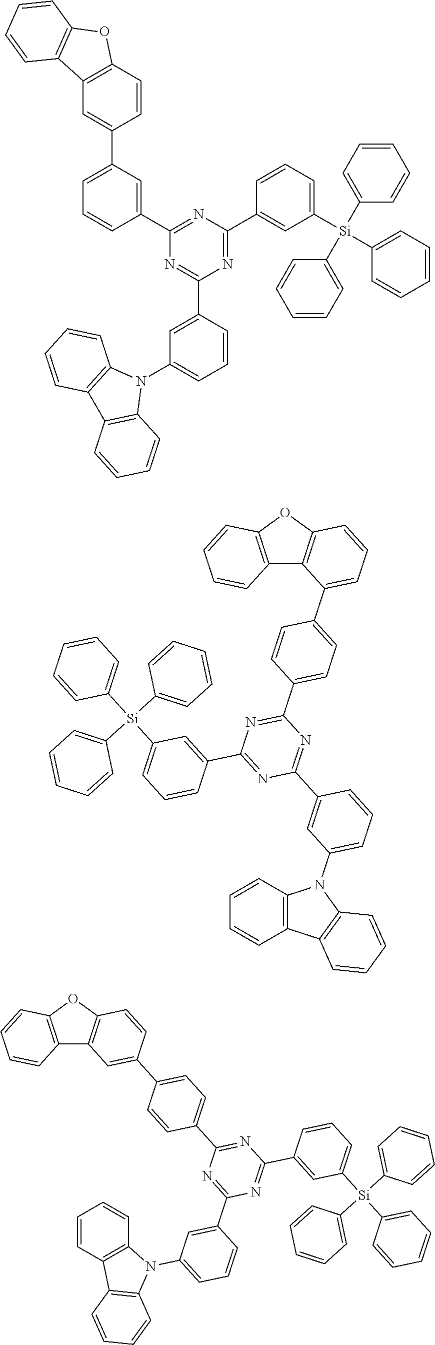 [SMILES: c1ccc([Si](c2ccccc2)(c2ccccc2)c2cccc(-c3nc(-c4cccc(-c5ccc6oc7ccccc7c6c5)c4)nc(-c4cccc(-n5c6ccccc6c6ccccc65)c4)n3)c2)cc1 ; c1ccc([Si](c2ccccc2)(c2ccccc2)c2cccc(-c3nc(-c4ccc(-c5cccc6oc7ccccc7c56)cc4)nc(-c4cccc(-n5c6ccccc6c6ccccc65)c4)n3)c2)cc1 ; c1ccc([Si](c2ccccc2)(c2ccccc2)c2cccc(-c3nc(-c4ccc(-c5ccc6oc7ccccc7c6c5)cc4)nc(-c4cccc(-n5c6ccccc6c6ccccc65)c4)n3)c2)cc1]

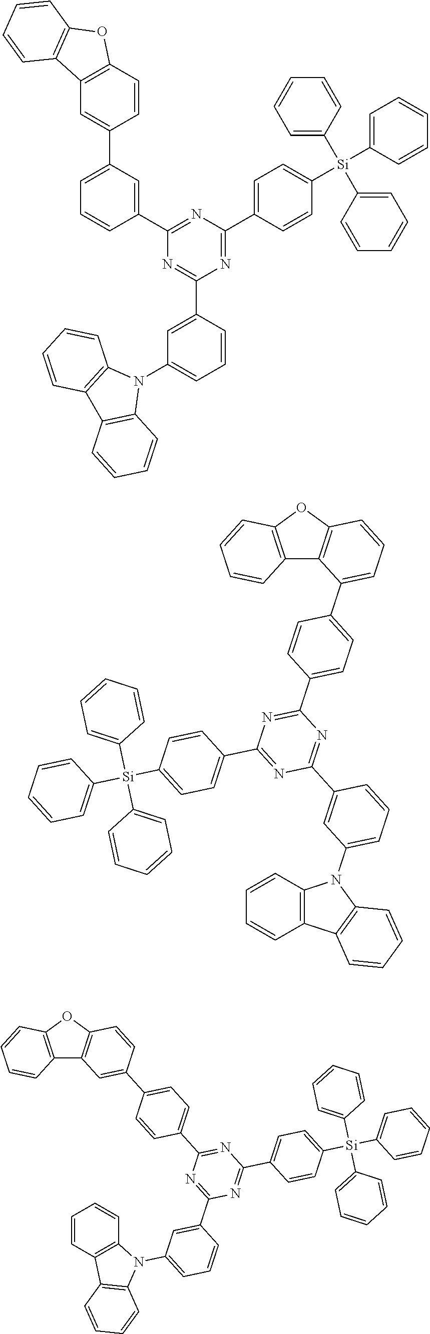 [SMILES: c1ccc([Si](c2ccccc2)(c2ccccc2)c2ccc(-c3nc(-c4cccc(-c5ccc6oc7ccccc7c6c5)c4)nc(-c4cccc(-n5c6ccccc6c6ccccc65)c4)n3)cc2)cc1 ; c1ccc([Si](c2ccccc2)(c2ccccc2)c2ccc(-c3nc(-c4ccc(-c5cccc6oc7ccccc7c56)cc4)nc(-c4cccc(-n5c6ccccc6c6ccccc65)c4)n3)cc2)cc1 ; c1ccc([Si](c2ccccc2)(c2ccccc2)c2ccc(-c3nc(-c4ccc(-c5ccc6oc7ccccc7c6c5)cc4)nc(-c4cccc(-n5c6ccccc6c6ccccc65)c4)n3)cc2)cc1]

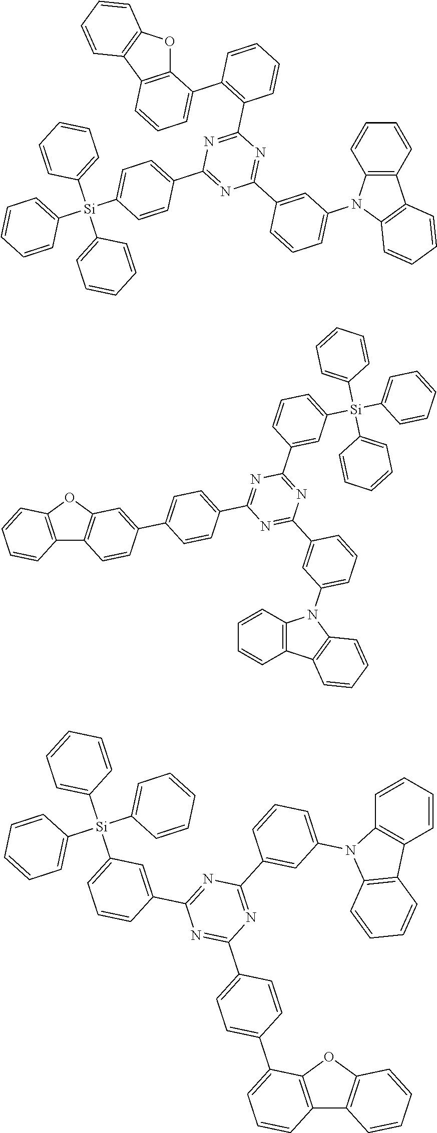 [SMILES: c1ccc([Si](c2ccccc2)(c2ccccc2)c2ccc(-c3nc(-c4cccc(-n5c6ccccc6c6ccccc65)c4)nc(-c4ccccc4-c4cccc5c4oc4ccccc45)n3)cc2)cc1 ; c1ccc([Si](c2ccccc2)(c2ccccc2)c2cccc(-c3nc(-c4ccc(-c5ccc6c(c5)oc5ccccc56)cc4)nc(-c4cccc(-n5c6ccccc6c6ccccc65)c4)n3)c2)cc1 ; c1ccc([Si](c2ccccc2)(c2ccccc2)c2cccc(-c3nc(-c4ccc(-c5cccc6c5oc5ccccc56)cc4)nc(-c4cccc(-n5c6ccccc6c6ccccc65)c4)n3)c2)cc1]

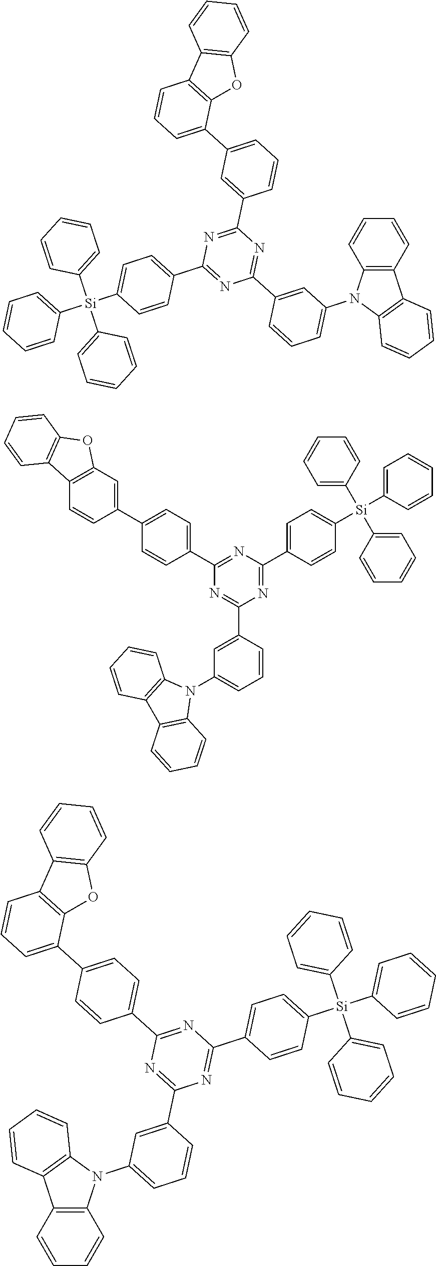 [SMILES: c1ccc([Si](c2ccccc2)(c2ccccc2)c2ccc(-c3nc(-c4cccc(-c5cccc6c5oc5ccccc56)c4)nc(-c4cccc(-n5c6ccccc6c6ccccc65)c4)n3)cc2)cc1 ; c1ccc([Si](c2ccccc2)(c2ccccc2)c2ccc(-c3nc(-c4ccc(-c5ccc6c(c5)oc5ccccc56)cc4)nc(-c4cccc(-n5c6ccccc6c6ccccc65)c4)n3)cc2)cc1 ; c1ccc([Si](c2ccccc2)(c2ccccc2)c2ccc(-c3nc(-c4ccc(-c5cccc6c5oc5ccccc56)cc4)nc(-c4cccc(-n5c6ccccc6c6ccccc65)c4)n3)cc2)cc1]

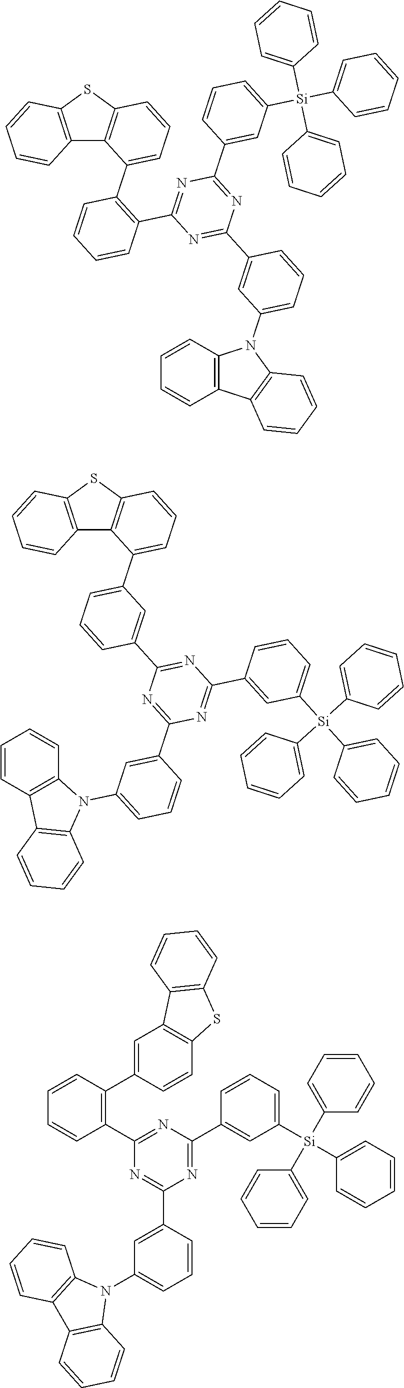 [SMILES: c1ccc([Si](c2ccccc2)(c2ccccc2)c2cccc(-c3nc(-c4cccc(-n5c6ccccc6c6ccccc65)c4)nc(-c4ccccc4-c4cccc5sc6ccccc6c45)n3)c2)cc1 ; c1ccc([Si](c2ccccc2)(c2ccccc2)c2cccc(-c3nc(-c4cccc(-c5cccc6sc7ccccc7c56)c4)nc(-c4cccc(-n5c6ccccc6c6ccccc65)c4)n3)c2)cc1 ; c1ccc([Si](c2ccccc2)(c2ccccc2)c2cccc(-c3nc(-c4cccc(-n5c6ccccc6c6ccccc65)c4)nc(-c4ccccc4-c4ccc5sc6ccccc6c5c4)n3)c2)cc1]

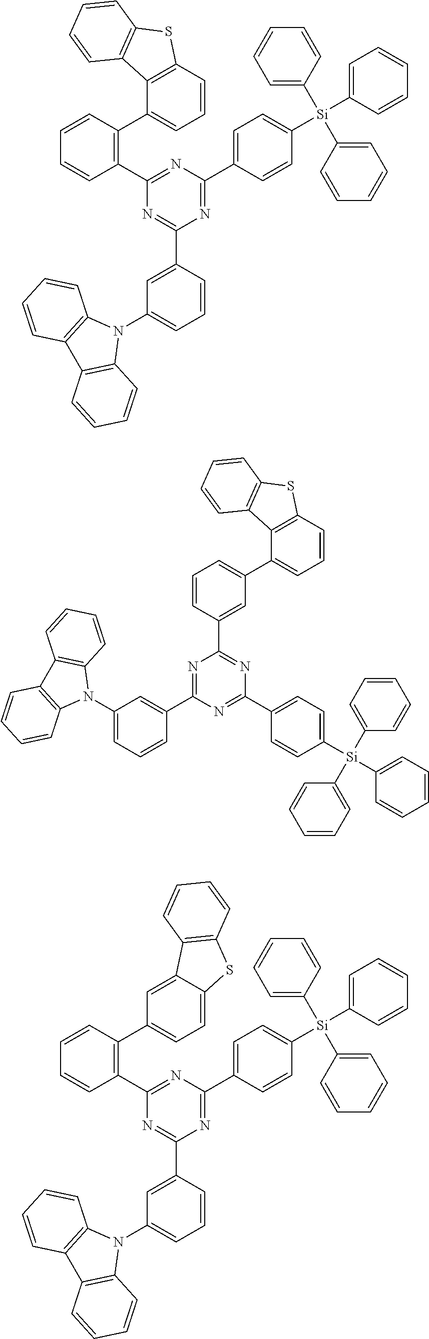 [SMILES: c1ccc([Si](c2ccccc2)(c2ccccc2)c2ccc(-c3nc(-c4cccc(-n5c6ccccc6c6ccccc65)c4)nc(-c4ccccc4-c4cccc5sc6ccccc6c45)n3)cc2)cc1 ; c1ccc([Si](c2ccccc2)(c2ccccc2)c2ccc(-c3nc(-c4cccc(-c5cccc6sc7ccccc7c56)c4)nc(-c4cccc(-n5c6ccccc6c6ccccc65)c4)n3)cc2)cc1 ; c1ccc([Si](c2ccccc2)(c2ccccc2)c2ccc(-c3nc(-c4cccc(-n5c6ccccc6c6ccccc65)c4)nc(-c4ccccc4-c4ccc5sc6ccccc6c5c4)n3)cc2)cc1]

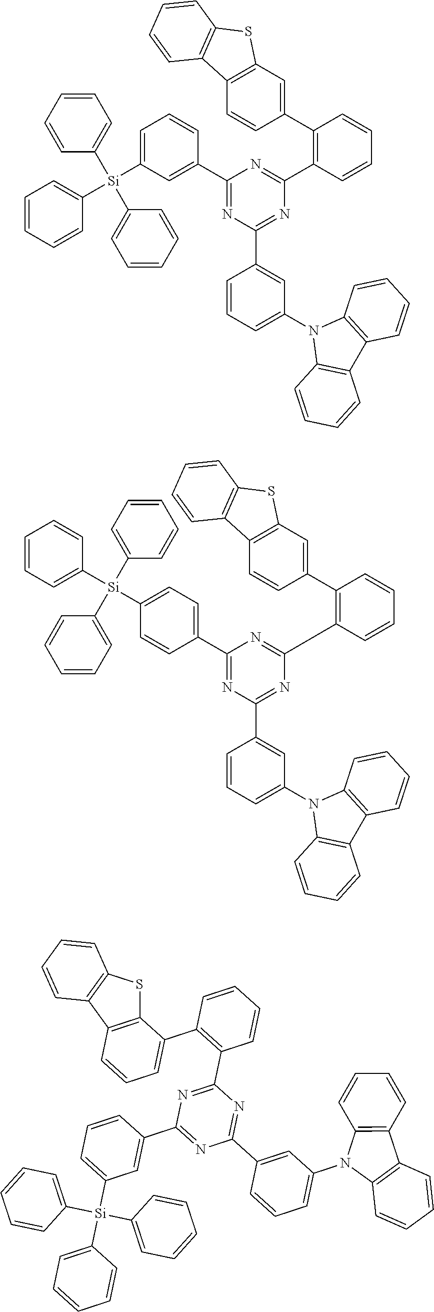 [SMILES: c1ccc([Si](c2ccccc2)(c2ccccc2)c2cccc(-c3nc(-c4cccc(-n5c6ccccc6c6ccccc65)c4)nc(-c4ccccc4-c4ccc5c(c4)sc4ccccc45)n3)c2)cc1 ; c1ccc([Si](c2ccccc2)(c2ccccc2)c2ccc(-c3nc(-c4cccc(-n5c6ccccc6c6ccccc65)c4)nc(-c4ccccc4-c4ccc5c(c4)sc4ccccc45)n3)cc2)cc1 ; c1ccc([Si](c2ccccc2)(c2ccccc2)c2cccc(-c3nc(-c4cccc(-n5c6ccccc6c6ccccc65)c4)nc(-c4ccccc4-c4cccc5c4sc4ccccc45)n3)c2)cc1]

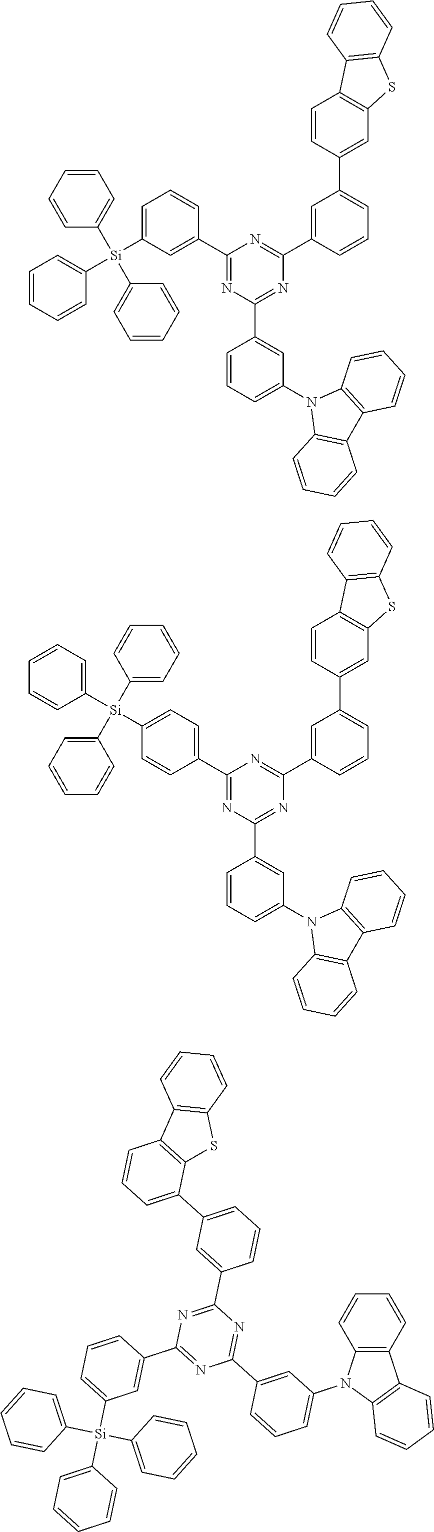

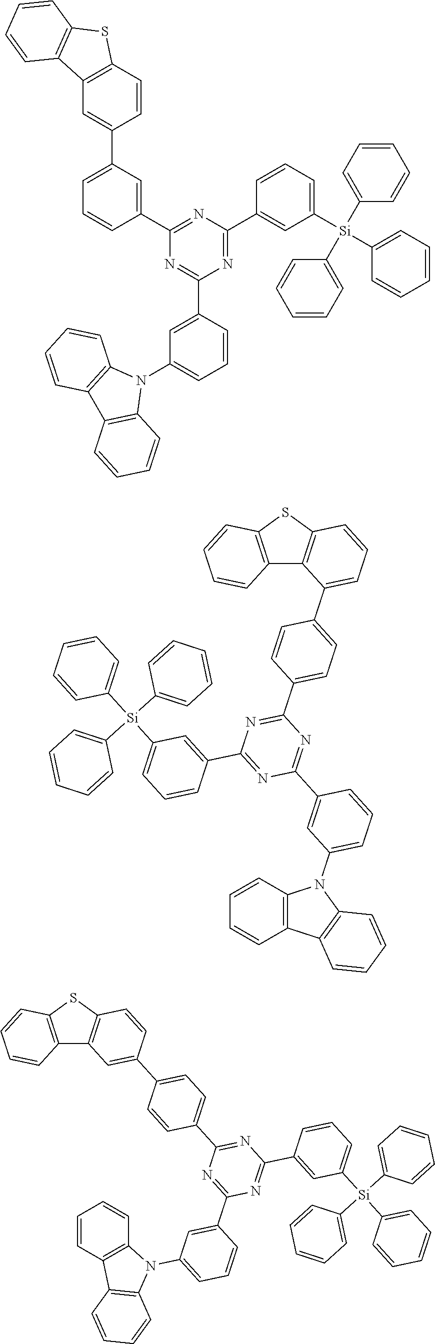 [SMILES: c1ccc([Si](c2ccccc2)(c2ccccc2)c2cccc(-c3nc(-c4cccc(-c5ccc6sc7ccccc7c6c5)c4)nc(-c4cccc(-n5c6ccccc6c6ccccc65)c4)n3)c2)cc1 ; c1ccc([Si](c2ccccc2)(c2ccccc2)c2cccc(-c3nc(-c4ccc(-c5cccc6sc7ccccc7c56)cc4)nc(-c4cccc(-n5c6ccccc6c6ccccc65)c4)n3)c2)cc1 ; c1ccc([Si](c2ccccc2)(c2ccccc2)c2cccc(-c3nc(-c4ccc(-c5ccc6sc7ccccc7c6c5)cc4)nc(-c4cccc(-n5c6ccccc6c6ccccc65)c4)n3)c2)cc1]

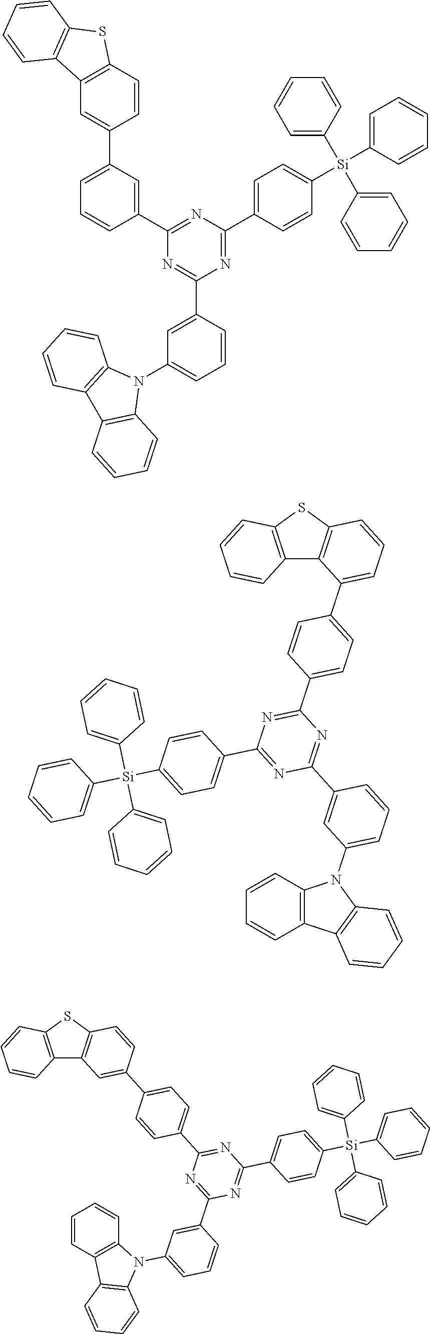 [SMILES: c1ccc([Si](c2ccccc2)(c2ccccc2)c2ccc(-c3nc(-c4cccc(-c5ccc6sc7ccccc7c6c5)c4)nc(-c4cccc(-n5c6ccccc6c6ccccc65)c4)n3)cc2)cc1 ; c1ccc([Si](c2ccccc2)(c2ccccc2)c2ccc(-c3nc(-c4ccc(-c5cccc6sc7ccccc7c56)cc4)nc(-c4cccc(-n5c6ccccc6c6ccccc65)c4)n3)cc2)cc1 ; c1ccc([Si](c2ccccc2)(c2ccccc2)c2ccc(-c3nc(-c4ccc(-c5ccc6sc7ccccc7c6c5)cc4)nc(-c4cccc(-n5c6ccccc6c6ccccc65)c4)n3)cc2)cc1]

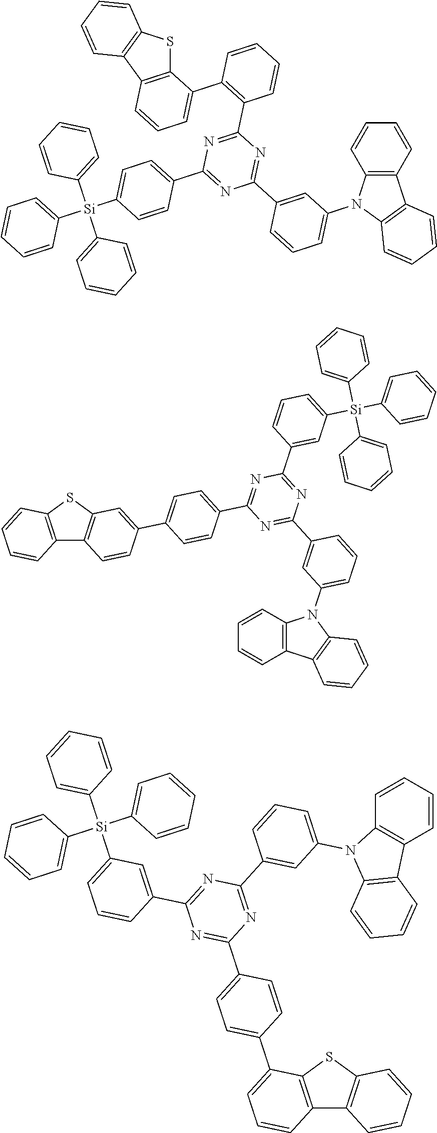 [SMILES: c1ccc([Si](c2ccccc2)(c2ccccc2)c2ccc(-c3nc(-c4cccc(-n5c6ccccc6c6ccccc65)c4)nc(-c4ccccc4-c4cccc5c4sc4ccccc45)n3)cc2)cc1 ; c1ccc([Si](c2ccccc2)(c2ccccc2)c2cccc(-c3nc(-c4ccc(-c5ccc6c(c5)sc5ccccc56)cc4)nc(-c4cccc(-n5c6ccccc6c6ccccc65)c4)n3)c2)cc1 ; c1ccc([Si](c2ccccc2)(c2ccccc2)c2cccc(-c3nc(-c4ccc(-c5cccc6c5sc5ccccc56)cc4)nc(-c4cccc(-n5c6ccccc6c6ccccc65)c4)n3)c2)cc1]

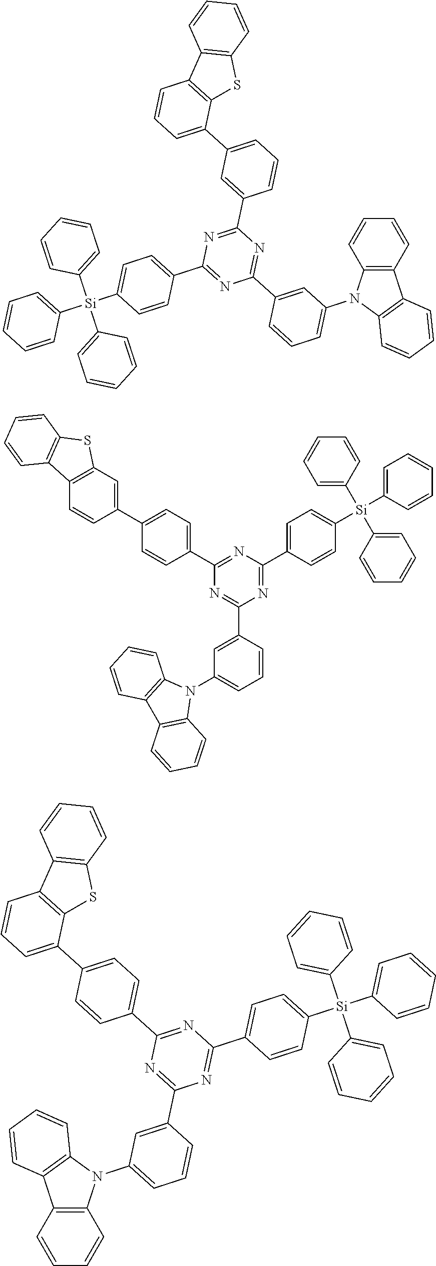 [SMILES: c1ccc([Si](c2ccccc2)(c2ccccc2)c2ccc(-c3nc(-c4cccc(-c5cccc6c5sc5ccccc56)c4)nc(-c4cccc(-n5c6ccccc6c6ccccc65)c4)n3)cc2)cc1 ; c1ccc([Si](c2ccccc2)(c2ccccc2)c2ccc(-c3nc(-c4ccc(-c5ccc6c(c5)sc5ccccc56)cc4)nc(-c4cccc(-n5c6ccccc6c6ccccc65)c4)n3)cc2)cc1 ; c1ccc([Si](c2ccccc2)(c2ccccc2)c2ccc(-c3nc(-c4ccc(-c5cccc6c5sc5ccccc56)cc4)nc(-c4cccc(-n5c6ccccc6c6ccccc65)c4)n3)cc2)cc1]

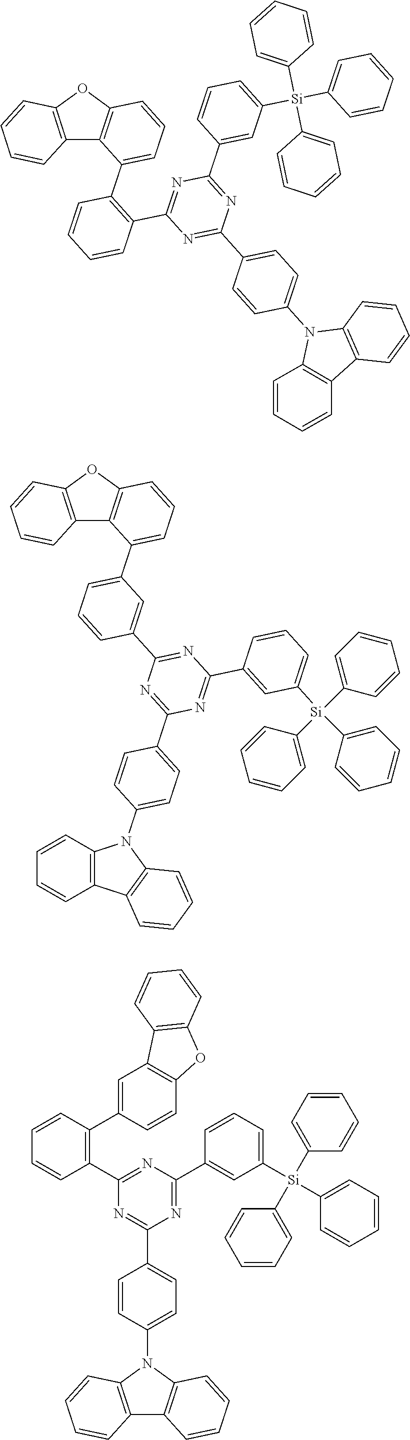

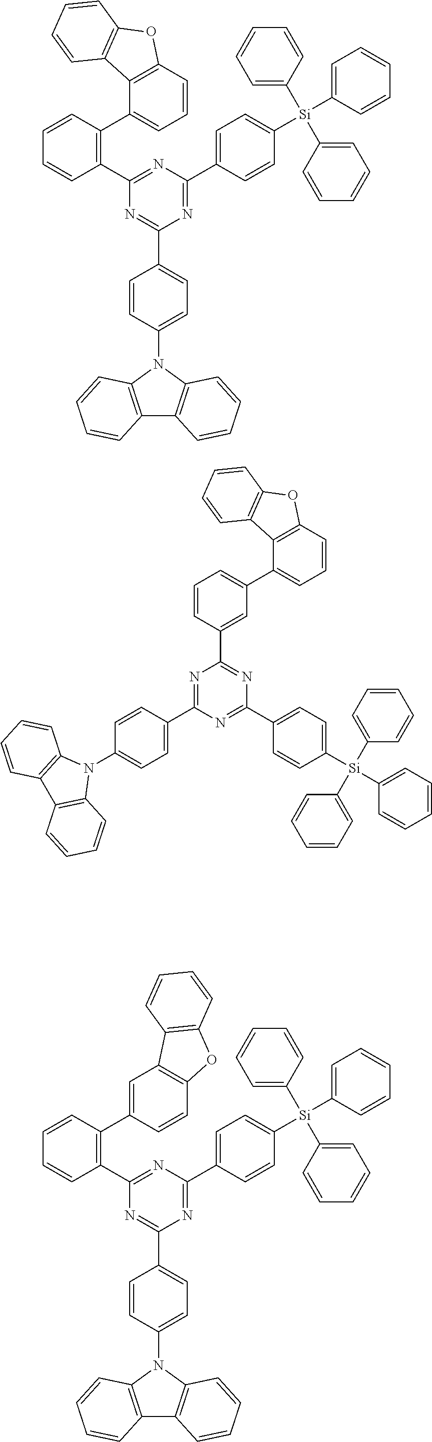

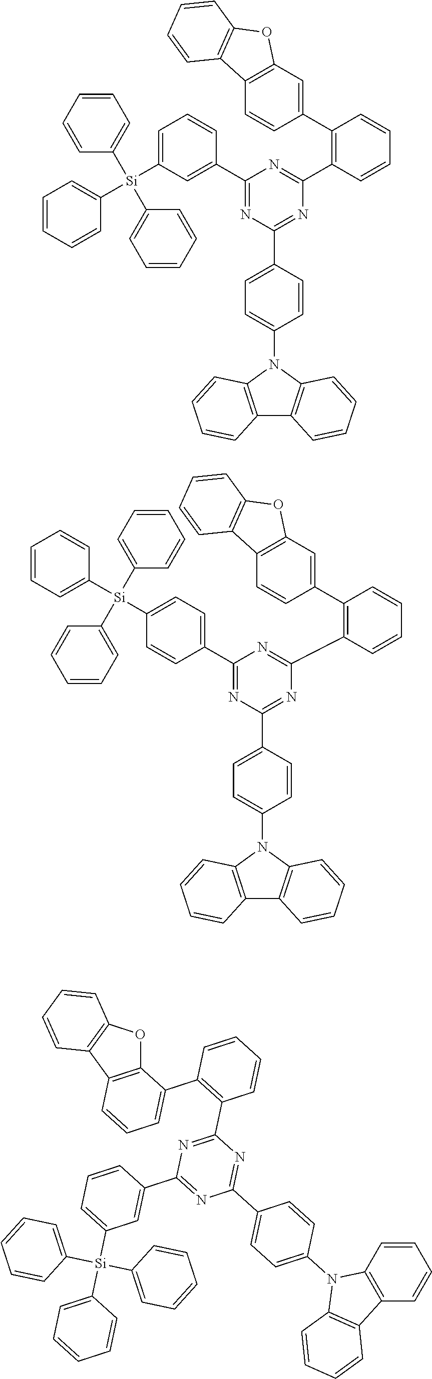

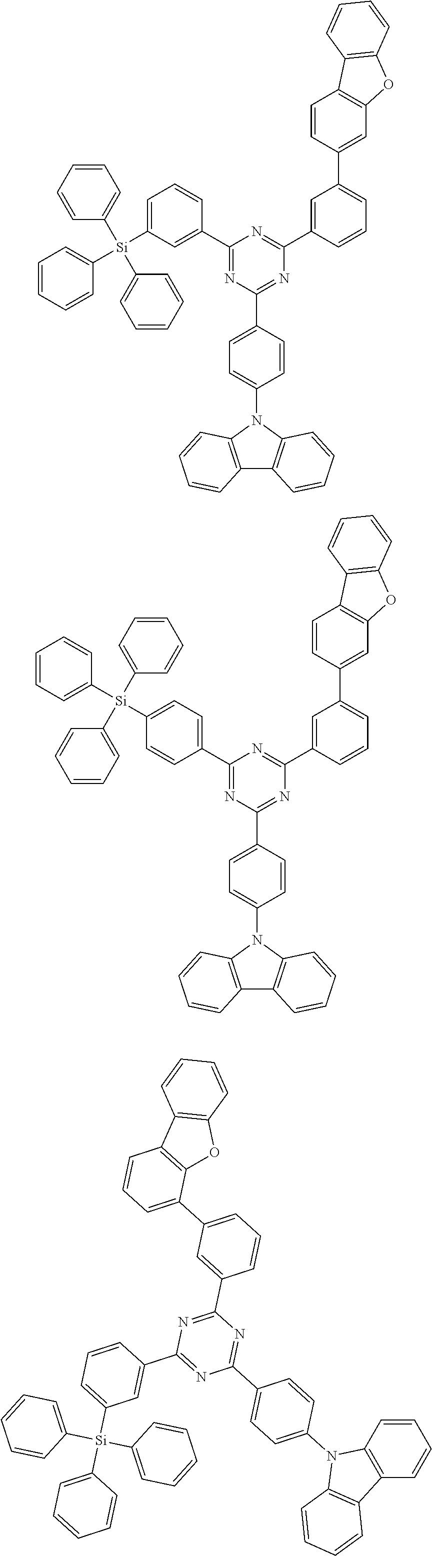

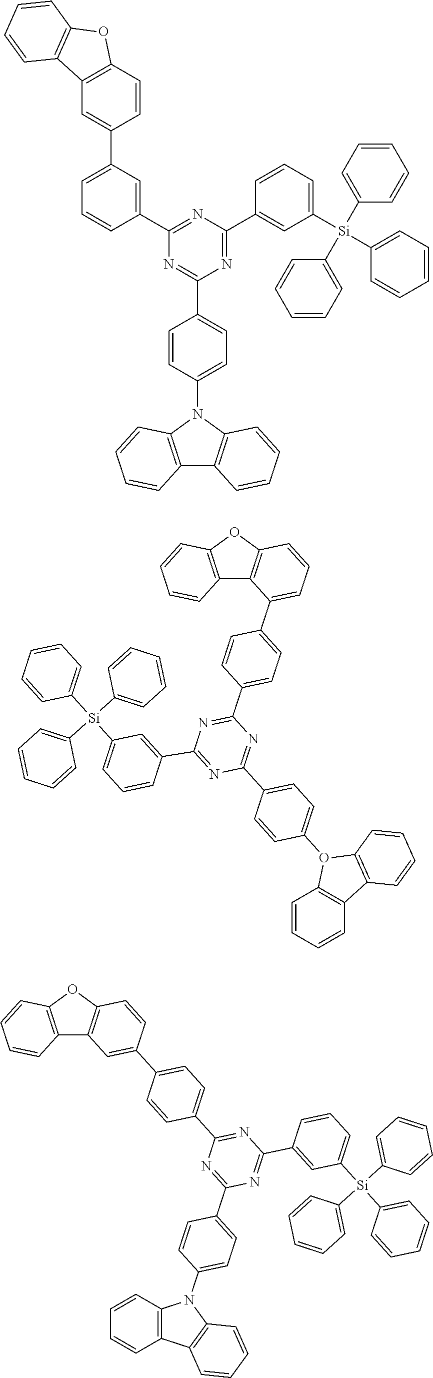

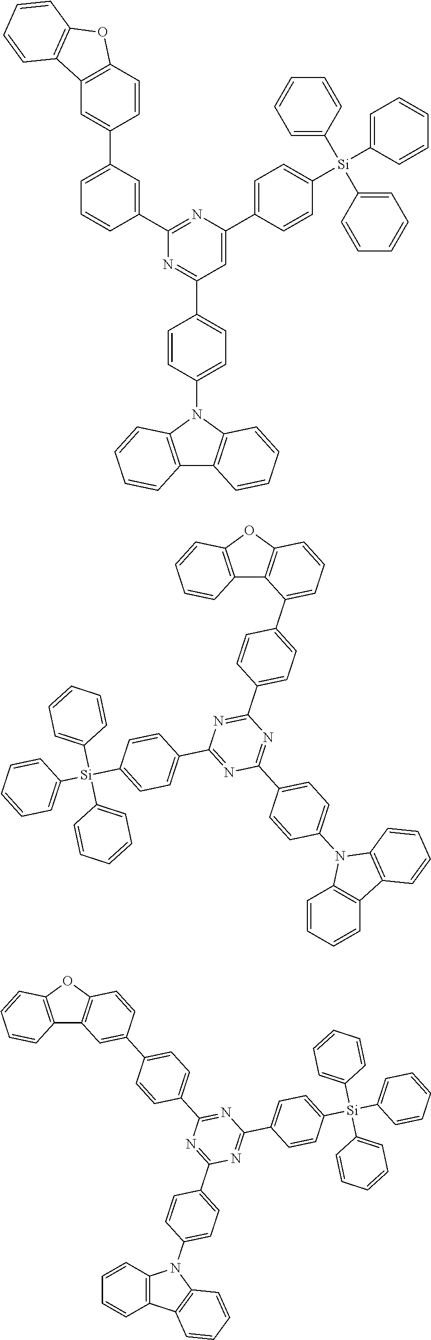 [SMILES: c1ccc([Si](c2ccccc2)(c2ccccc2)c2ccc(-c3cc(-c4ccc(-n5c6ccccc6c6ccccc65)cc4)nc(-c4cccc(-c5ccc6oc7ccccc7c6c5)c4)n3)cc2)cc1 ; c1ccc([Si](c2ccccc2)(c2ccccc2)c2ccc(-c3nc(-c4ccc(-c5cccc6oc7ccccc7c56)cc4)nc(-c4ccc(-n5c6ccccc6c6ccccc65)cc4)n3)cc2)cc1 ; c1ccc([Si](c2ccccc2)(c2ccccc2)c2ccc(-c3nc(-c4ccc(-c5ccc6oc7ccccc7c6c5)cc4)nc(-c4ccc(-n5c6ccccc6c6ccccc65)cc4)n3)cc2)cc1]

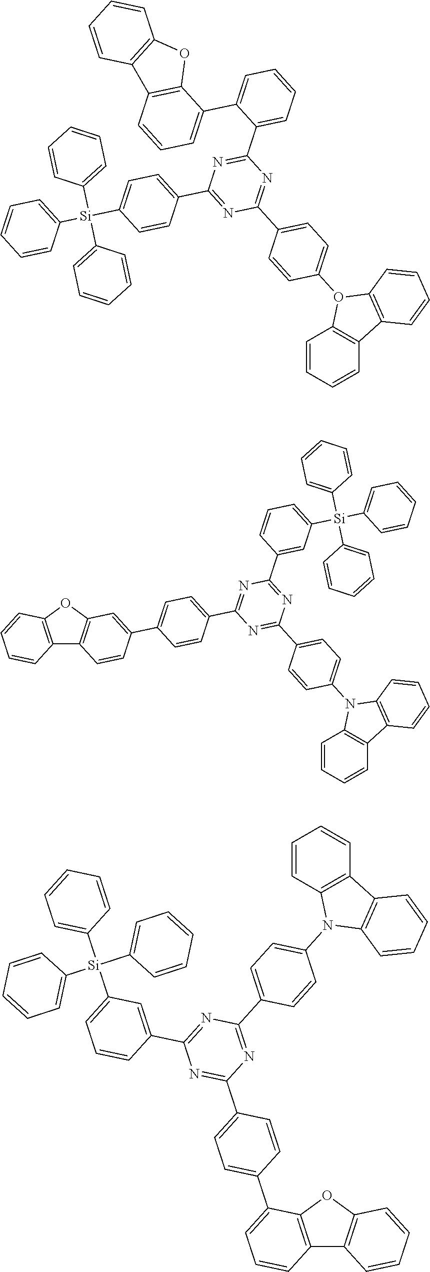

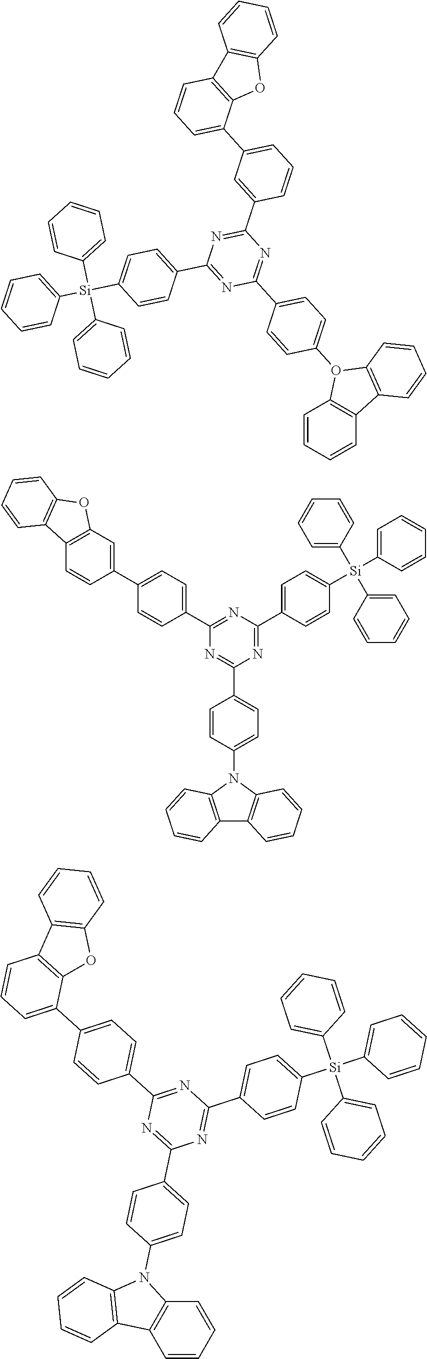

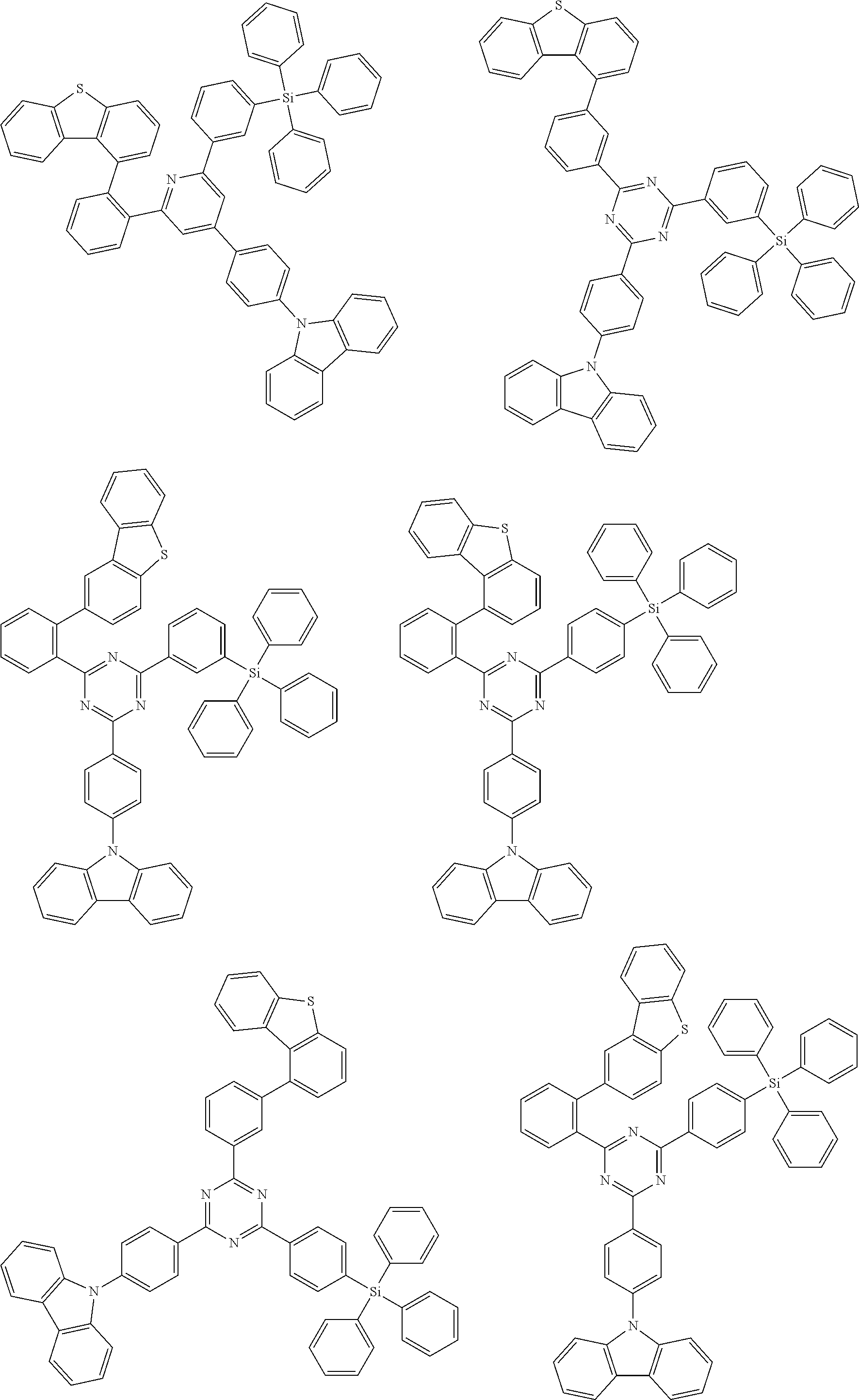

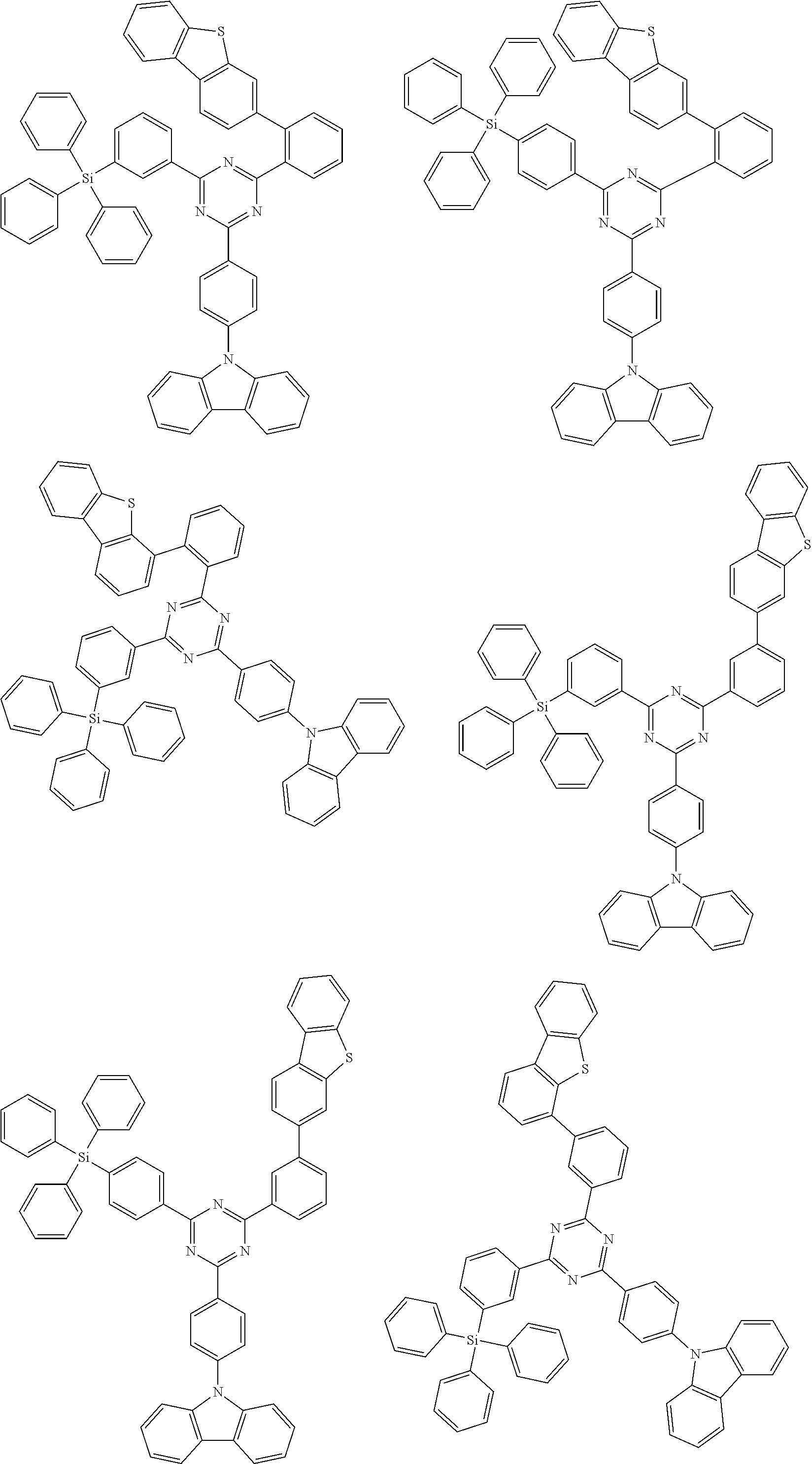

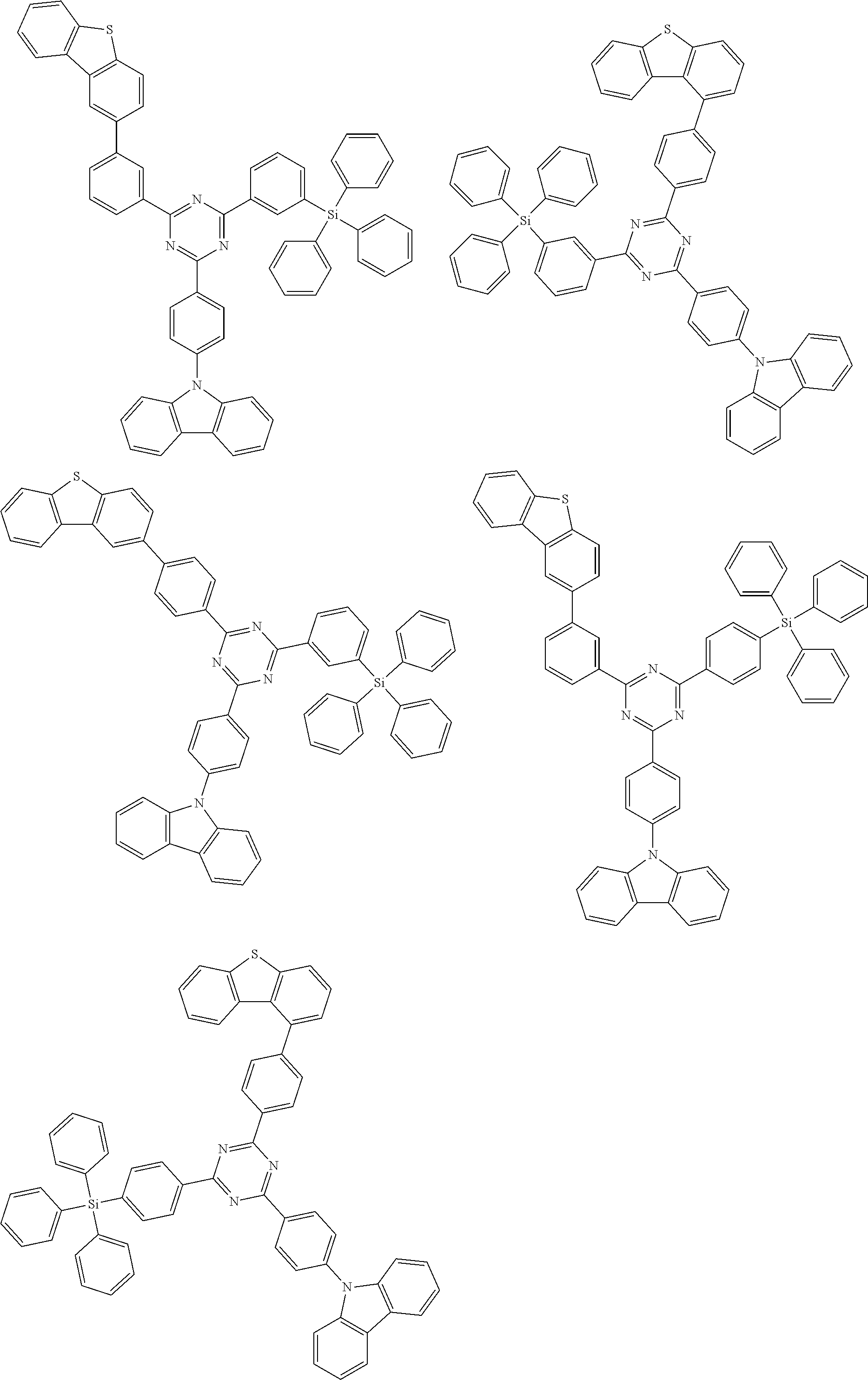

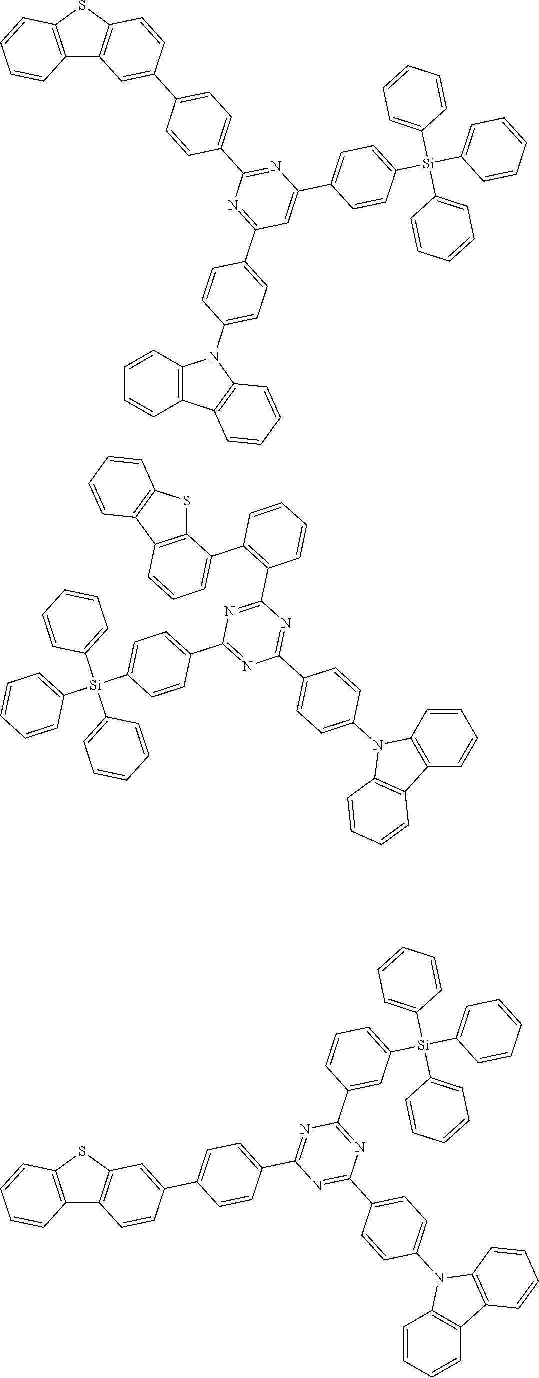

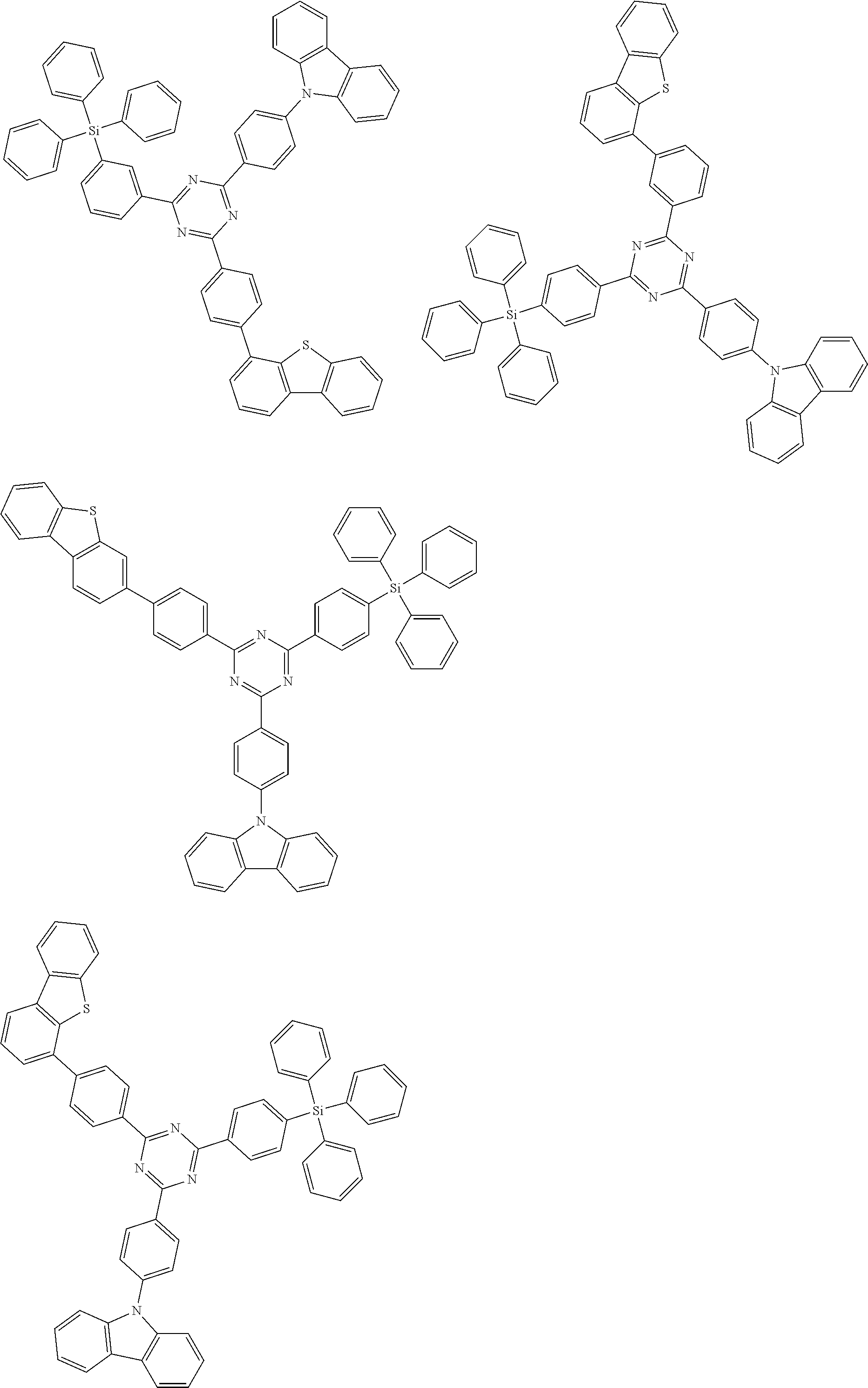 [SMILES: c1ccc([Si](c2ccccc2)(c2ccccc2)c2cccc(-c3nc(-c4ccc(-c5cccc6c5sc5ccccc56)cc4)nc(-c4ccc(-n5c6ccccc6c6ccccc65)cc4)n3)c2)cc1 ; c1ccc([Si](c2ccccc2)(c2ccccc2)c2ccc(-c3nc(-c4ccc(-n5c6ccccc6c6ccccc65)cc4)nc(-c4cccc(-c5cccc6c5sc5ccccc56)c4)n3)cc2)cc1 ; c1ccc([Si](c2ccccc2)(c2ccccc2)c2ccc(-c3nc(-c4ccc(-c5ccc6c(c5)sc5ccccc56)cc4)nc(-c4ccc(-n5c6ccccc6c6ccccc65)cc4)n3)cc2)cc1 ; c1ccc([Si](c2ccccc2)(c2ccccc2)c2ccc(-c3nc(-c4ccc(-c5cccc6c5sc5ccccc56)cc4)nc(-c4ccc(-n5c6ccccc6c6ccccc65)cc4)n3)cc2)cc1]

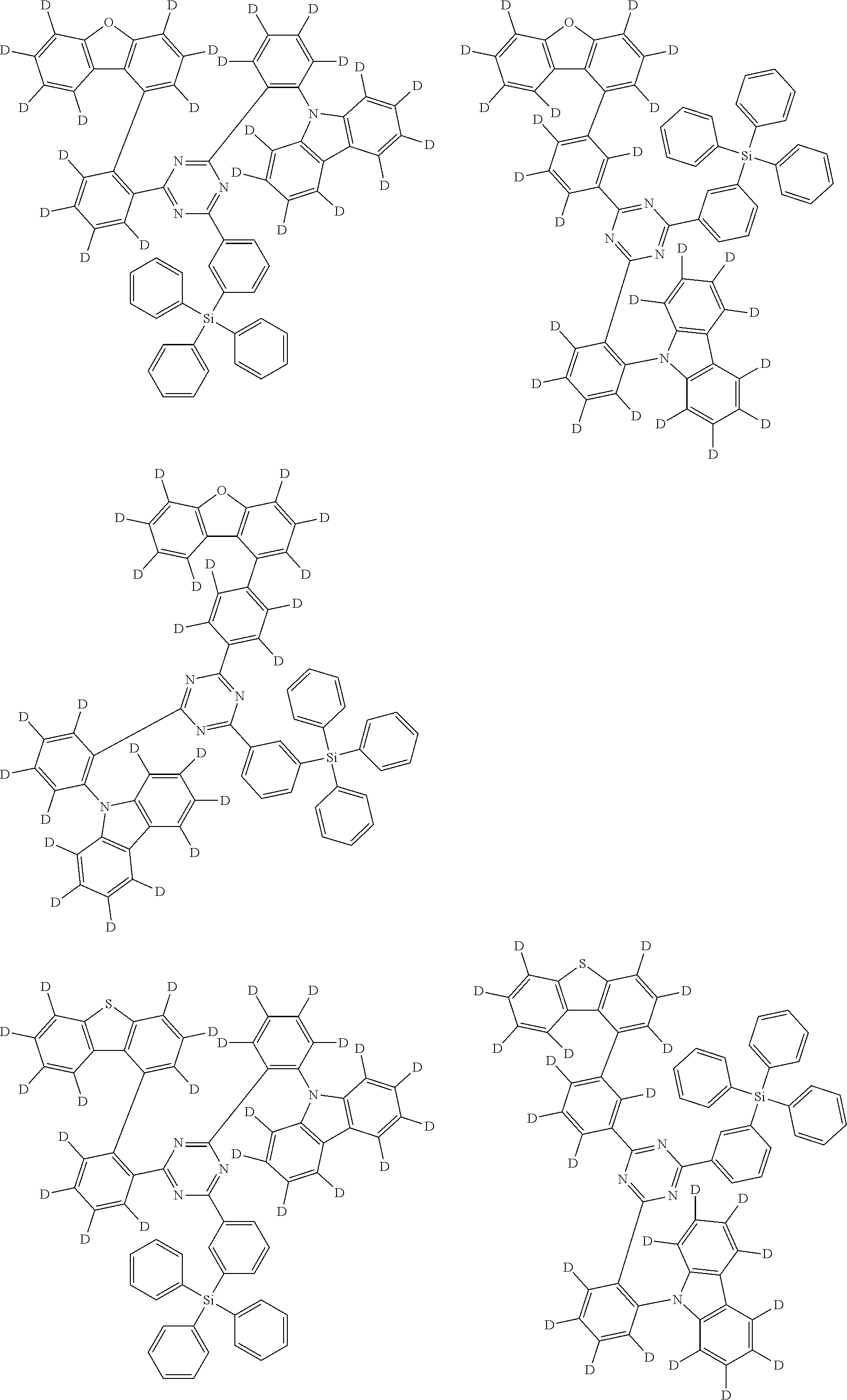

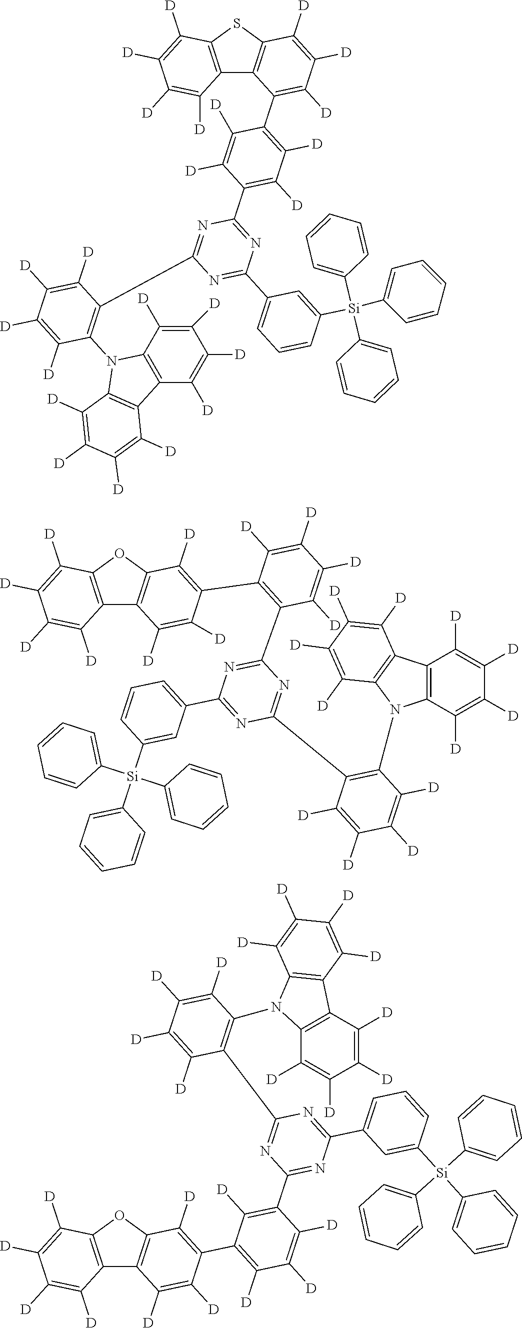

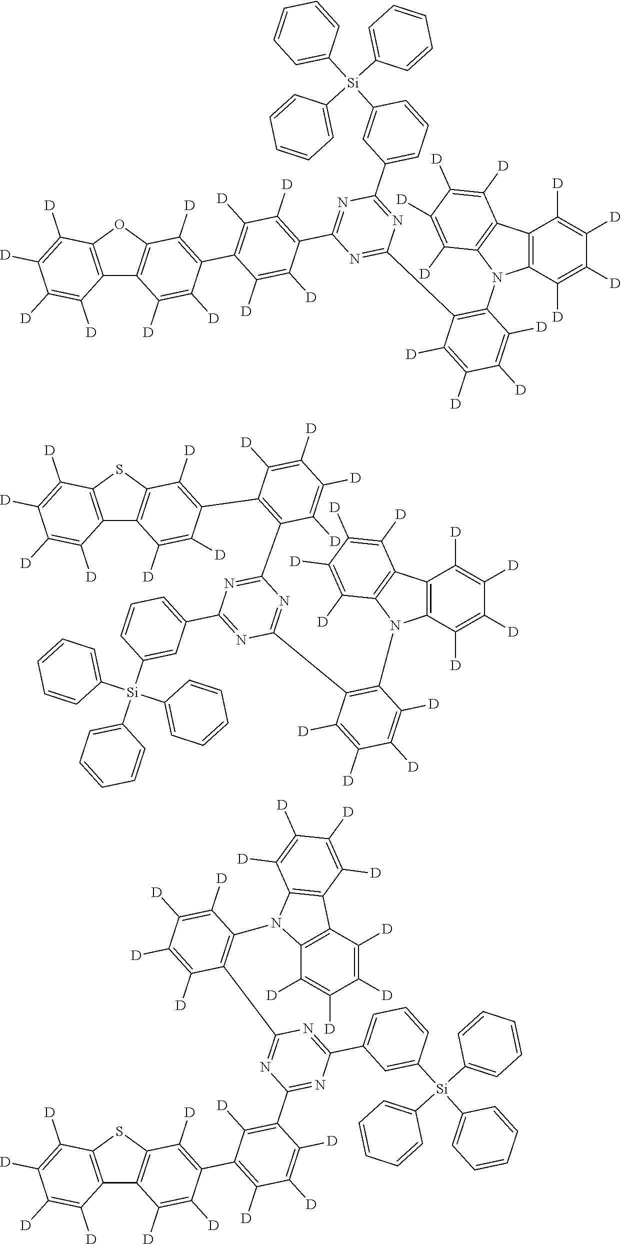

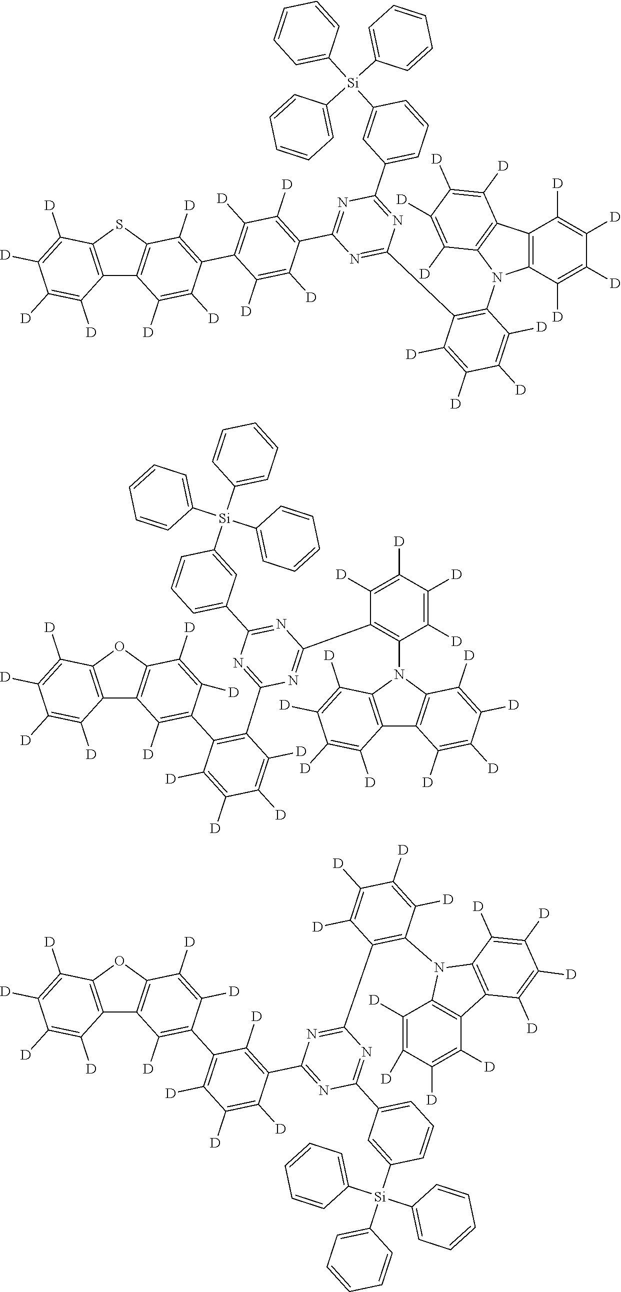

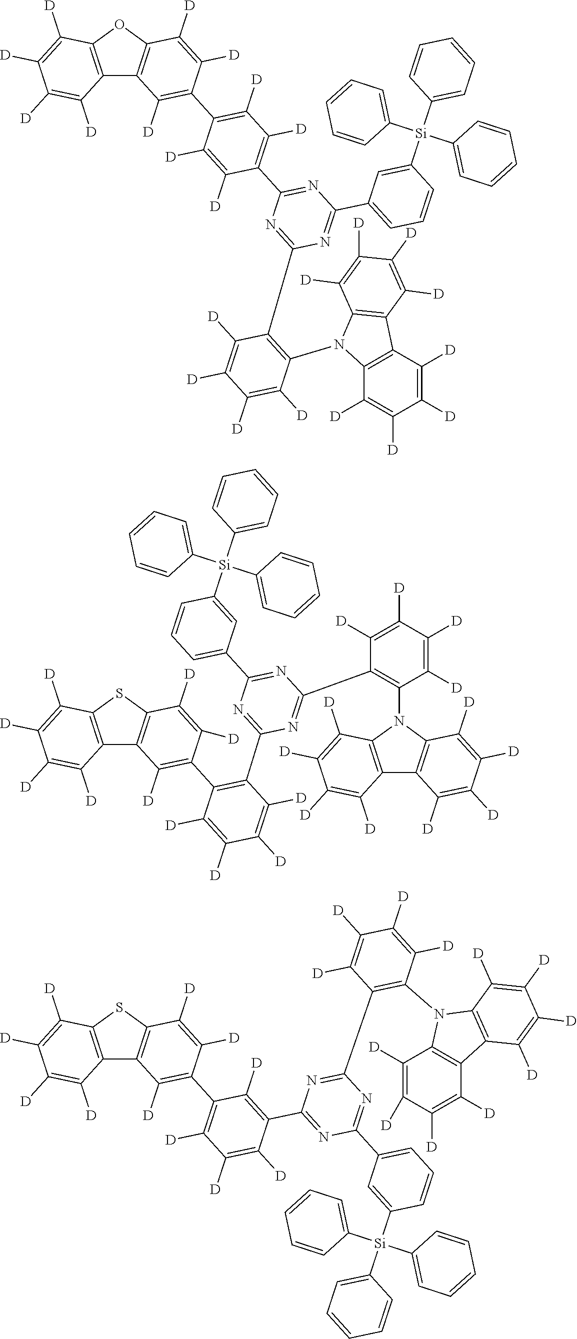

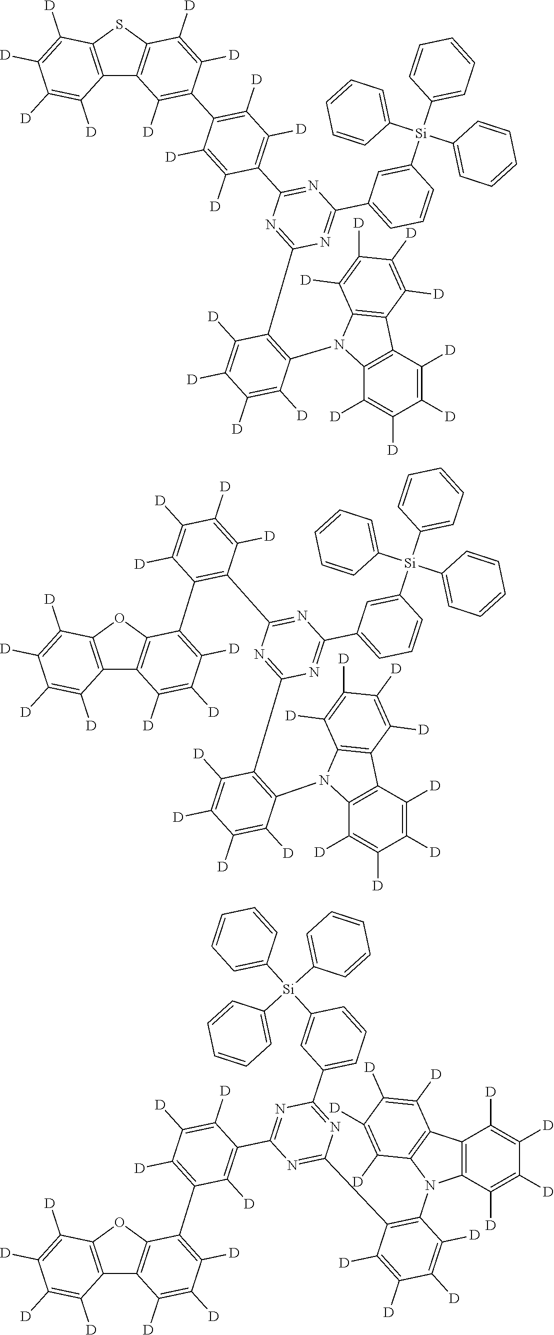

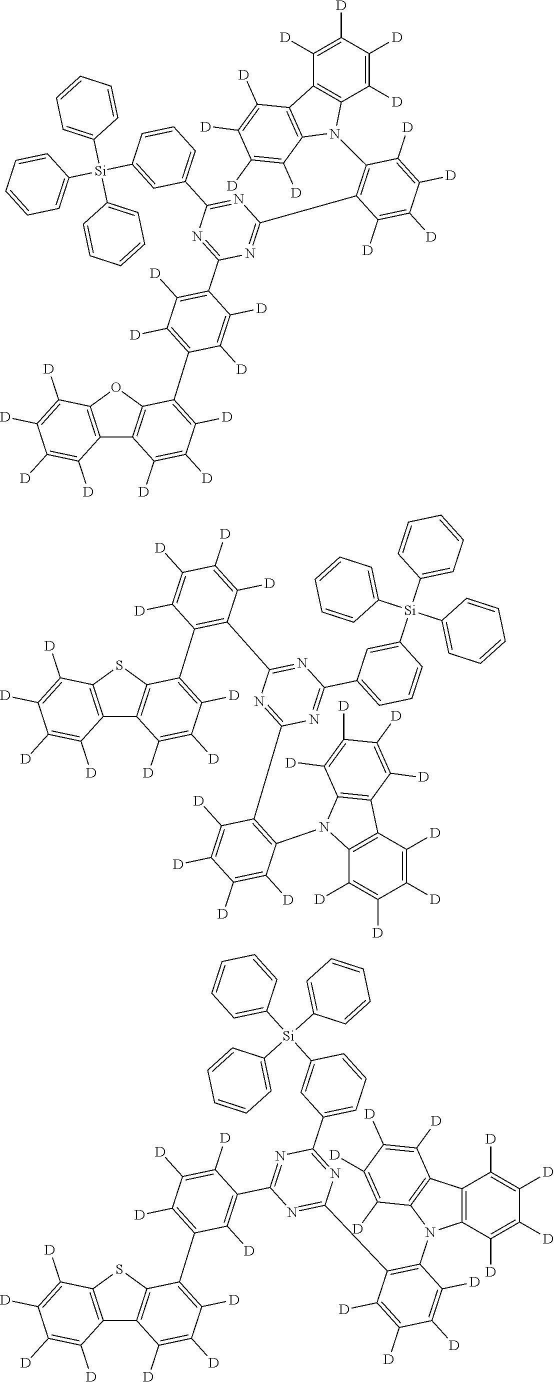

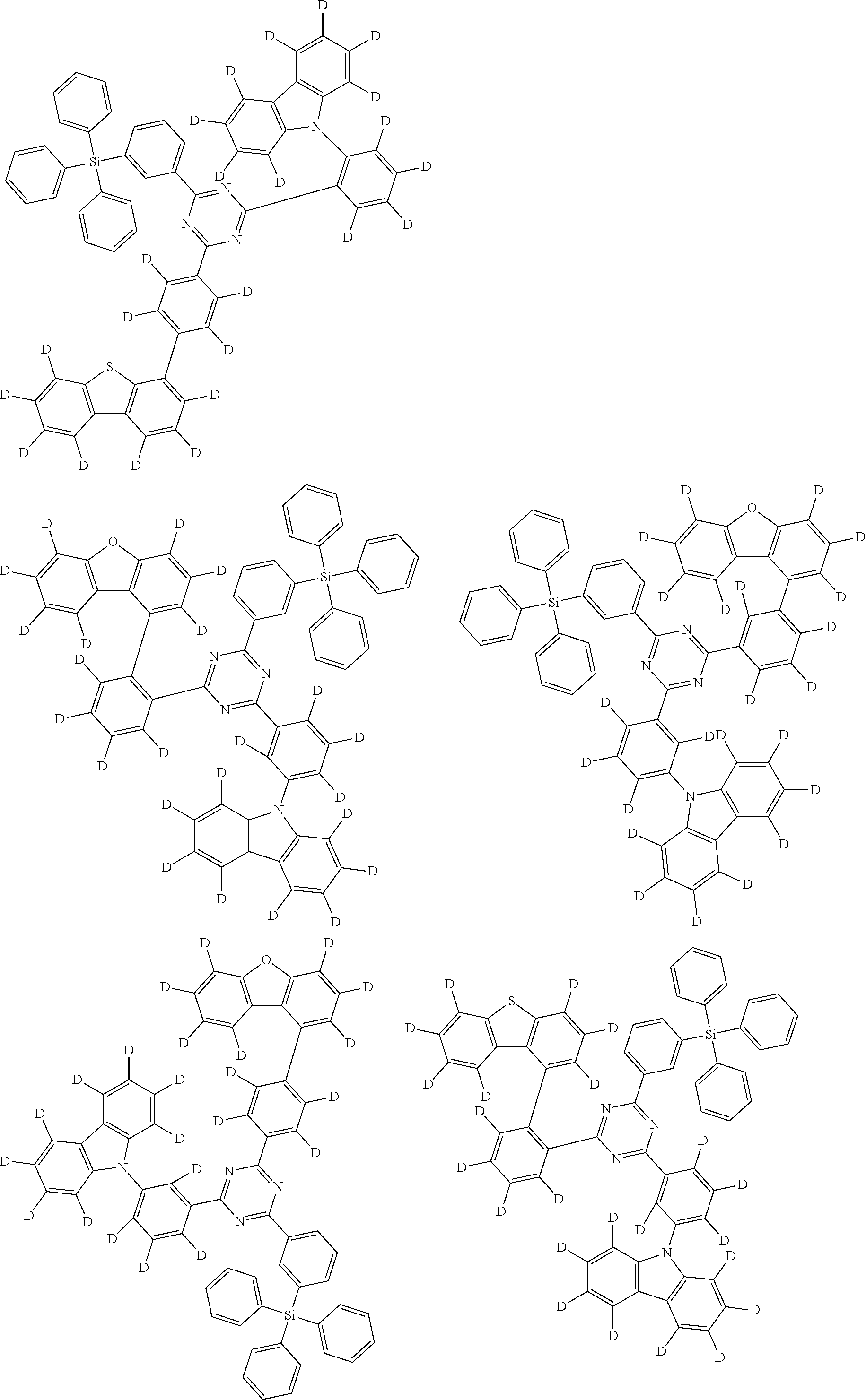

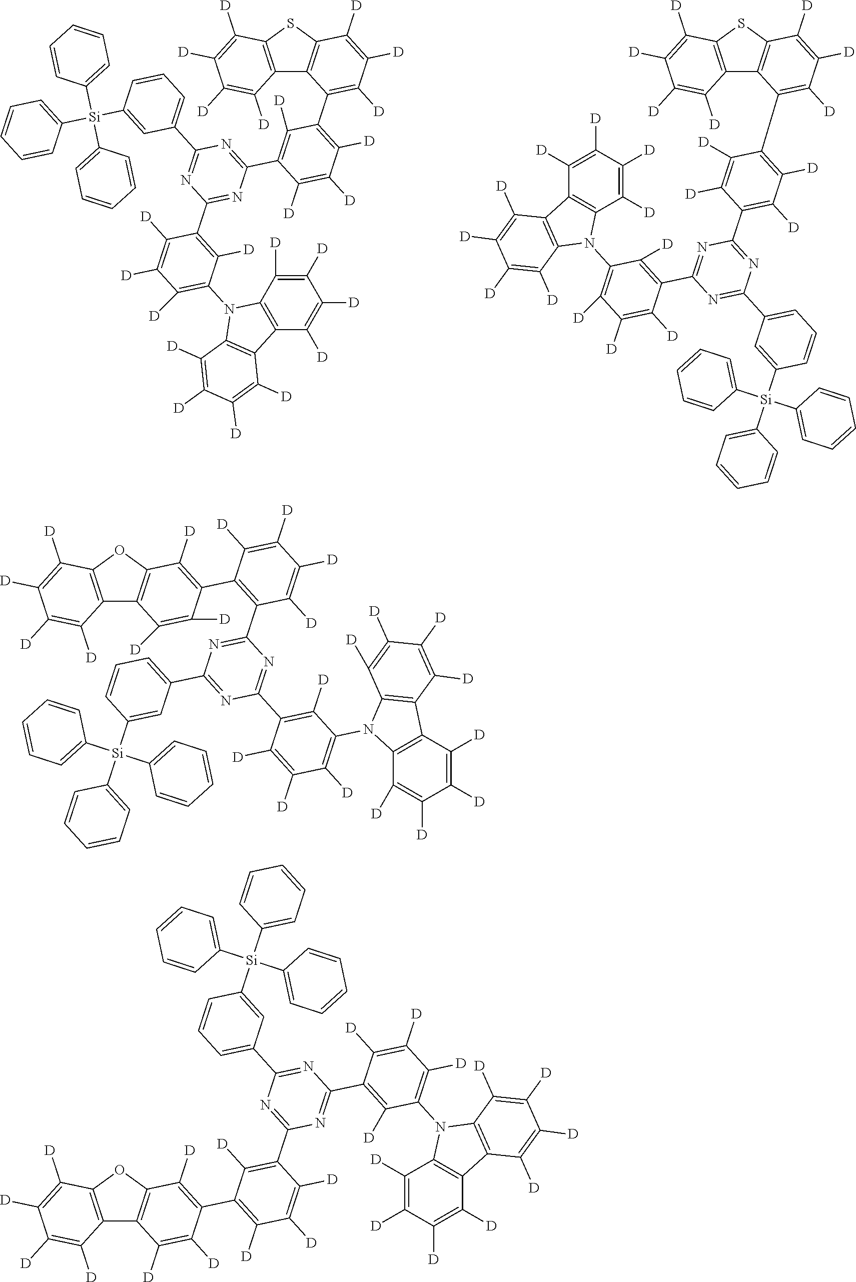

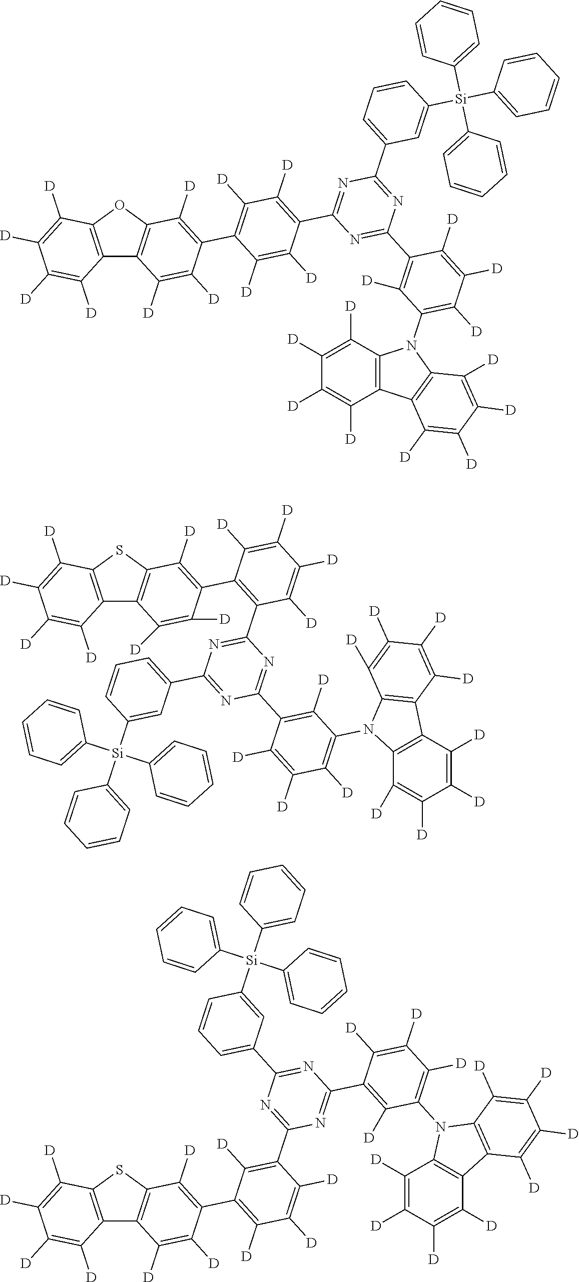

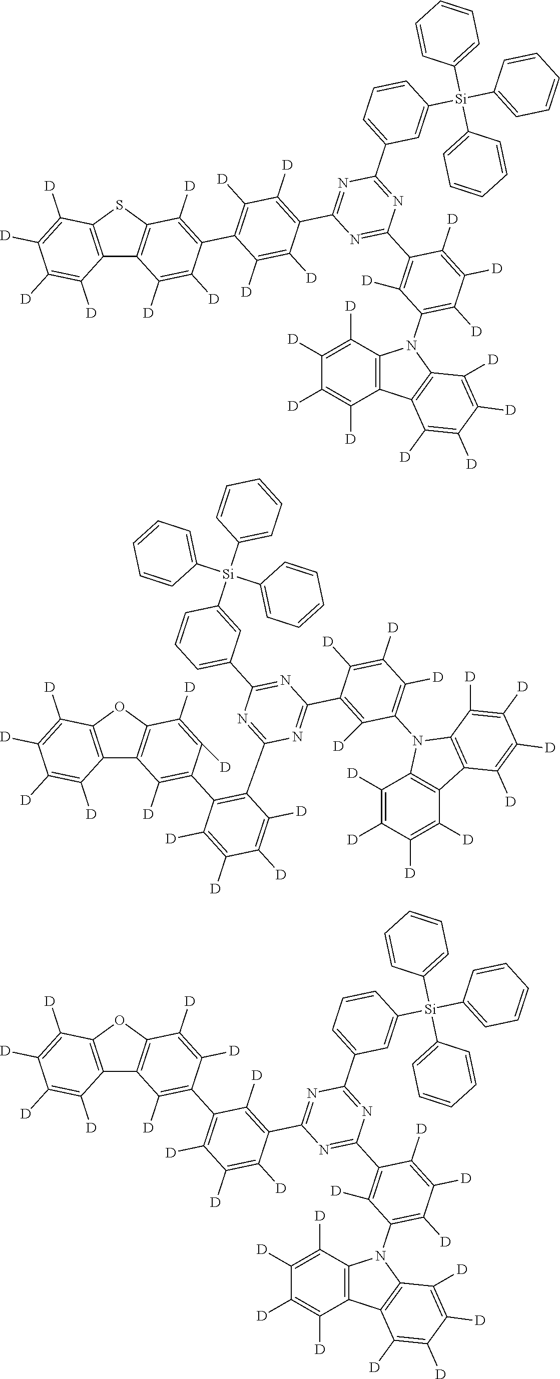

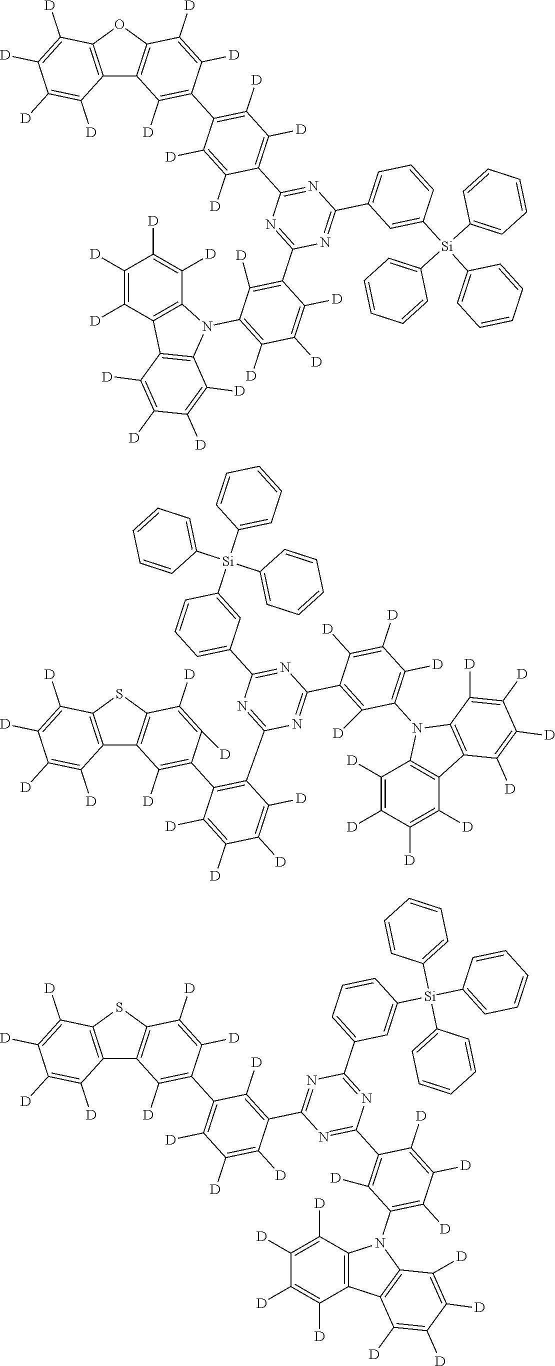

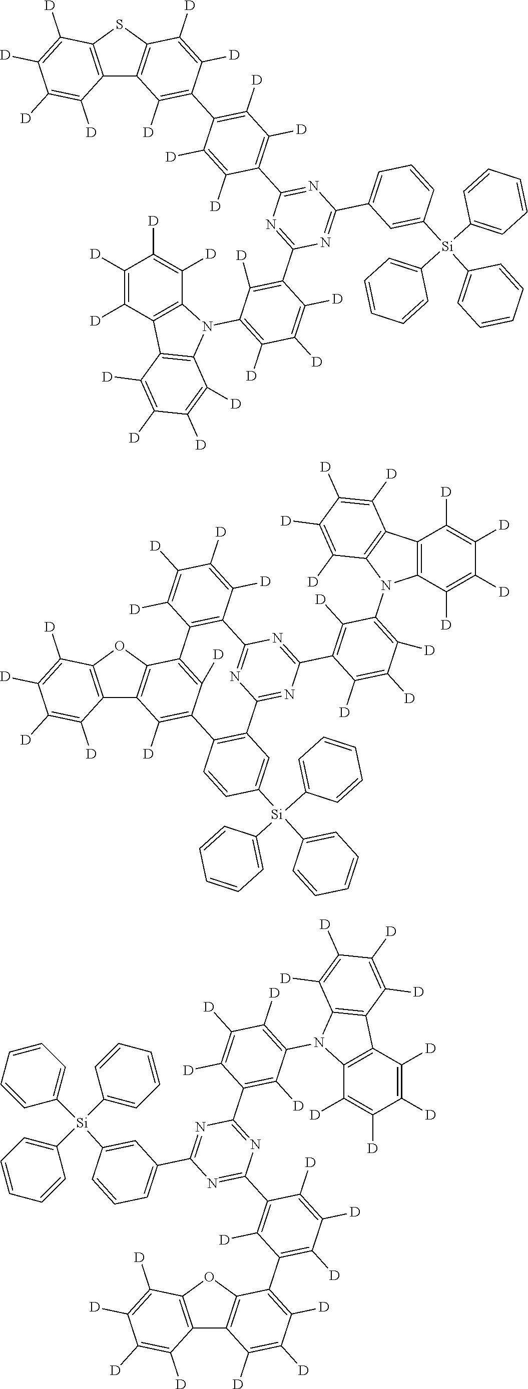

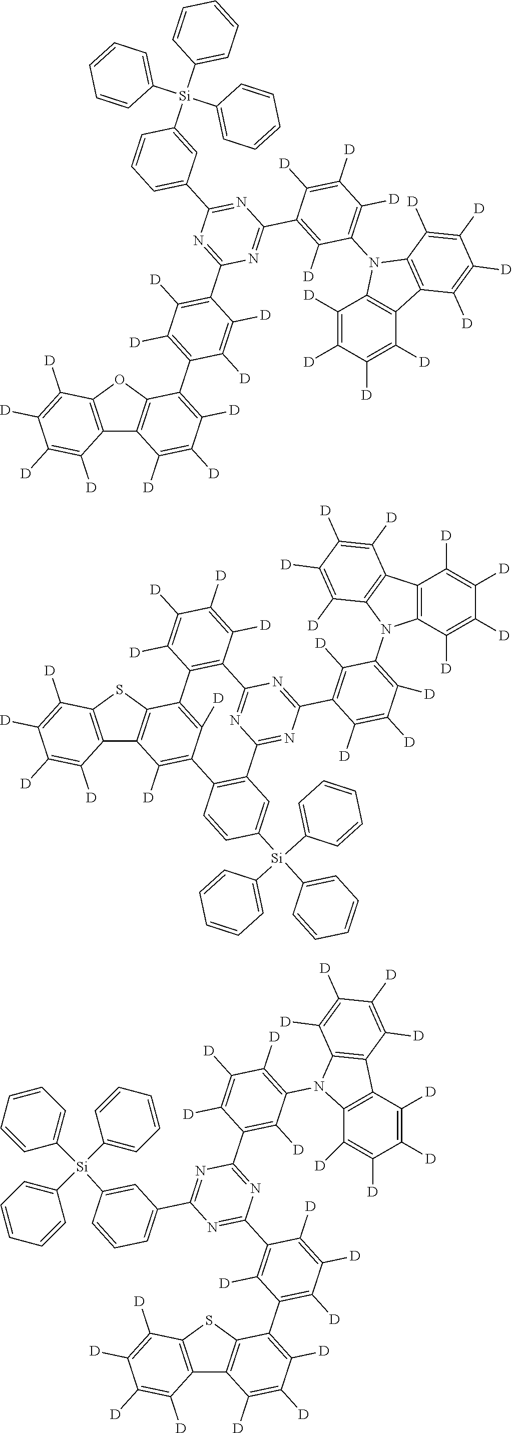

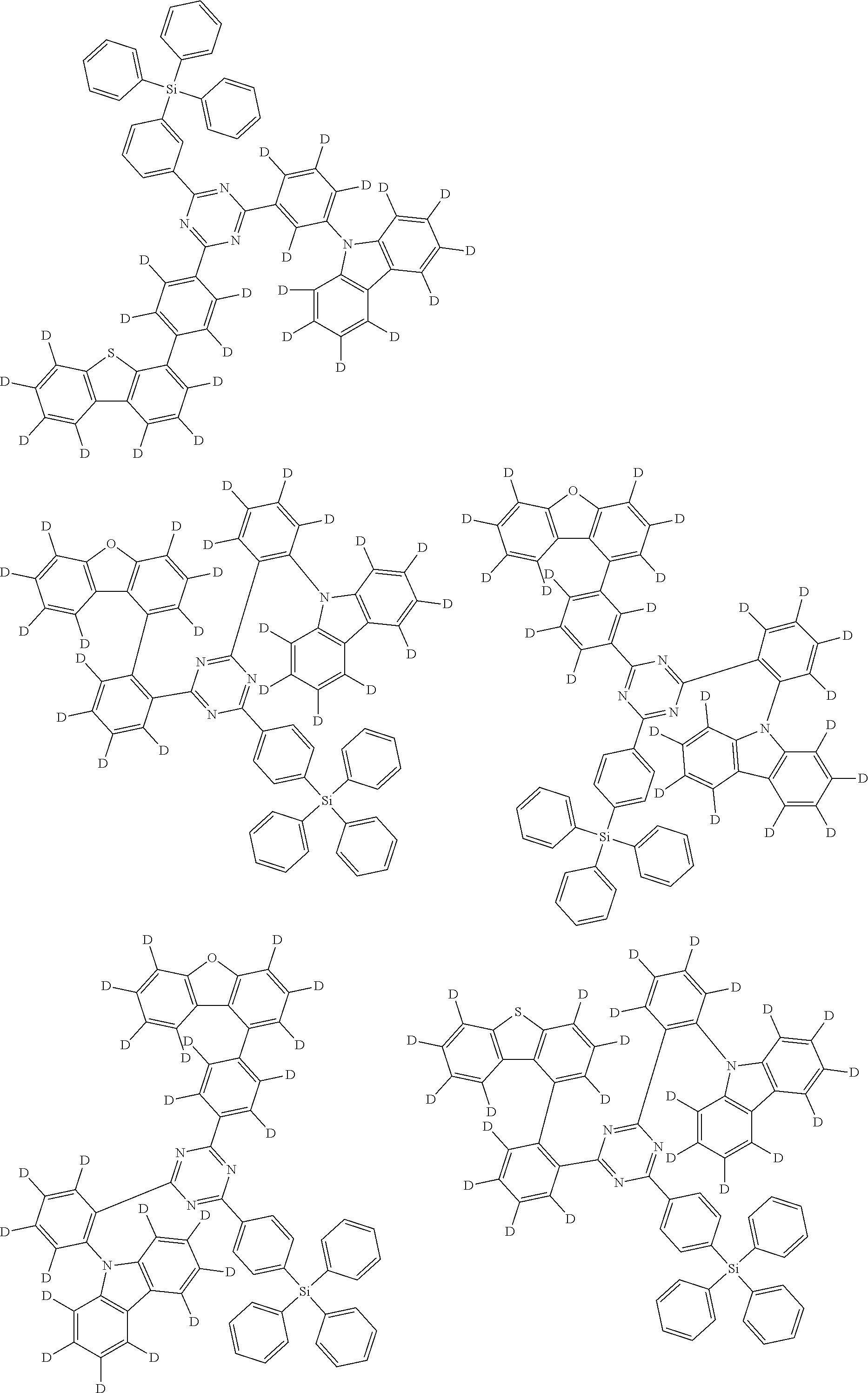

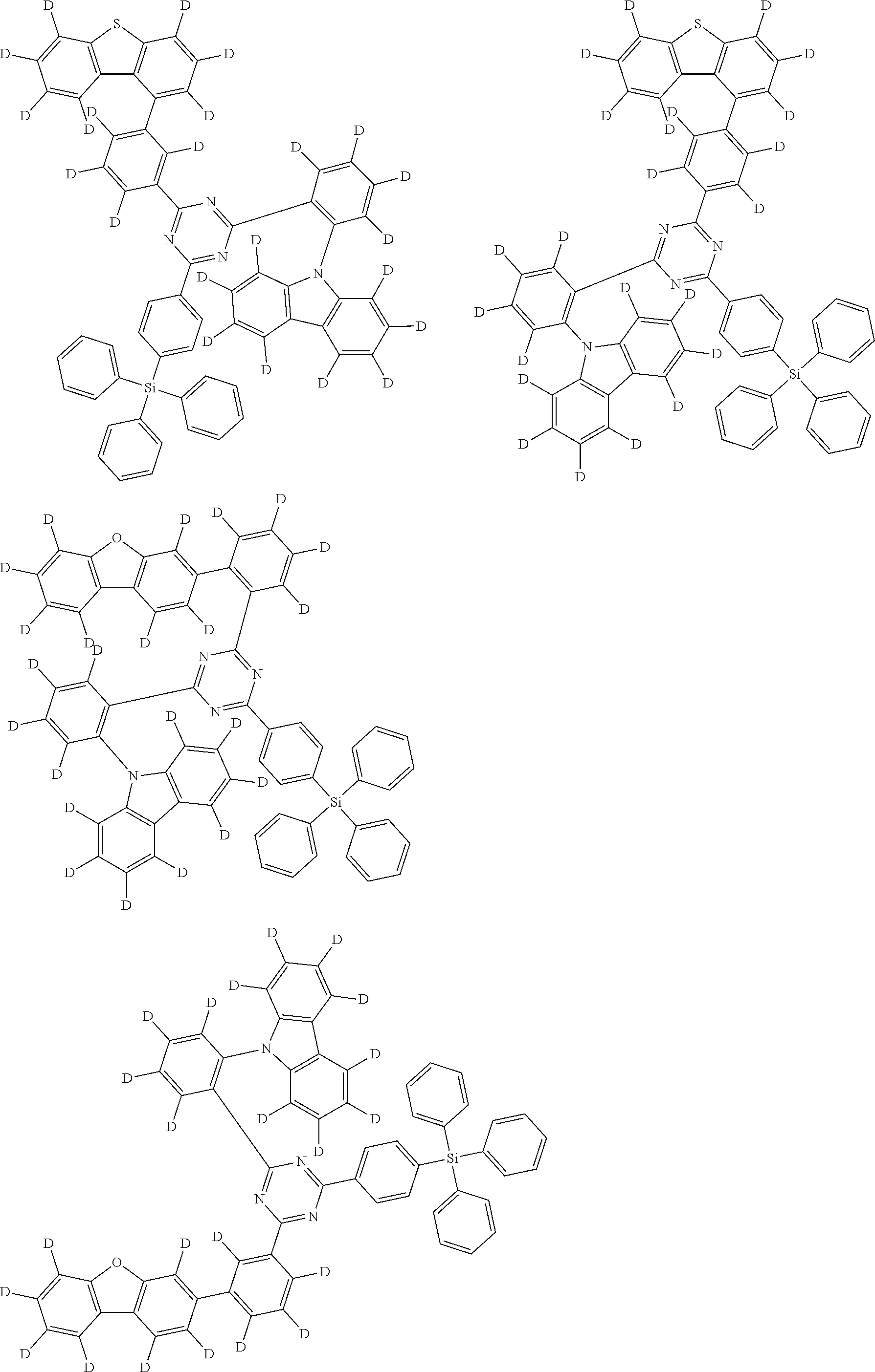

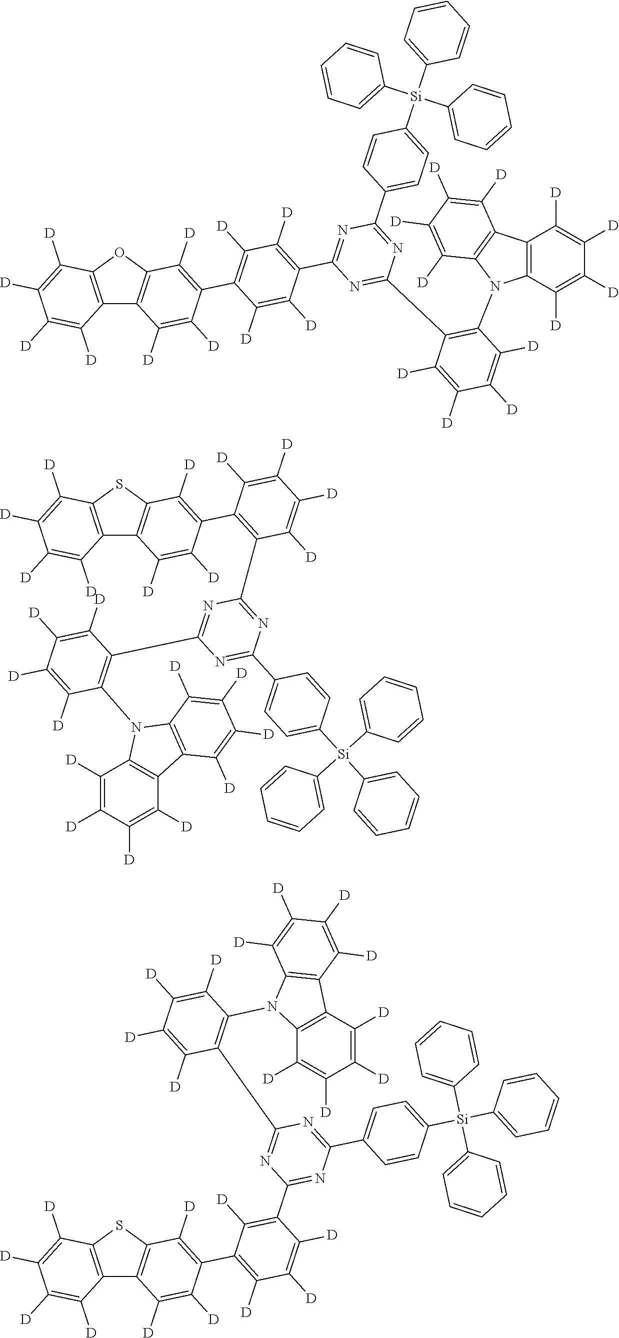

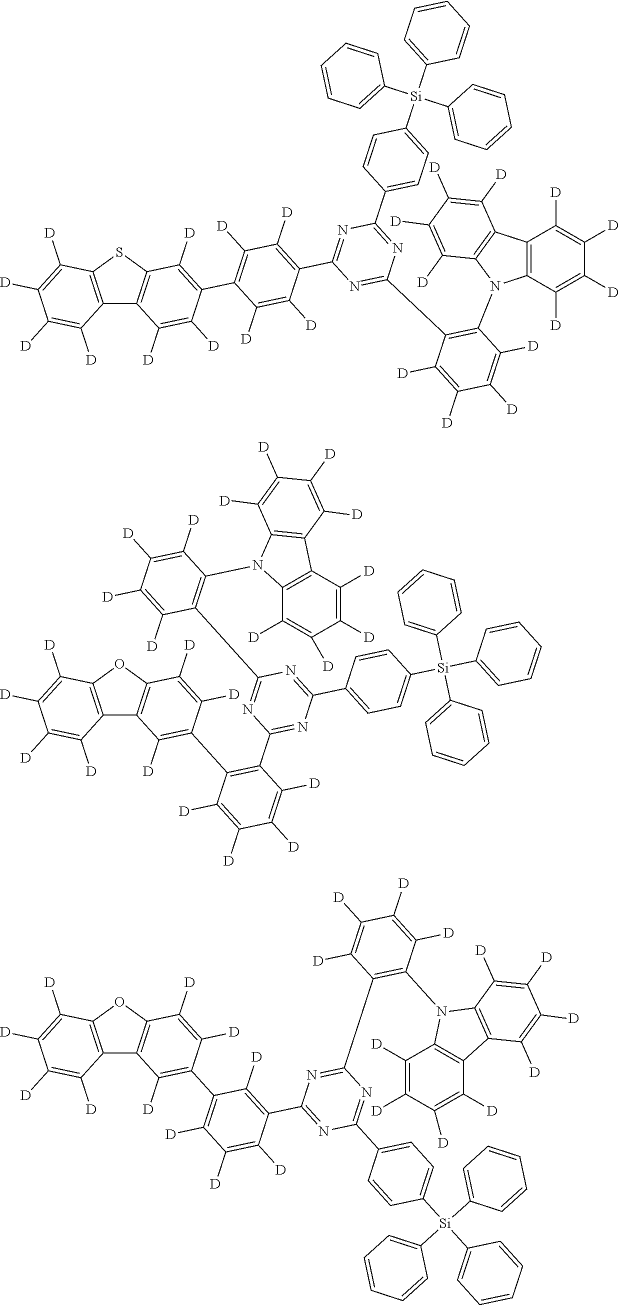

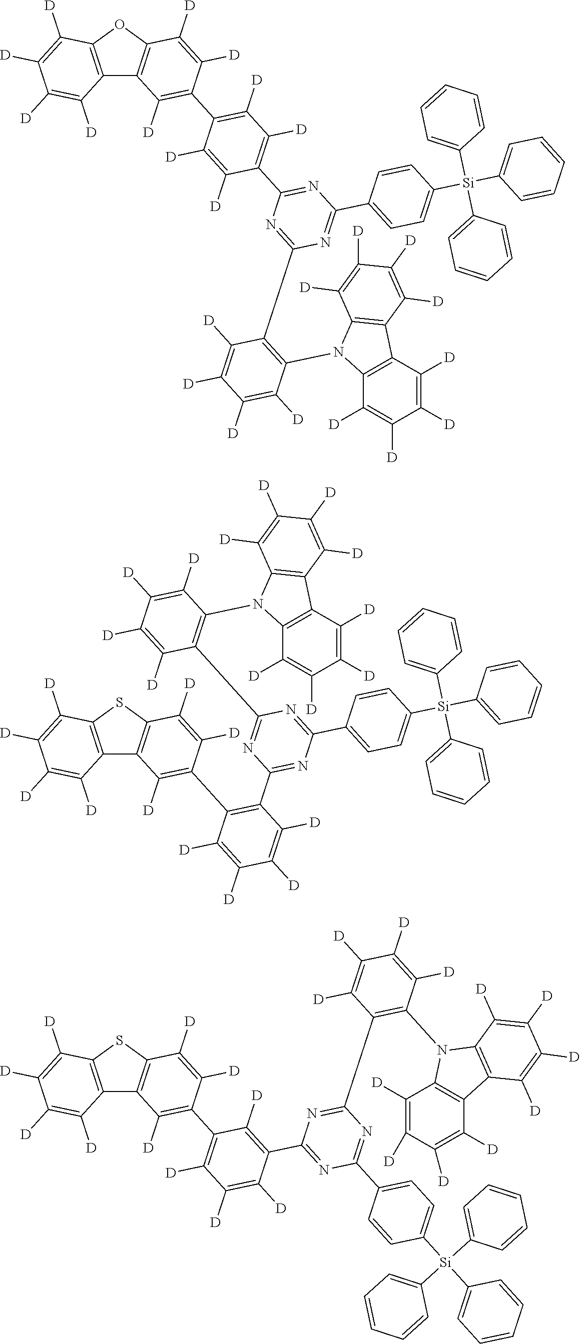

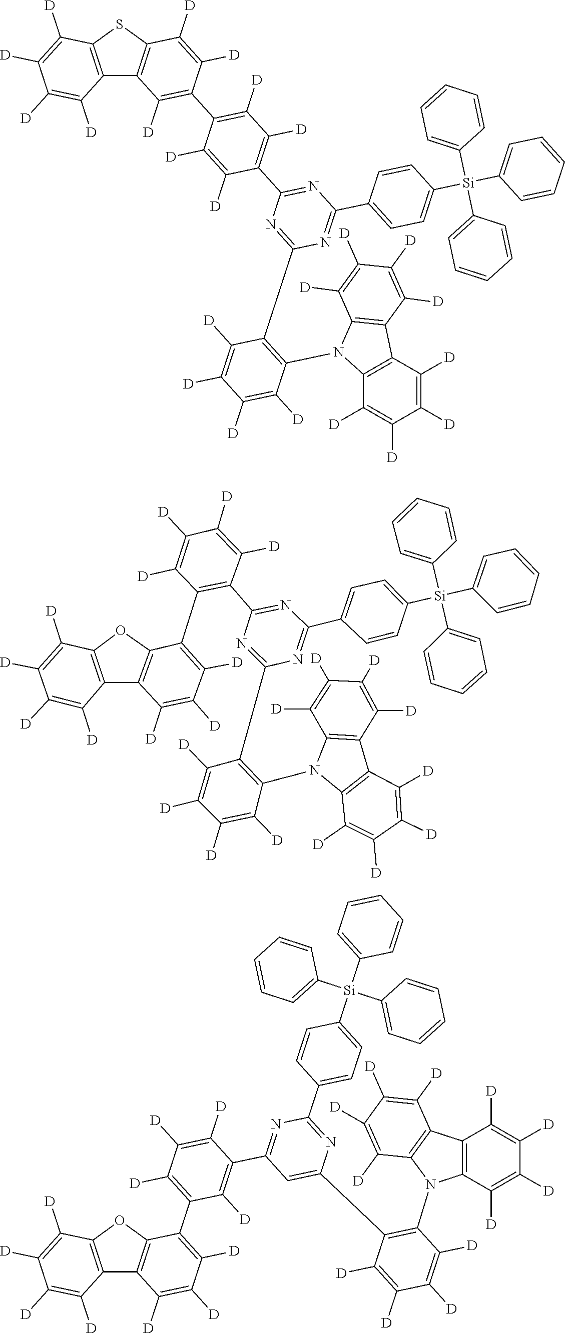

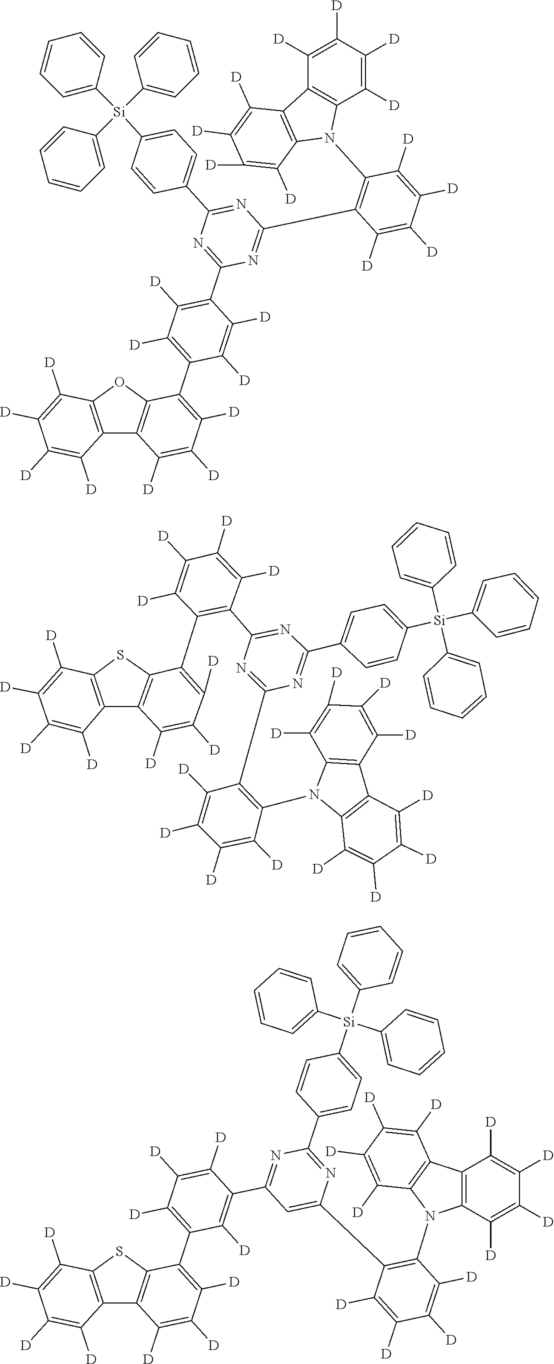

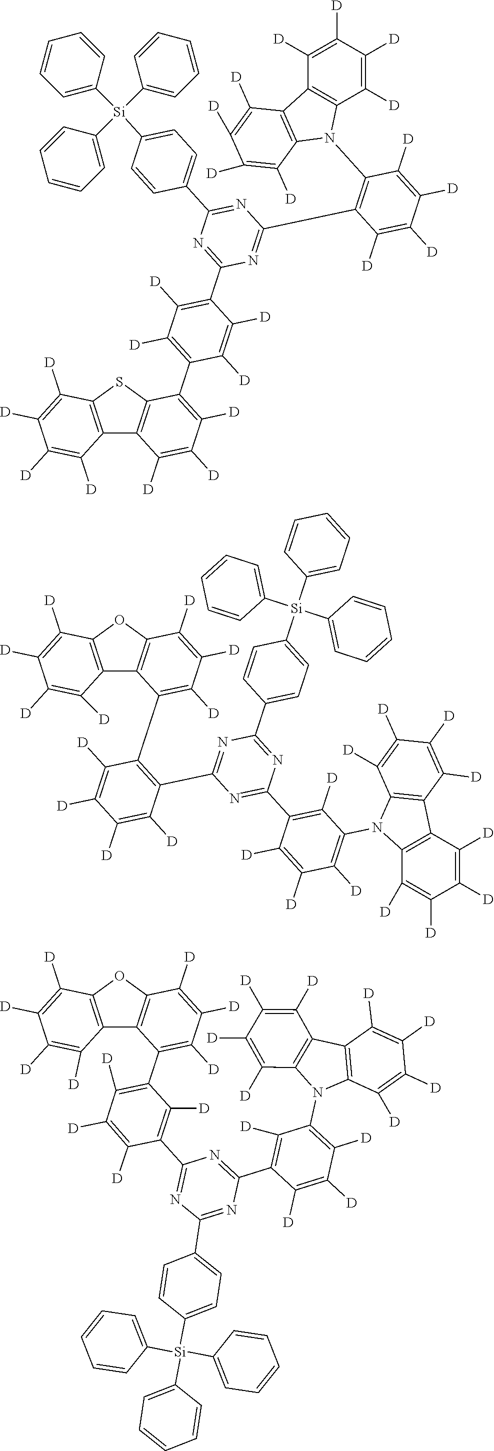

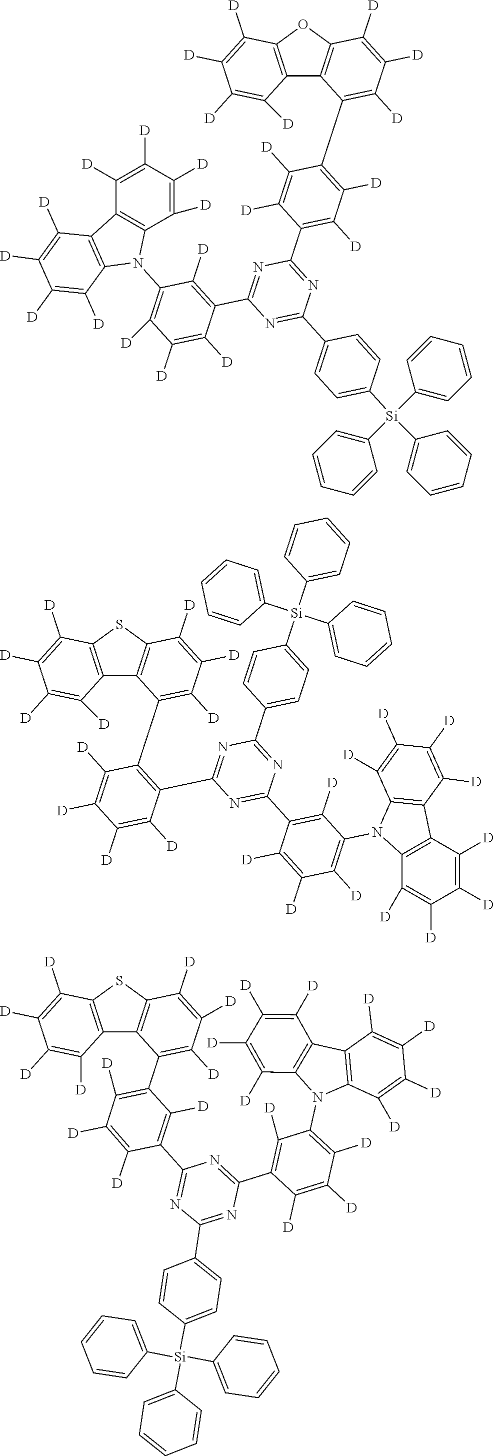

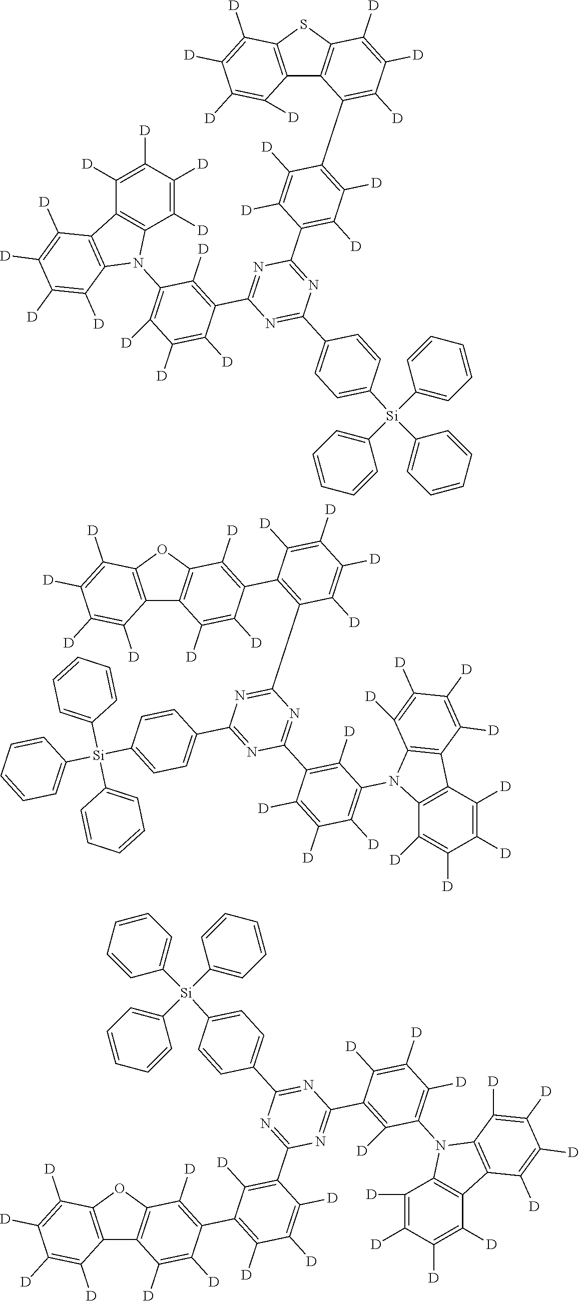

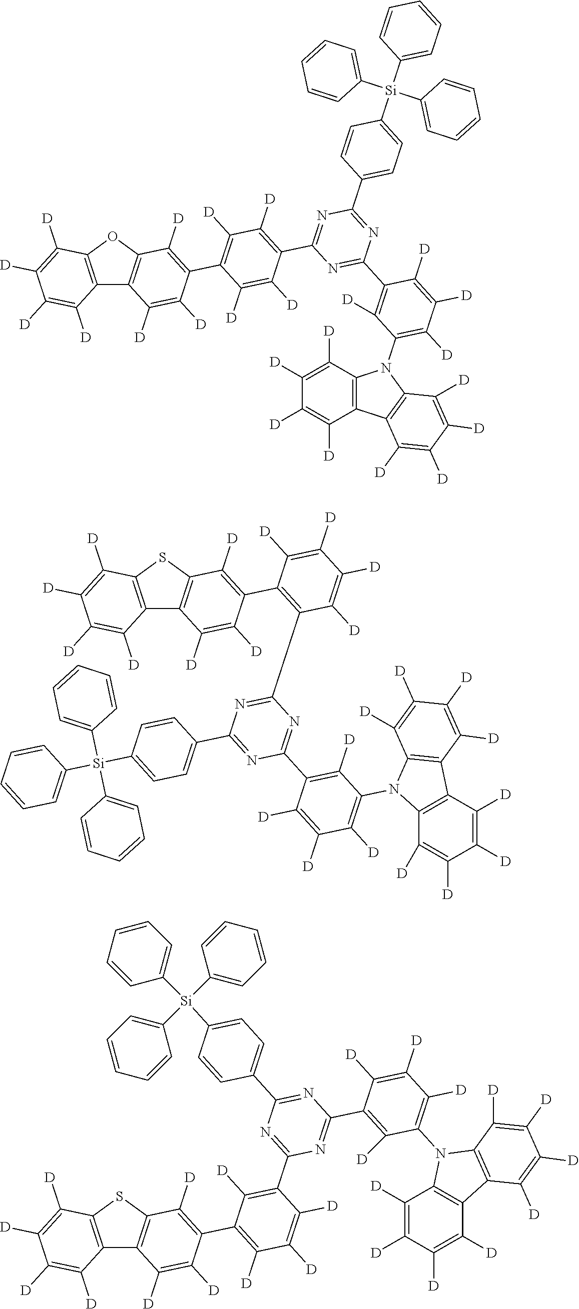

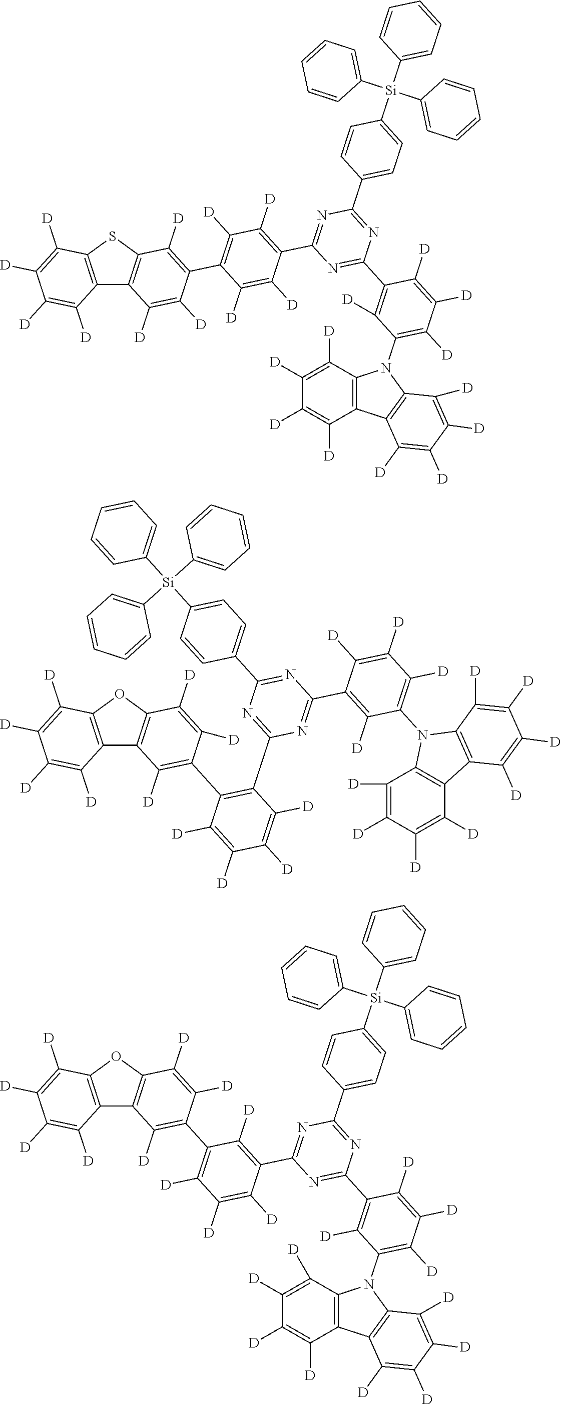

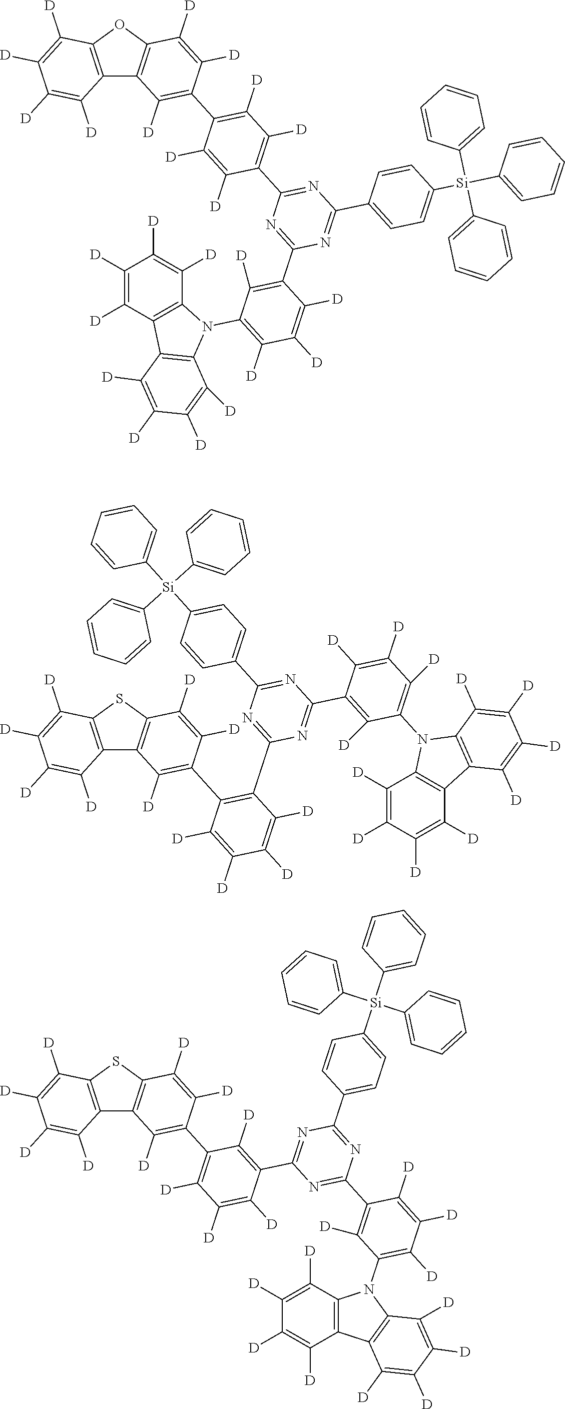

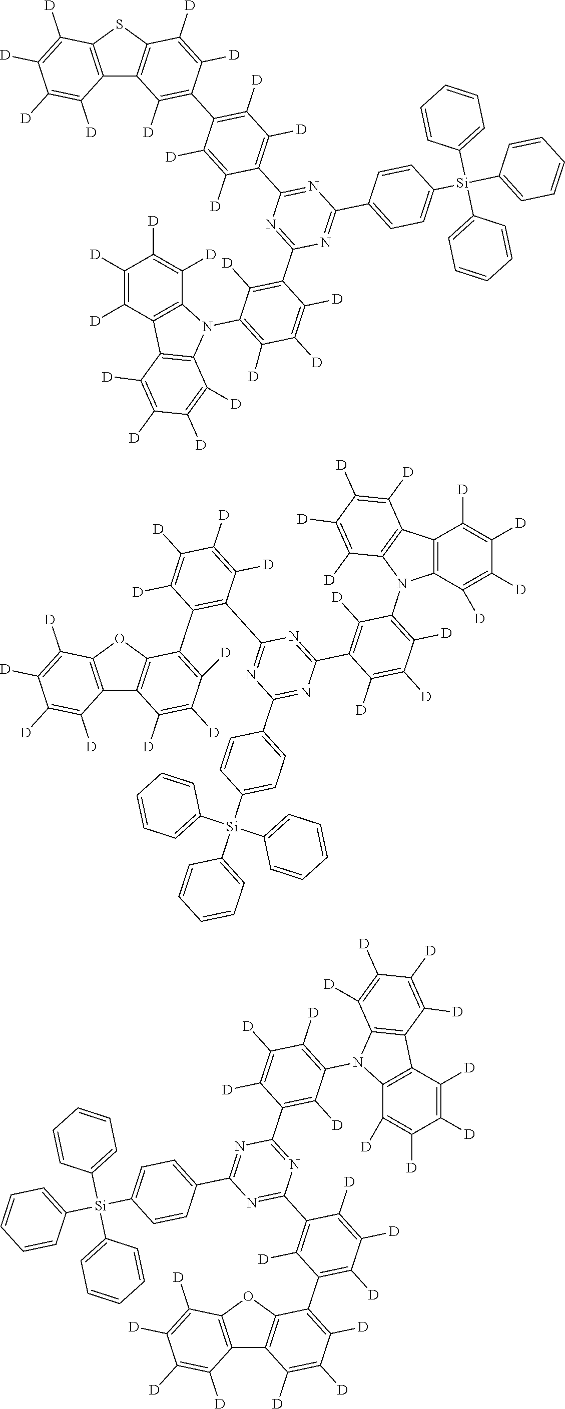

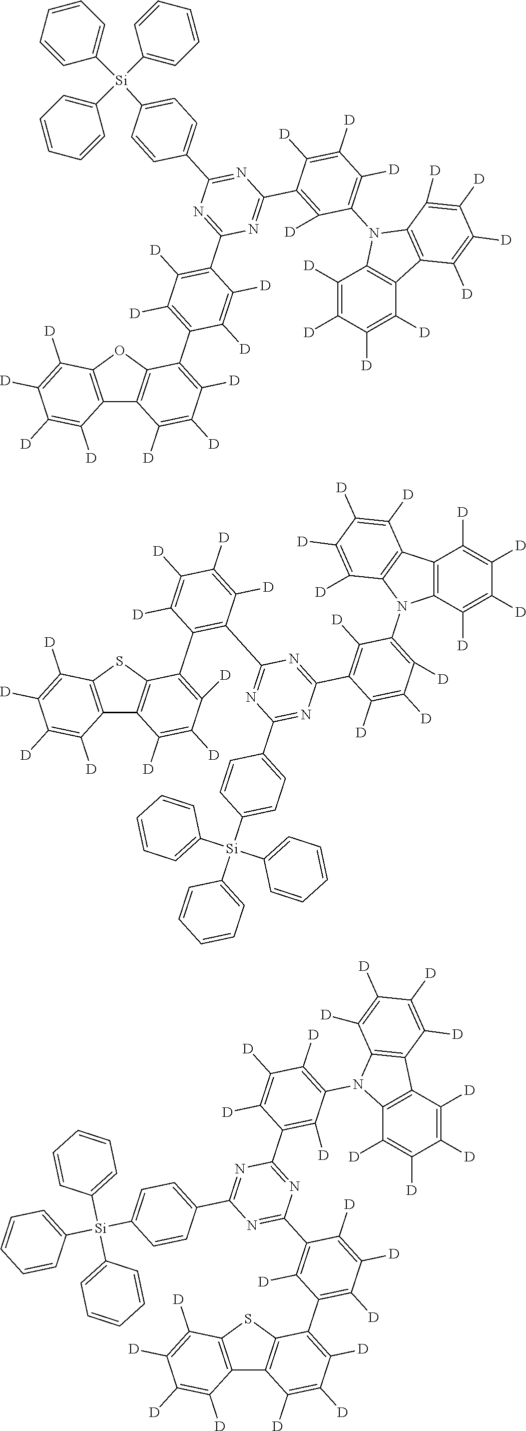

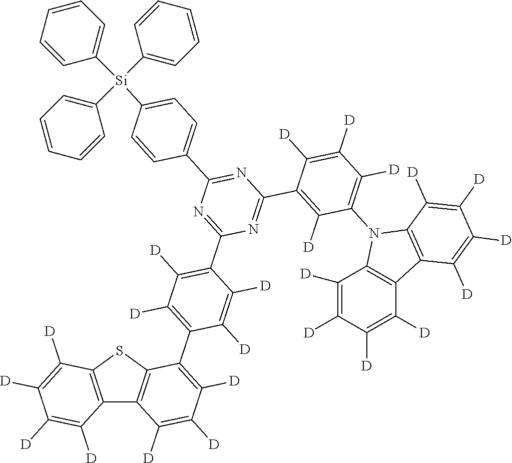 [SMILES: [2H]c1c([2H])c(-c2nc(-c3ccc([Si](c4ccccc4)(c4ccccc4)c4ccccc4)cc3)nc(-c3c([2H])c([2H])c(-c4c([2H])c([2H])c([2H])c5c4sc4c([2H])c([2H])c([2H])c([2H])c45)c([2H])c3[2H])n2)c([2H])c(-n2c3c([2H])c([2H])c([2H])c([2H])c3c3c([2H])c([2H])c([2H])c([2H])c32)c1[2H]]

Further, the present specification provides an organic light emitting device including the above-described compound.

When one member is disposed “on” another member in the present specification, this includes not only a case where the one member is brought into contact with another member, but also a case where still another member is present between the two members.

When one part “includes” one constituent element in the present specification, unless otherwise specifically described, this does not mean that another constituent element is excluded, but means that another constituent element may be further included.

In the present specification, the ‘layer’ has a meaning compatible with a ‘film’ usually used in the art, and means a coating covering a target region. The size of the ‘layer’ is not limited, and the sizes of the respective ‘layers’ may be the same as or different from one another. According to an exemplary embodiment, the size of the ‘layer’ may be the same as that of the entire device, may correspond to the size of a specific functional region, and may also be as small as a single sub-pixel.

In the present specification, when a specific A material is included in a B layer, this means both i) the fact that one or more A materials are included in one B layer and ii) the fact that the B layer is composed of one or more layers, and the A material is included in one or more layers of the multi-layered B layer.

In the present specification, when a specific A material is included in a C layer or a D layer, this means all of i) the fact that the A material is included in one or more layers of the C layer having one or more layers, ii) the fact that the A material is included in one or more layers of the D layer having one or more layers, and iii) the fact that the A material is included in each of the C layer having one or more layers and the D layer having one or more layers.

In the present specification, the n-type is a material capable of stealing electrons from a matrix material (a material of an organic layer), and commonly known materials are used, but the material is not limited thereto. That is, the n-type may be defined as a material that has characteristics capable of providing electrons to the LUMO (lowest unoccupied molecular orbital) energy level of the matrix. Conversely, the p-type is a material that, when one layer is composed of only the p-type material, receives electrons at the highest occupied molecular orbital (HOMO) energy level of the material located in the adjacent cathode direction to generate holes in the adjacent cathode direction material, or a material that, when any matrix is doped with the p-type material, receives electrons from the HOMO of the matrix material and generate holes in the HOMO of the matrix as many as the number of electrons received, and for this purpose, when a layer is formed using only a p-type material, the more adjacent the HOMO level of the material located in the cathode direction is to the LUMO of the p-type material, the more likely it is that electrons are stolen from the HOMO of the adjacent layer and holes are generated in the HOMO of the adjacent layer, and further, when any matrix is doped with the p-type, the more adjacent the LUMO of the p-type material is to the HOMO of the matrix, the more likely it is that electrons are stolen and holes are generated in the matrix.

The present specification provides an organic light emitting device including: a first electrode; a second electrode; and an organic material layer having one or more layers provided between the first electrode and the second electrode, in which one or more layers of the organic material layer include the compound of Chemical Formula 1.

The organic material layer of the organic light emitting device of the present specification may also have a single-layered structure, but may have a multi-layered structure in which two or more organic material layers are stacked. For example, the organic material layer may have a structure including a hole injection layer, a hole transport layer, a light emitting layer, an electron transport layer, an electron injection layer, an electron blocking layer, a hole blocking layer, and the like. However, the structure of the organic light emitting device is not limited thereto, and may include a fewer number of organic layers.

According to an exemplary embodiment of the present specification, the organic material layer includes an electron injection layer, an electron transport layer, or an electron injection and transport layer, and the electron injection layer, electron transport layer, or electron injection and transport layer includes the compound.

According to an exemplary embodiment of the present specification, the organic material layer includes a hole blocking layer, and the hole blocking layer includes the compound.

According to an exemplary embodiment of the present specification, the organic material layer includes a hole injection layer, a hole transport layer, or a hole injection and transport layer.

According to an exemplary embodiment of the present specification, the organic material layer includes an electron blocking layer.

According to an exemplary embodiment of the present specification, the organic material layer includes a light emitting layer, and the light emitting layer includes the compound.

According to an exemplary embodiment of the present specification, the organic material layer includes a light emitting layer, and the light emitting layer includes the compound as a host of the light emitting layer.

According to an exemplary embodiment of the present specification, the organic material layer includes a light emitting layer, and the light emitting layer includes the compound as an n-type host of the light emitting layer.

According to an exemplary embodiment of the present specification, the organic material layer includes a light emitting layer, and the light emitting layer includes the compound as an n-type phosphorescent host of the light emitting layer.

According to an exemplary embodiment of the present specification, the organic material layer includes a light emitting layer, and the light emitting layer includes the compound as a host, and further includes another host.

According to an exemplary embodiment of the present specification, the organic material layer includes a light emitting layer, and the light emitting layer includes the compound as a host, and further includes a host and a dopant.

According to an exemplary embodiment of the present specification, the organic material layer includes a light emitting layer, and the light emitting layer includes the compound as a first host, and further includes a second host.

According to an exemplary embodiment of the present specification, the first host is an n-type phosphorescent host, and the second host is a p-type phosphorescent host.

According to an exemplary embodiment of the present specification, the light emitting layer includes a first host and a second host at a weight ratio of 2:8 to 8:2, and the first host is the compound of Chemical Formula 1.

According to an exemplary embodiment of the present specification, the light emitting layer includes a first host and a second host at a weight ratio of 1:1, and the first host is the compound of Chemical Formula 1.

According to an exemplary embodiment of the present specification, the second host is a dibenzofuran-based compound.

According to an exemplary embodiment of the present specification, the second host is the following Chemical Formula EB-1.

According to an exemplary embodiment of the present specification, the second host is a dibenzofuran-based compound substituted with triazine substituted with a carbazole group.

According to an exemplary embodiment of the present specification, the light emitting layer further includes a dopant.

According to an exemplary embodiment of the present specification, the light emitting layer includes a first host and a second host, and further includes a dopant.

According to an exemplary embodiment of the present specification, the dopant is a phosphorescent dopant.

According to an exemplary embodiment of the present specification, the dopant is included in an amount of 1 to 20 parts by weight with respect to 100 parts by weight of the host.

According to an exemplary embodiment of the present specification, the light emitting layer includes a dopant, and the dopant includes a phosphorescent dopant.

According to an exemplary embodiment of the present specification, the organic material layer includes a light emitting layer, the light emitting layer includes a host and a dopant, the host includes the compound, and the dopant includes the phosphorescent dopant.

According to an exemplary embodiment of the present specification, the light emitting layer is a blue light emitting layer.

According to an exemplary embodiment of the present specification, the light emitting layer includes the host and the dopant at a weight ratio of 99:1 to 1:99. The light emitting layer includes the host and the dopant specifically, at a weight ratio of 99:1 to 50:50, and more specifically, at a weight ratio of 99:1 to 95:5.

When the light emitting layer emits red light, it is possible to use a phosphorescent material such as bis(1-phenylisoquinoline) acetylacetonate iridium (PIQIr (acac)), bis(1-phenylquinoline) acetylacetonate iridium (PQIr (acac)), tris(1-phenylquinoline) iridium (PQIr), or octaethylporphyrin platinum (PtOEP), or a fluorescent material such as tris(8-hydroxyquinolino)aluminum (Alq3) as a light emitting dopant, but the light emitting dopant is not limited thereto. When the light emitting layer emits green light, it is possible to use a phosphorescent material such as fac tris(2-phenylpyridine) iridium (Ir(ppy)₃), or a fluorescent material such as tris(8-hydroxyquinolino)aluminum (Alq₃), as the light emitting dopant, but the light emitting dopant is not limited thereto. When the light emitting layer emits blue light, it is possible to use a platinum complex compound, a phosphorescent material such as (4,6-F2ppy) 2Irpic, or a fluorescent material such as spiro-DPVBi, spiro-6P, distyryl benzene (DSB), distyryl arylene (DSA), a PFO-based polymer or a PPV-based polymer as the light emitting dopant, but the light emitting dopant is not limited thereto.

According to an exemplary embodiment of the present specification, the dopant is a metal complex compound.

According to an exemplary embodiment of the present specification, the dopant is a platinum complex compound.

According to an exemplary embodiment of the present specification, the dopant is an iridium complex compound.

According to an exemplary embodiment of the present specification, the dopant is the following Chemical Formula D-1 or D-2, but is not limited thereto.

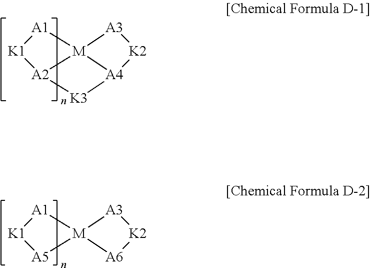

In Chemical Formulae D-1 and D-2,
M is a transition metal,
A1, A3, A5, A6, K1, K2, and K3 are the same as or different from each other, and are each independently a direct bond; O; S; a divalent ester group; a substituted or unsubstituted alkylene group; a substituted or unsubstituted divalent alkenyl group; a substituted or unsubstituted divalent allyl group; a substituted or unsubstituted arylene group; or a substituted or unsubstituted heteroarylene group,
A2 and A4 are the same as or different from each other, and are each independently a direct bond; N; a substituted or unsubstituted trivalent alkylene group; a substituted or unsubstituted trivalent aryl group; or a substituted or unsubstituted trivalent heteroaryl group, and
n is 1 or 2, and when n is 2, structures in the parenthesis are the same as or different from each other.

According to an exemplary embodiment of the present specification, M is iridium or platinum.

According to an exemplary embodiment of the present specification, the dopant may be selected from the following structural formulae, but is not limited thereto.

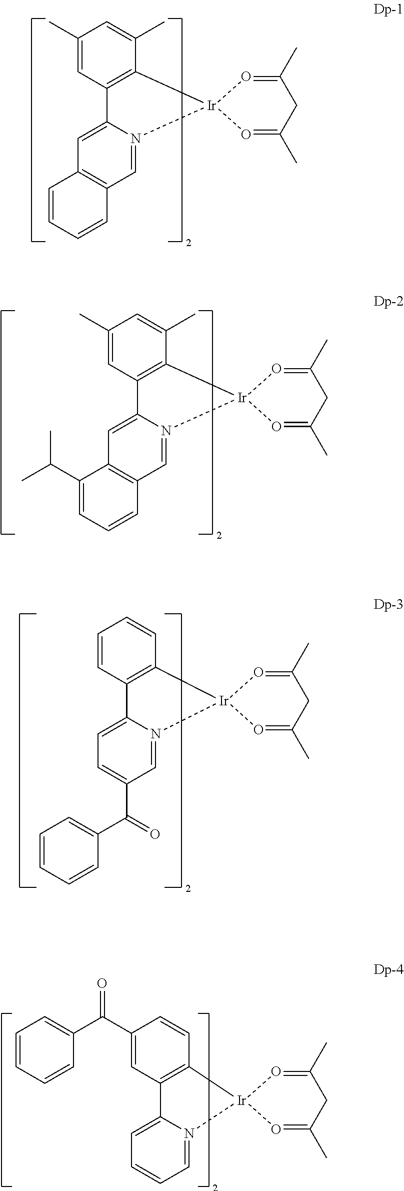

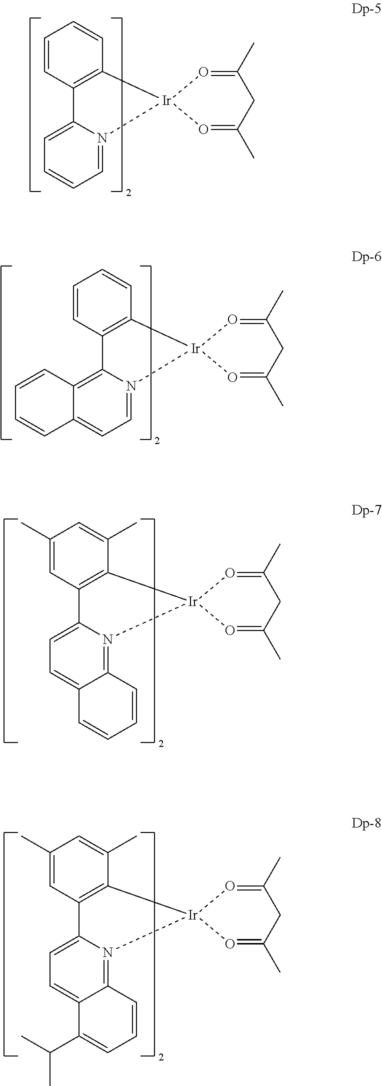

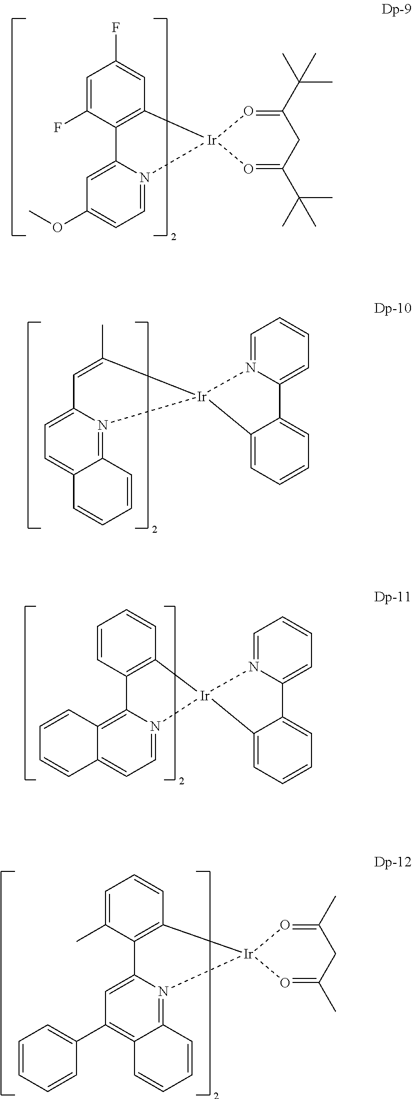

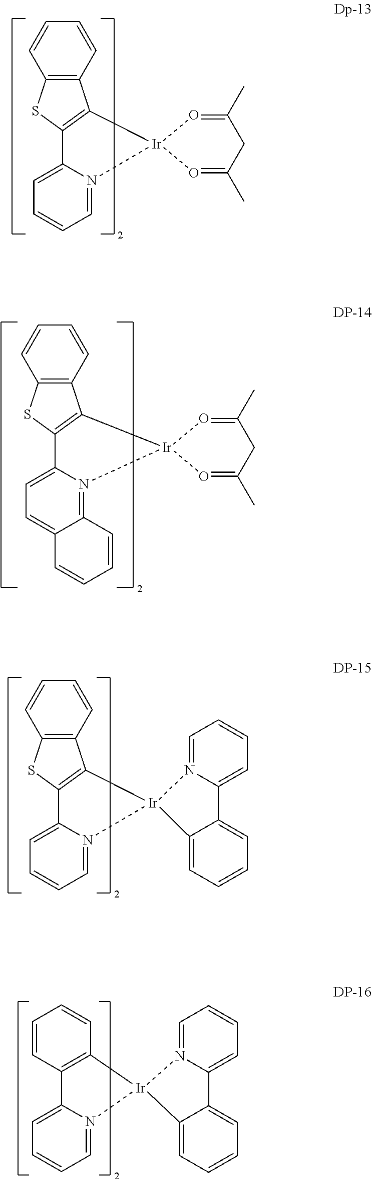

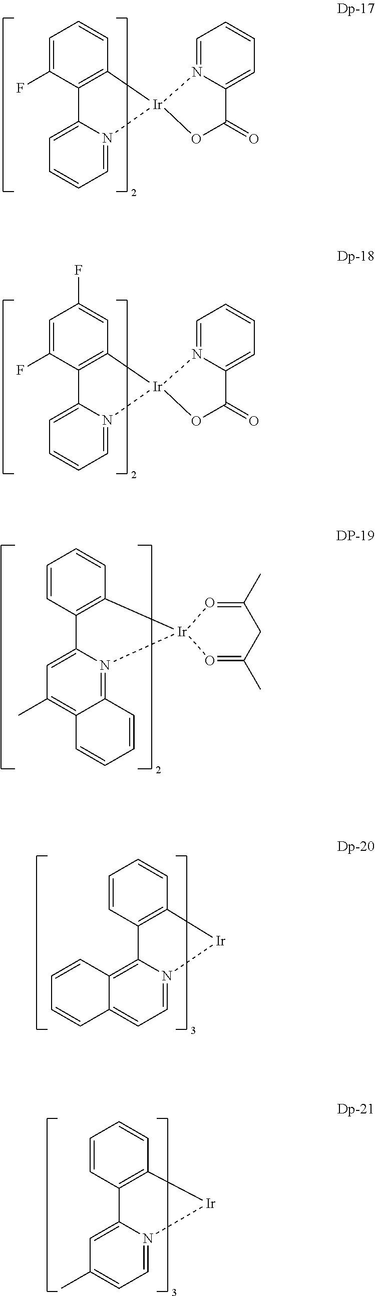

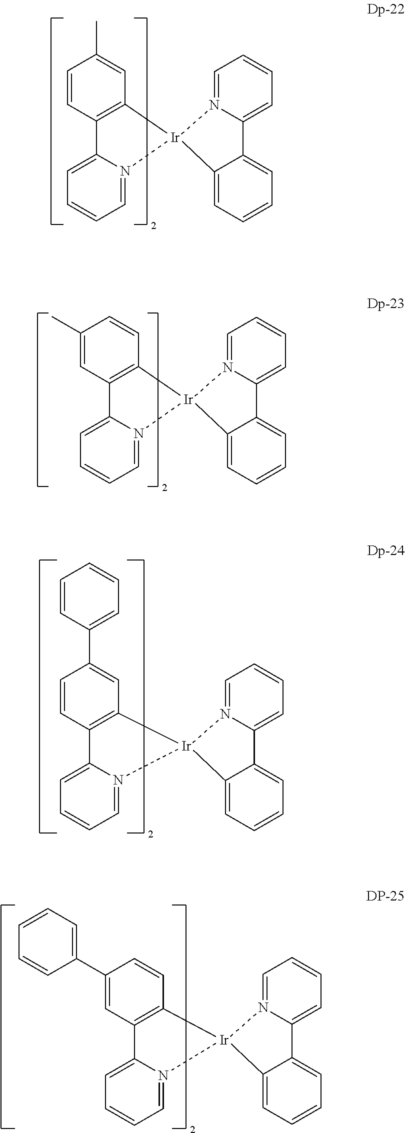

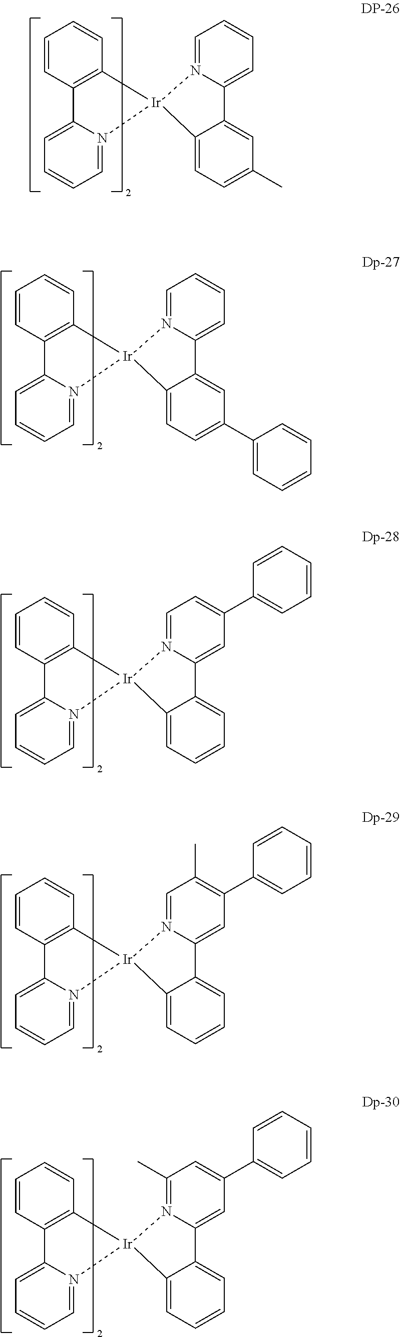

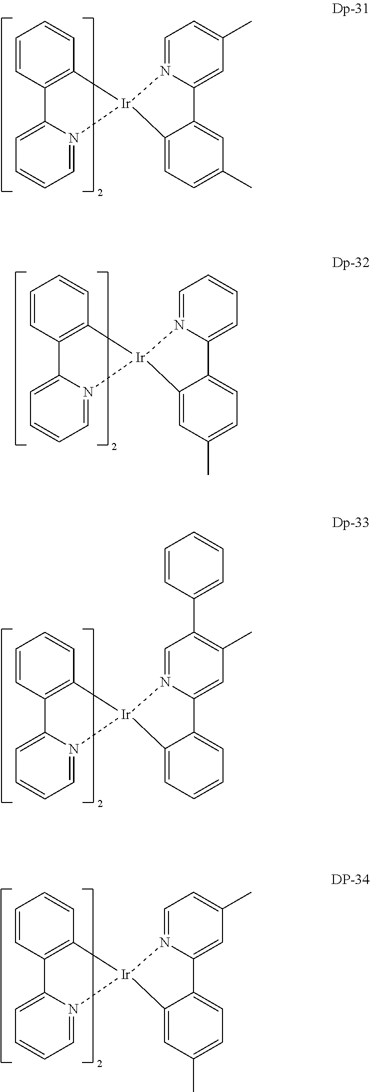

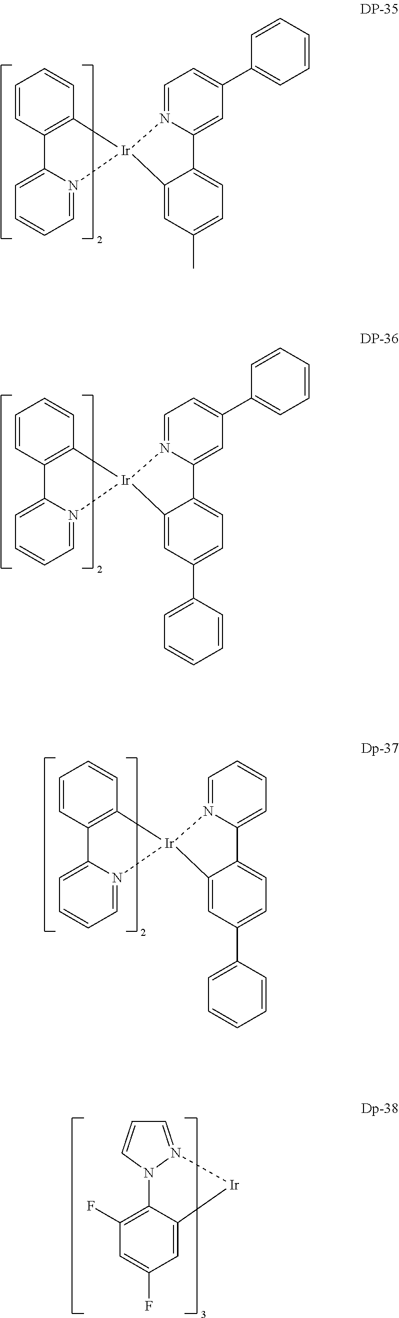

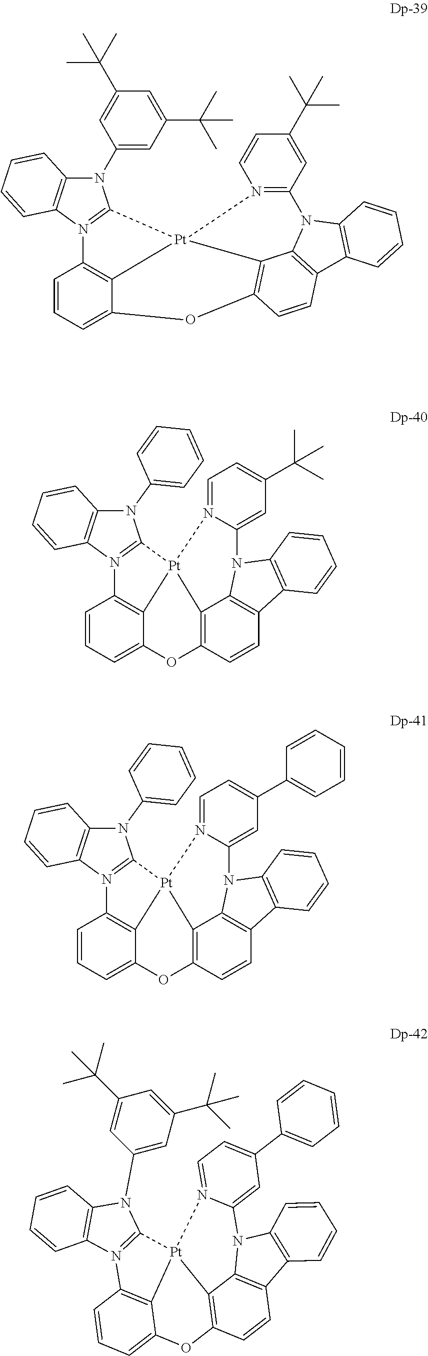

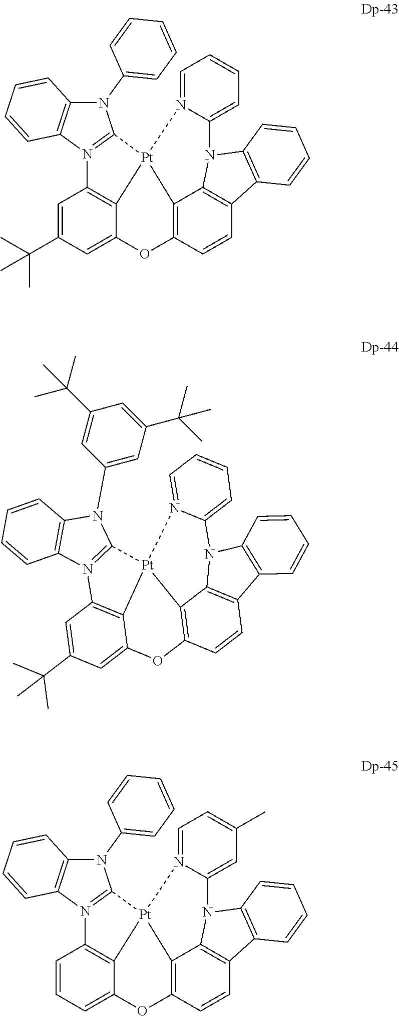

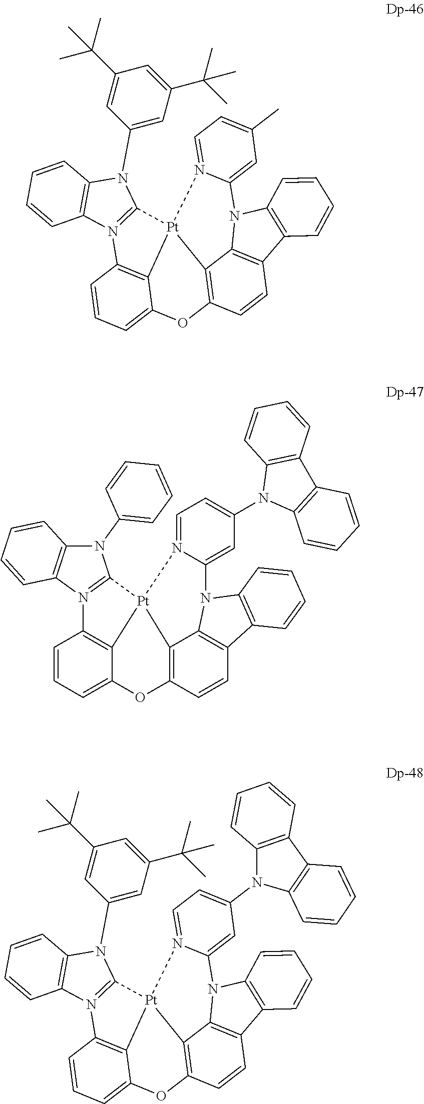

According to an exemplary embodiment of the present specification, the organic material layer includes an electron blocking layer.

According to an exemplary embodiment of the present specification, the organic material layer further includes one or more layers selected from among a hole injection layer, a hole transport layer, a hole injection and transport layer, an electron blocking layer, a light emitting layer, a hole blocking layer, an electron transport layer, an electron injection layer, and an electron injection and transport layer.

According to an exemplary embodiment of the present specification, the organic light emitting device further includes one or two or more layers selected from the group consisting of a hole injection layer, a hole transport layer, a hole injection and transport layer, a light emitting layer, an electron transport layer, an electron injection layer, an electron injection and transport layer, a hole blocking layer, and an electron blocking layer.

According to an exemplary embodiment of the present specification, the organic light emitting device includes: a first electrode; a second electrode provided to face the first electrode; a light emitting layer provided between the first electrode and the second electrode; and an organic material layer having two or more layers provided between the light emitting layer and the first electrode, or between the light emitting layer and the second electrode.

According to an exemplary embodiment of the present specification, as the organic material layer having two or more layers, two or more may be selected from the group consisting of a hole injection layer, a hole transport layer, a hole injection and transport layer, a light emitting layer, an electron transport layer, an electron injection layer, an electron injection and transport layer, a hole blocking layer, and an electron blocking layer.

According to an exemplary embodiment of the present specification, a hole transport layer having two or more layers is included between the light emitting layer and the first electrode. The hole transport layer having two or more layers may include materials which are the same as or different from each other.

According to an exemplary embodiment of the present specification, the first electrode is an anode or a cathode.

According to an exemplary embodiment of the present specification, the second electrode is a cathode or an anode.

According to an exemplary embodiment of the present specification, the organic light emitting device may be a normal type organic light emitting device in which an anode, an organic material layer having one or more layers, and a cathode are sequentially stacked on a substrate.

According to an exemplary embodiment of the present specification, the organic light emitting device may be an inverted type organic light emitting device in which a cathode, an organic material layer having one or more layers, and an anode are sequentially stacked on a substrate.

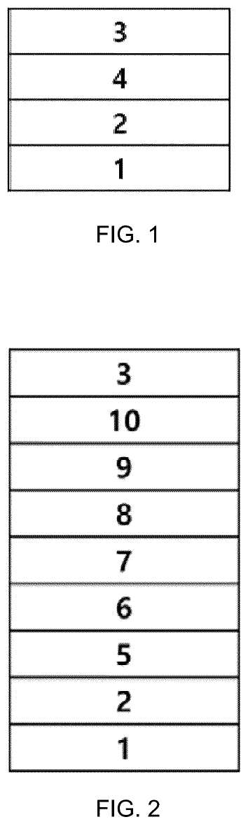

For example, the structure of the organic light emitting device according to an exemplary embodiment of the present specification is exemplified in FIGS. 1 and 2. FIGS. 1 and 2 exemplify an organic light emitting device, and the organic light emitting device is not limited thereto.

FIG. 1 exemplifies a structure of an organic light emitting device in which a first electrode 2, an organic material layer 4, and a second electrode 3 are sequentially stacked on a substrate 1. The compound is included in the organic material layer.

FIG. 2 exemplifies the structure of an organic light emitting device in which a first electrode 2, a hole injection layer 5, a hole transport layer 6, an electron blocking layer 7, a light emitting layer 8, a hole blocking layer 9, an electron injection and transport layer 10, and a second electrode 3 are sequentially stacked on a substrate 1. The compound is included in a hole blocking layer 9 and/or a light emitting layer 8.

The organic light emitting device of the present specification may be manufactured by the materials and methods known in the art, except that the hole blocking layer and/or the light emitting layer include(s) the compound, that is, the compound of Chemical Formula 1.

When the organic light emitting device includes a plurality of organic material layers, the organic material layers may be formed of the same material or different materials.

For example, the organic light emitting device of the present specification may be manufactured by sequentially stacking a first electrode, an organic material layer, and a second electrode on a substrate. In this case, the organic light emitting device of the present application may be manufactured by depositing a metal or a metal oxide having conductivity, or an alloy thereof on a substrate to form an anode, forming an organic material layer including a hole injection layer, a hole transport layer, a light emitting layer, and an electron transport layer thereon, and then depositing a material, which may be used as a negative electrode, thereon, by using a physical vapor deposition (PVD) method such as sputtering or e-beam evaporation. In addition to the method described above, an organic light emitting device may be manufactured by sequentially depositing a cathode material, an organic material layer, and an anode material on a substrate.

Further, the compound of Chemical Formula 1 may be formed as an organic material layer by not only a vacuum deposition method, but also a solution application method when an organic light emitting device is manufactured. Here, the solution application method means spin coating, dip coating, doctor blading, inkjet printing, screen printing, a spray method, roll coating, and the like, but is not limited thereto.

In addition to the method described above, an organic light emitting device may be made by sequentially depositing a cathode material, an organic material layer, and an anode material on a substrate. However, the manufacturing method is not limited thereto.

As the anode material, materials having large work function are normally preferred so that hole injection to an organic material layer is smooth. Examples thereof include: a metal, such as vanadium, chromium, copper, zinc, and gold, or an alloy thereof; a metal oxide, such as zinc oxide, indium oxide, indium tin oxide (ITO), and indium zinc oxide (IZO); a combination of a metal and an oxide, such as Zno:Al or SnO₂:Sb; a conductive polymer, such as poly(3-methylthiophene), poly [3,4-(ethylene-1,2-dioxy)thiophene] (PEDOT), polypyrrole, and polyaniline; and the like, but are not limited thereto.

As the cathode material, materials having a low work function are usually preferred so as to facilitate the injection of electrons into an organic material layer. Examples thereof include: a metal, such as magnesium, calcium, sodium, potassium, titanium, indium, yttrium, lithium, gadolinium, aluminum, silver, tin, and lead, or an alloy thereof; a multi-layer structured material, such as LiF/Al or LiO₂/Al; and the like, but are not limited thereto.

The light emitting layer may include a host material and a dopant material. When the organic light emitting device according to an exemplary embodiment of the present specification includes an additional light emitting layer other than a light emitting layer including Chemical Formula 1, examples of a host material include a fused aromatic ring derivative, a hetero ring-containing compound, and the like. Specific examples of the fused aromatic ring derivative include anthracene derivatives, pyrene derivatives, naphthalene derivatives, pentacene derivatives, phenanthrene compounds, fluoranthene compounds, and the like, and specific examples of the hetero ring-containing compound include dibenzofuran derivatives, ladder-type furan compounds, pyrimidine derivatives, and the like, but the examples are not limited thereto.

Examples of the dopant material include an aromatic amine derivative, a styrylamine compound, a boron complex, a fluoranthene compound, a metal complex, and the like. Specifically, the aromatic amine derivative is a fused aromatic ring derivative having a substituted or unsubstituted arylamine group, and examples thereof include pyrene, anthracene, chrysene, periflanthene, and the like having an arylamine group. Further, the styrylamine compound is a compound in which a substituted or unsubstituted arylamine is substituted with at least one arylvinyl group, and one or two or more substituents selected from the group consisting of an aryl group, a silyl group, an alkyl group, a cycloalkyl group, and an arylamine group are substituted or unsubstituted. Specific examples thereof include styrylamine, styryldiamine, styryltriamine, styryltetramine, and the like, but are not limited thereto. Further, examples of the metal complex include an iridium complex, a platinum complex, and the like, but are not limited thereto.

The hole injection layer is a layer which accepts holes from an electrode. It is preferred that hole injection material has an ability to transport holes, and has an effect of accepting holes from an anode and an excellent hole injection effect for a light emitting layer or a light emitting material. Further, the hole injection material is preferably a material which is excellent in ability to prevent excitons produced from a light emitting layer from moving to an electron injection layer or an electron injection material. In addition, the hole injection material is preferably a material which is excellent in ability to form a thin film. In addition, the highest occupied molecular orbital (HOMO) of the hole injection material is preferably a value between the work function of the anode material and the HOMO of the neighboring organic material layer. Specific examples of the hole injection material include: metal porphyrin, oligothiophene, and arylamine-based organic materials; hexanitrile hexaazatriphenylene-based organic materials; quinacridone-based organic materials; perylene-based organic materials; polythiophene-based conductive polymers such as anthraquinone and polyaniline; and the like, but are not limited thereto.

According to an exemplary embodiment of the present specification, the hole injection layer includes a compound represented by the following Chemical Formula HI-1, but is not limited thereto.

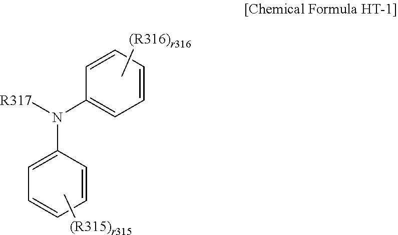

In Chemical Formula HI-1,
R315 to R317 are the same as or different from each other, and are each independently any one selected from the group consisting of hydrogen, deuterium, a substituted or unsubstituted alkyl group, a substituted or unsubstituted aryl group, a substituted or unsubstituted heteroaryl group, and a combination thereof, or are bonded to an adjacent group to form a substituted or unsubstituted ring,
r315 is an integer from 1 to 5, and when r315 is 2 or higher, two or more R315s are the same as or different from each other, and
r316 is an integer from 1 to 5, and when r316 is 2 or higher, two or more R316s are the same as or different from each other.

According to an exemplary embodiment of the present specification, R317 is any one selected from the group consisting of a substituted or unsubstituted aryl group; a substituted or unsubstituted heteroaryl group; and a combination thereof.

According to an exemplary embodiment of the present specification, R317 is any one selected from the group consisting of a carbazole group, a phenyl group, a biphenyl group, a triphenylene group, and a combination thereof.

According to an exemplary embodiment of the present specification, R315 and R316 are the same as or different from each other, and are each independently a substituted or unsubstituted aryl group, or are bonded to an adjacent group to form an aromatic hydrocarbon ring substituted with an aryl group or an alkyl group.

According to an exemplary embodiment of the present specification, R315 and R316 are the same as or different from each other, and are each independently a phenyl group or a biphenyl group, or are bonded to an adjacent group to form indene substituted with a phenyl group or a methyl group.

According to an exemplary embodiment of the present specification, Chemical Formula HI-1 is represented by any one of the following compounds.

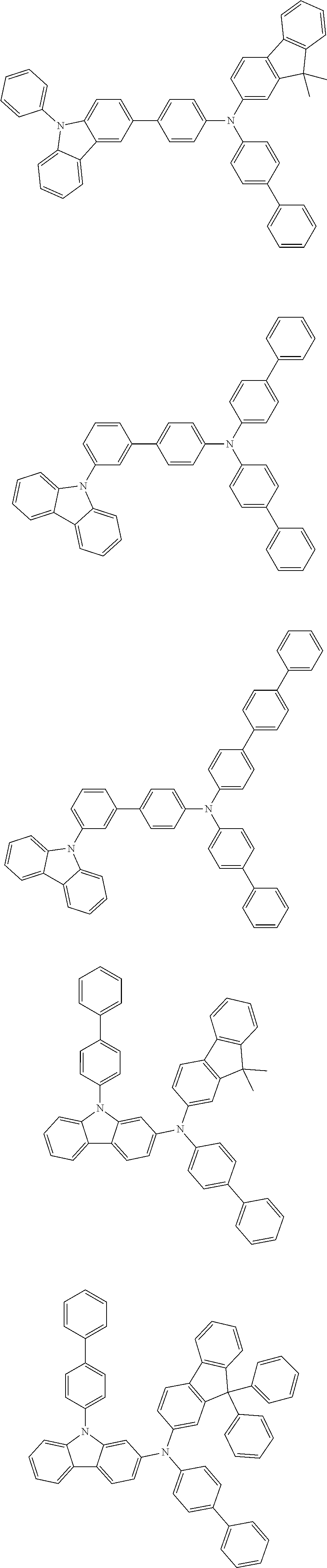 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(N(c3ccc(-c4ccccc4)cc3)c3ccc(-c4cccc(-n5c6ccccc6c6ccccc65)c4)cc3)cc2)cc1 ; c1ccc(-c2ccc(-c3ccc(N(c4ccc(-c5ccccc5)cc4)c4ccc(-c5cccc(-n6c7ccccc7c7ccccc76)c5)cc4)cc3)cc2)cc1 ; CC1(C)c2ccccc2-c2ccc(N(c3ccc(-c4ccccc4)cc3)c3ccc4c5ccccc5n(-c5ccc(-c6ccccc6)cc5)c4c3)cc21 ; c1ccc(-c2ccc(N(c3ccc4c(c3)C(c3ccccc3)(c3ccccc3)c3ccccc3-4)c3ccc4c5ccccc5n(-c5ccc(-c6ccccc6)cc5)c4c3)cc2)cc1]

According to an exemplary embodiment of the present specification, the hole injection layer includes a compound represented by the following Chemical Formula HI-2, but is not limited thereto.

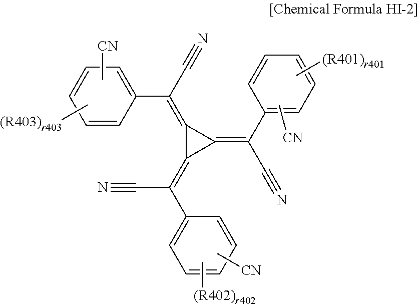

In Chemical Formula HI-2,
R401 to R403 are the same as or different from each other, and are each independently a halogen group, and
r401 to r403 are 4.

According to an exemplary embodiment of the present specification, R401 to R403 are F.

According to an exemplary embodiment of the present specification, Chemical Formula HI-2 is represented by the following compound.

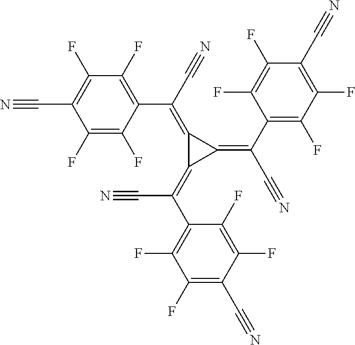 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

According to an exemplary embodiment of the present specification, the hole injection layer includes Chemical Formulae HI-1 and HI-2.

According to an exemplary embodiment of the present specification, the hole injection layer includes Chemical Formulae HI-1 and HI-2 at a weight ratio of 1:99 to 99:1.

The hole transport layer is a layer which accepts holes from a hole injection layer and transports the holes to a light emitting layer. A hole transport material is preferably a material having high hole mobility which may accept holes from an anode or a hole injection layer and transfer the holes to a light emitting layer. Specific examples thereof include arylamine-based organic materials, conductive polymers, block copolymers having both conjugated portions and non-conjugated portions, and the like, but are not limited thereto.

According to an exemplary embodiment of the present specification, the hole transport layer includes the compound represented by Chemical Formula HI-1, but is not limited thereto.

According to an exemplary embodiment of the present specification, the hole injection and transport layer is a layer that transports holes to the light emitting layer. Materials exemplified for the hole transport layer and the hole injection layer may be used, but the materials are not limited thereto.

The electron transport layer is a layer which accepts electrons from an electron injection layer and transports the electrons to a light emitting layer. When the organic light emitting device includes an electron transport layer other than the electron transport layer including the compound of Chemical Formula 1, an electron transport material is preferably a material having high electron mobility which may proficiently accept electrons from a cathode and transfer the electrons to a light emitting layer. Specific examples thereof include: Al complexes of 8-hydroxyquinoline; complexes including Alq₃; organic radical compounds; hydroxyflavone-metal complexes; and the like, but are not limited thereto. The electron transport layer may be used with any desired cathode material, as used according to the related art. In particular, an appropriate cathode material is a typical material which has a low work function, followed by an aluminum layer or a silver layer. Specific examples thereof include cesium, barium, calcium, ytterbium, and samarium, in each case followed by an aluminum layer or a silver layer.

The electron injection layer is a layer which accepts electrons from an electrode. It is preferred that an electron injection material is excellent in ability to transport electrons and has an effect of accepting electrons from the second electrode and an excellent electron injection effect for a light emitting layer or a light emitting material. Further, the electron injection material is preferably a material which prevents excitons produced from a light emitting layer from moving to a hole injection layer and is excellent in ability to form a thin film. When the organic light emitting device includes an electron injection layer other than the electron injection layer including the compound of Chemical Formula 1, specific examples thereof include fluorenone, anthraquinodimethane, diphenoquinone, thiopyran dioxide, oxazole, oxadiazole, triazole, imidazole, perylenetetracarboxylic acid, fluorenylidene methane, anthrone, and the like, and derivatives thereof, metal complex compounds, nitrogen-containing 5-membered ring derivatives, and the like, but are not limited thereto.

Examples of the metal complex compounds include 8-hydroxyquinolinato lithium, bis(8-hydroxyquinolinato) zinc, bis(8-hydroxyquinolinato) copper, bis(8-hydroxyquinolinato) manganese, tris(8-hydroxyquinolinato) aluminum, tris(2-methyl-8-hydroxyquinolinato) aluminum, tris(8-hydroxyquinolinato) gallium, bis(10-hydroxybenzo[h] quinolinato) beryllium, bis(10-hydroxybenzo[h] quinolinato) zinc, bis(2-methyl-8-quinolinato) chlorogallium, bis(2-methyl-8-quinolinato) (o-cresolato) gallium, bis(2-methyl-8-quinolinato) (1-naphtholato) aluminum, bis(2-methyl-8-quinolinato) (2-naphtholato) gallium, and the like, but are not limited thereto.

According to an exemplary embodiment of the present specification, the electron injection and transport layer is a layer that transports electrons to the light emitting layer. When the organic light emitting device includes an electron injection and transport layer other than the electron injection and transport layer including the compound of Chemical Formula 1, the materials exemplified for the electron transport layer and the electron injection layer may be used, but are not limited thereto.

According to an exemplary embodiment of the present specification, the electron injection and transport layer includes a compound represented by the following Chemical Formula ET-1, but is not limited thereto.

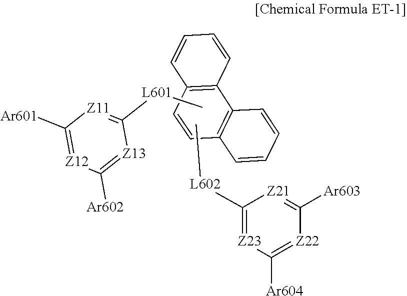

In Chemical Formula ET-1,
at least one of Z11 to Z13 is N, and the others are CH,
at least one of Z21 to Z23 is N, and the others are CH,
L601 and L602 are the same as or different from each other, and are each independently a direct bond; a substituted or unsubstituted arylene group; or a substituted or unsubstituted heteroarylene group, and
Ar601 to Ar604 are the same as or different from each other, and are each independently a substituted or unsubstituted aryl group; or a substituted or unsubstituted heteroaryl group.

According to an exemplary embodiment of the present specification, L601 and L602 are the same as or different from each other, and are each independently a substituted or unsubstituted monocyclic or polycyclic arylene group having 6 to 30 carbon atoms.

According to an exemplary embodiment of the present specification, L601 and L602 are a phenylene group.

According to an exemplary embodiment of the present specification, Ar601 to Ar604 are the same as or different from each other, and are each independently a substituted or unsubstituted monocyclic or polycyclic aryl group having 6 to 30 carbon atoms.

According to an exemplary embodiment of the present specification, Ar601 to Ar604 are a phenyl group.

According to an exemplary embodiment of the present specification, Chemical Formula ET-1 is represented by the following compound.

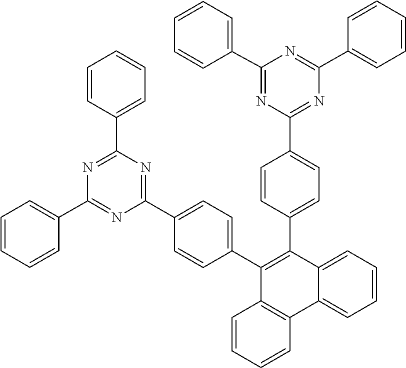 [SMILES: c1ccc(-c2nc(-c3ccccc3)nc(-c3ccc(-c4c(-c5ccc(-c6nc(-c7ccccc7)nc(-c7ccccc7)n6)cc5)c5ccccc5c5ccccc45)cc3)n2)cc1]

According to an exemplary embodiment of the present specification, the electron injection and transport layer may further include a metal complex compound. The metal complex compound is as described above.

The electron blocking layer is a layer which may improve the service life and efficiency of a device by preventing electrons injected from an electron injection layer from passing through a light emitting layer and entering a hole injection layer. For the electron blocking layer, any known material can be used without limitation, and the materials exemplified in the description of the hole injection layer may be used, but the material is not limited thereto. The electron blocking layer may be formed between a light emitting layer and a hole transport layer, between a light emitting layer and a hole injection layer, or between a light emitting layer and a layer which simultaneously injects and transports holes.

According to an exemplary embodiment of the present specification, the electron blocking layer includes a compound represented by the following Chemical Formula EB-1, but is not limited thereto.

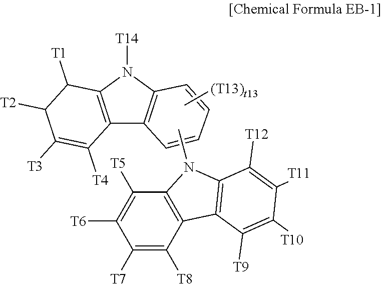

In Chemical Formula EB-1,
T1 to T14 are the same as or different from each other, and are each independently hydrogen, deuterium, a substituted or unsubstituted aryl group, or a substituted or unsubstituted heteroaryl group, and
t13 is an integer from 1 to 3, and when t13 is 2 or higher, two or more t13s are the same as or different from each other.

According to an exemplary embodiment of the present specification, T1 to T14 are the same as or different from each other, and are each independently hydrogen, deuterium, or a monocyclic or polycyclic aryl group having 6 to 30 carbon atoms.

According to an exemplary embodiment of the present specification, T1 to T14 are the same as or different from each other, and are each independently hydrogen, deuterium, or a monocyclic or polycyclic aryl group having 6 to 20 carbon atoms.

According to an exemplary embodiment of the present specification, T1 to T14 are the same as or different from each other, and are each independently hydrogen, deuterium, a phenyl group, a biphenyl group, or a naphthyl group.

According to an exemplary embodiment of the present specification, T1 to T13 are the same as or different from each other, and are each independently hydrogen or deuterium.

According to an exemplary embodiment of the present specification, T14 is a monocyclic or polycyclic aryl group having 6 to 30 carbon atoms.

According to an exemplary embodiment of the present specification, T14 is a monocyclic or polycyclic aryl group having 6 to 20 carbon atoms.

According to an exemplary embodiment of the present specification, T14 is a phenyl group, a biphenyl group, or a naphthyl group.

According to an exemplary embodiment of the present specification, Chemical Formula EB-1 may include the following compound, but is not limited thereto.

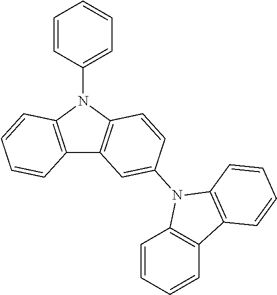 [SMILES: c1ccc(-n2c3ccccc3c3cc(-n4c5ccccc5c5ccccc54)ccc32)cc1]

According to an exemplary embodiment of the present specification, Chemical Formula EB-1 may also be used as a second host material of the light emitting layer.

The hole blocking layer is a layer which blocks holes from reaching a cathode, and may be generally formed under the same conditions as those of the electron injection layer. When the organic light emitting device according to an exemplary embodiment of the present specification includes an additional hole blocking layer other than the hole blocking layer including Chemical Formula 1, specifically, an oxadiazole derivative or a triazole derivative, a phenanthroline derivative, an aluminum complex, and the like are used, but are not limited thereto.

According to an exemplary embodiment of the present specification, Chemical Formula EB-1 may also be used as a second host material of the light emitting layer.

The organic light emitting device according to the present specification may be a top-emission type, a bottom-emission type or a dual-emission type depending on the materials used.

The organic light emitting device according to the present specification may be included and used in various electronic devices. For example, the electronic device may be a display panel, a touch panel, a solar module, a lighting device, and the like, and is not limited thereto.

Hereinafter, the present specification will be described in detail with reference to Examples, Comparative Examples, and the like for specifically describing the present specification. However, the Examples and the Comparative Examples according to the present specification may be modified in various forms, and it is not interpreted that the scope of the present specification is limited to the Examples and the Comparative Examples described below in detail. The Examples and the Comparative Examples of the present specification are provided to more completely explain the present specification to a person with ordinary skill in the art.

### <Preparation Example 1> Synthesis of Compound 1

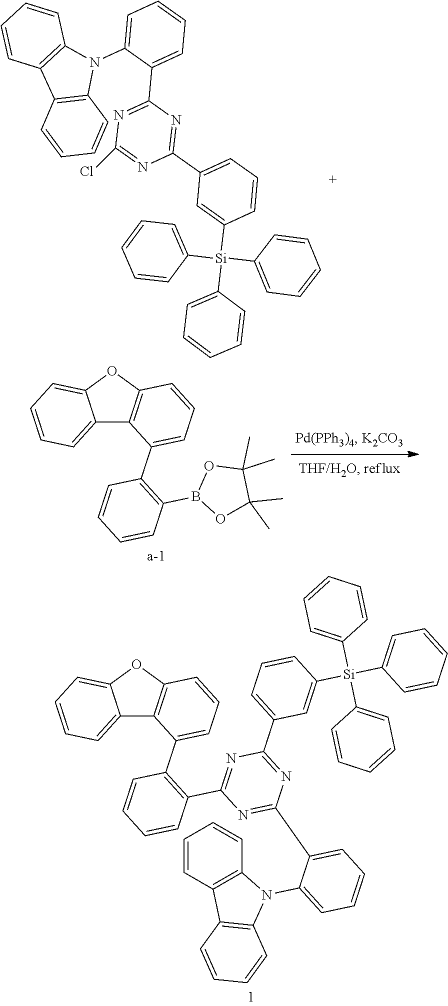

A compound 9-(2-(4-chloro-6-(3-(triphenylsilyl)phenyl)-1,3,5-triazin-2-yl)phenyl)-9H-carbazole (4.50 g, 6.51 mmol) and Compound a-1 (2.77 g, 7.49 mmol) were completely dissolved in 240 mL of tetrahydrofuran in a 500-mL round bottom flask under a nitrogen atmosphere, and then an aqueous 2 M potassium carbonate solution (120 mL) was added thereto, tetrakis-(triphenylphosphine) palladium (0.23 g, 0.20 mmol) was put thereinto, and then the resulting mixture was heated and stirred for 6 hours. The temperature was lowered to room temperature, the aqueous layer was removed, and the residue was dried over anhydrous magnesium sulfate, and then concentrated under reduced pressure, and recrystallized with 360 mL of ethyl acetate to prepare Compound 1 (3.33 g, 57%).

MS[M+H]⁺=900

### <Preparation Example 2> Synthesis of Compound 2

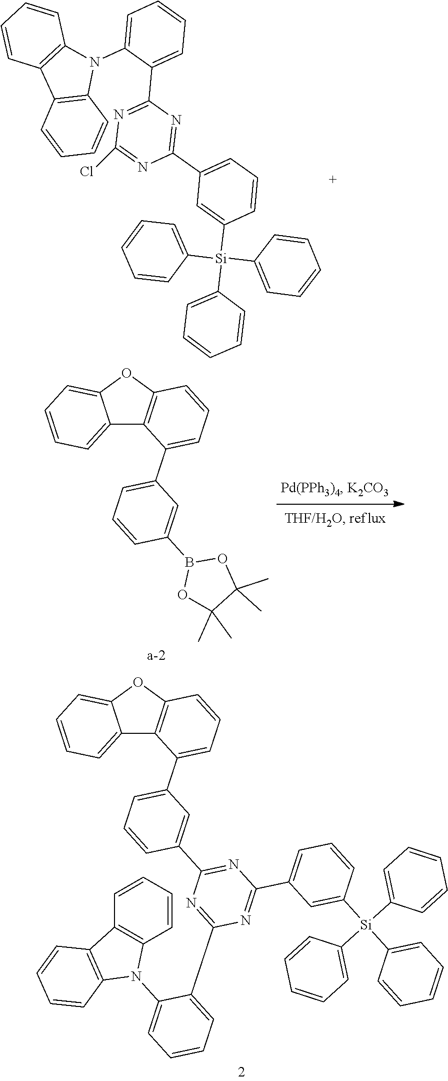

A compound 9-(2-(4-chloro-6-(3-(triphenylsilyl)phenyl)-1,3,5-triazin-2-yl)phenyl)-9H-carbazole (4.50 g, 6.51 mmol) and Compound a-2 (2.77 g, 7.49 mmol) were completely dissolved in 240 mL of tetrahydrofuran in a 500-mL round bottom flask under a nitrogen atmosphere, and then an aqueous 2 M potassium carbonate solution (120 mL) was added thereto, tetrakis-(triphenylphosphine) palladium (0.23 g, 0.20 mmol) was put thereinto, and then the resulting mixture was heated and stirred for 5 hours. The temperature was lowered to room temperature, the aqueous layer was removed, and the residue was dried over anhydrous magnesium sulfate, and then concentrated under reduced pressure, and recrystallized with 370 mL of ethyl acetate to prepare Compound 2 (3.59 g, 61%).

MS[M+H]⁺=900

### <Preparation Example 3> Synthesis of Compound 3

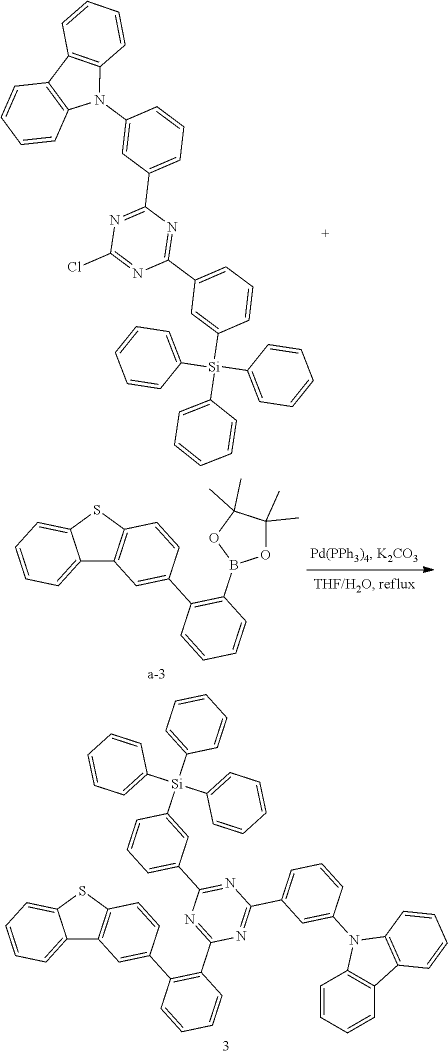

A compound 9-(3-(4-chloro-6-(3-(triphenylsilyl)phenyl)-1,3,5-triazin-2-yl)phenyl)-9H-carbazole (4.50 g, 6.51 mmol) and Compound a-3 (2.89 g, 7.49 mmol) were completely dissolved in 240 mL of tetrahydrofuran in a 500-mL round bottom flask under a nitrogen atmosphere, and then an aqueous 2 M potassium carbonate solution (120 mL) was added thereto, tetrakis-(triphenylphosphine) palladium (0.23 g, 0.20 mmol) was put thereinto, and then the resulting mixture was heated and stirred for 7 hours. The temperature was lowered to room temperature, the aqueous layer was removed, and the residue was dried over anhydrous magnesium sulfate, and then concentrated under reduced pressure, and recrystallized with 350 mL of ethyl acetate to prepare Compound 3 (3.77 g, 63%).

MS[M+H]⁺=916

### <Preparation Example 4> Synthesis of Compound 4

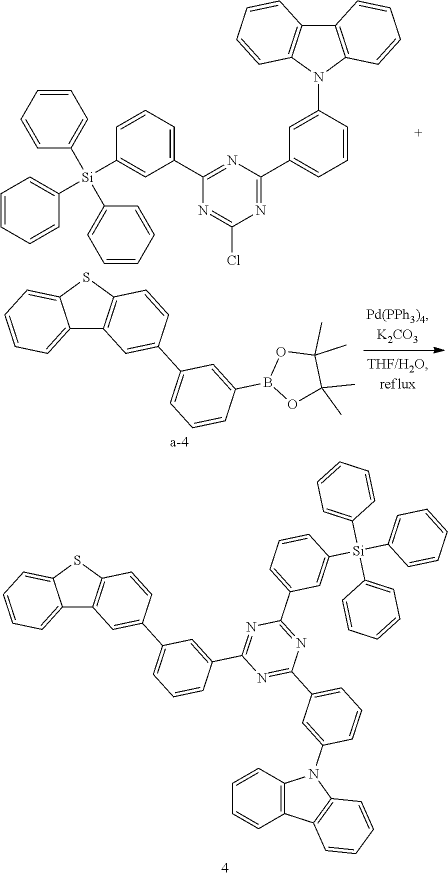

A compound 9-(3-(4-chloro-6-(3-(triphenylsilyl)phenyl)-1,3,5-triazin-2-yl)phenyl)-9H-carbazole (4.50 g, 6.51 mmol) and Compound a-4 (2.89 g, 7.49 mmol) were completely dissolved in 240 mL of tetrahydrofuran in a 500-mL round bottom flask under a nitrogen atmosphere, and then an aqueous 2 M potassium carbonate solution (120 mL) was added thereto, tetrakis-(triphenylphosphine) palladium (0.23 g, 0.20 mmol) was put thereinto, and then the resulting mixture was heated and stirred for 6 hours. The temperature was lowered to room temperature, the aqueous layer was removed, and the residue was dried over anhydrous magnesium sulfate, and then concentrated under reduced pressure, and recrystallized with 340 mL of ethyl acetate to prepare Compound 4 (3.12 g, 52%).

MS[M+H]⁺=916

### <Preparation Example 5> Synthesis of Compound 5

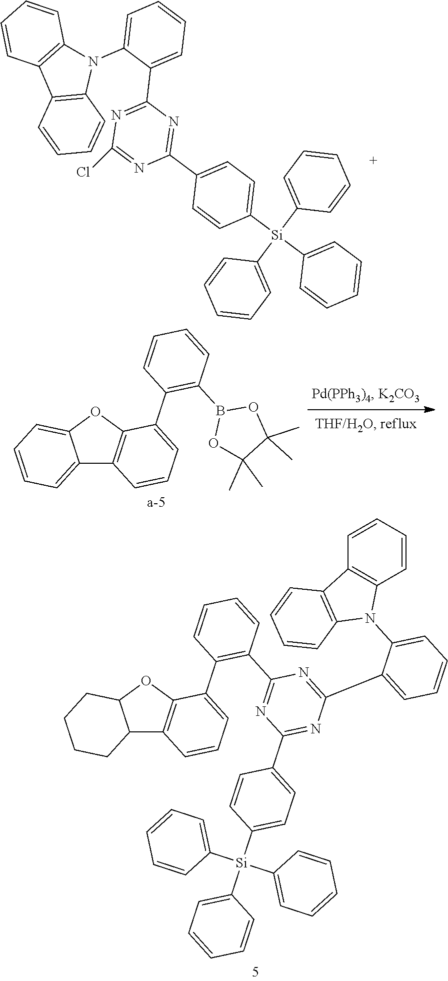

A compound 9-(2-(4-chloro-6-(4-(triphenylsilyl)phenyl)-1,3,5-triazin-2-yl)phenyl)-9H-carbazole (4.50 g, 6.51 mmol) and Compound a-5 (2.77 g, 7.49 mmol) were completely dissolved in 240 mL of tetrahydrofuran in a 500-mL round bottom flask under a nitrogen atmosphere, and then an aqueous 2 M potassium carbonate solution (120 mL) was added thereto, tetrakis-(triphenylphosphine) palladium (0.23 g, 0.20 mmol) was put thereinto, and then the resulting mixture was heated and stirred for 8 hours. The temperature was lowered to room temperature, the aqueous layer was removed, and the residue was dried over anhydrous magnesium sulfate, and then concentrated under reduced pressure, and recrystallized with 350 mL of ethyl acetate to prepare Compound 5 (3.97 g, 68%).

MS[M+H]⁺=900

### <Preparation Example 6> Synthesis of Compound 6

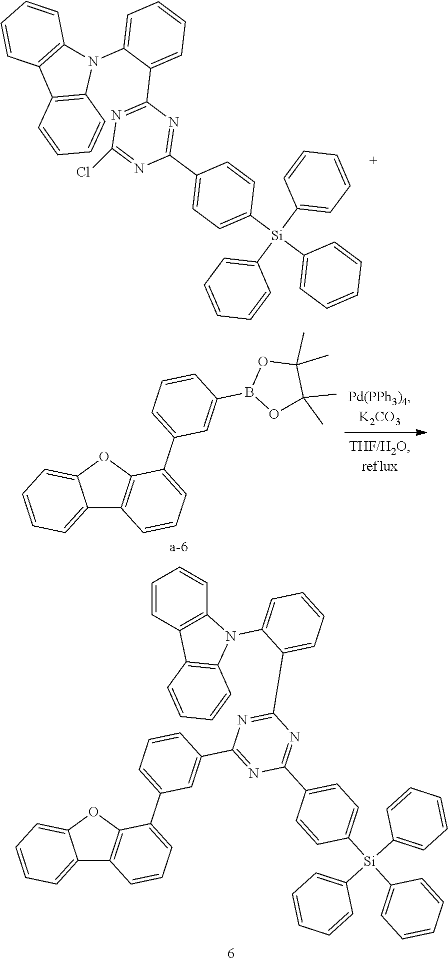

A compound 9-(2-(4-chloro-6-(4-(triphenylsilyl)phenyl)-1,3,5-triazin-2-yl)phenyl)-9H-carbazole (4.50 g, 6.51 mmol) and Compound a-6 (2.77 g, 7.49 mmol) were completely dissolved in 240 mL of tetrahydrofuran in a 500-mL round bottom flask under a nitrogen atmosphere, and then an aqueous 2 M potassium carbonate solution (120 mL) was added thereto, tetrakis-(triphenylphosphine) palladium (0.23 g, 0.20 mmol) was put thereinto, and then the resulting mixture was heated and stirred for 6 hours. The temperature was lowered to room temperature, the aqueous layer was removed, and the residue was dried over anhydrous magnesium sulfate, and then concentrated under reduced pressure, and recrystallized with 320 ml of ethyl acetate to prepare Compound 6 (4.05 g, 69%).

MS[M+H]⁺=900

### <Preparation Example 7> Synthesis of Compound 7

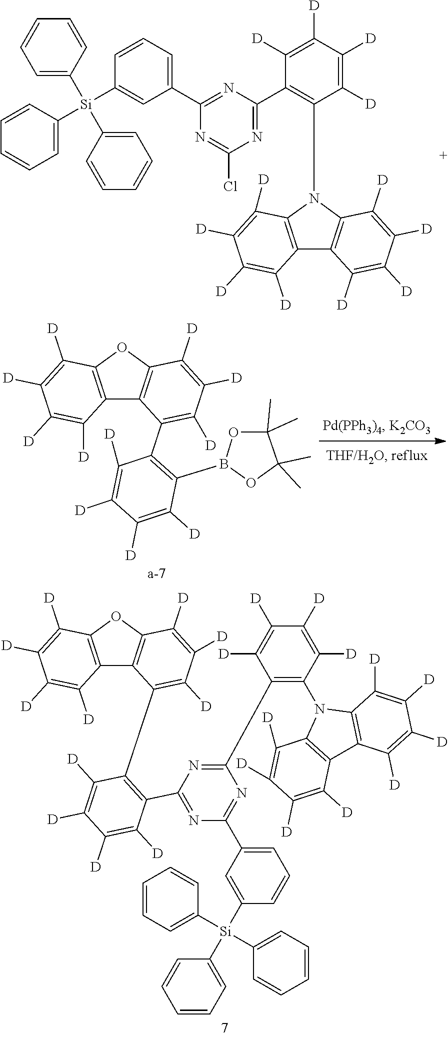

A compound 9-(2-(4-chloro-6-(3-(triphenylsilyl)phenyl)-1,3,5-triazin-2-yl)phenyl-3, 4, 5, 6-d4)-9H-carbazole-1, 2, 3, 4, 5, 6,7,8-d8 (3.50 g, 4.99 mmol) and Compound a-7 (2.19 g, 5.74 mmol) were completely dissolved in 240 mL of tetrahydrofuran in a 500-mL round bottom flask under a nitrogen atmosphere, and then an aqueous 2 M potassium carbonate solution (120 mL) was added thereto, tetrakis-(triphenylphosphine) palladium (0.17 g, 0.15 mmol) was put thereinto, and then the resulting mixture was heated and stirred for 8 hours. The temperature was lowered to room temperature, the aqueous layer was removed, and the residue was dried over anhydrous magnesium sulfate, and then concentrated under reduced pressure, and recrystallized with 380 mL of ethyl acetate to prepare Compound 7 (2.56 g, 56%).

MS[M+H]⁺=923

### <Preparation Example 8> Synthesis of Compound 8

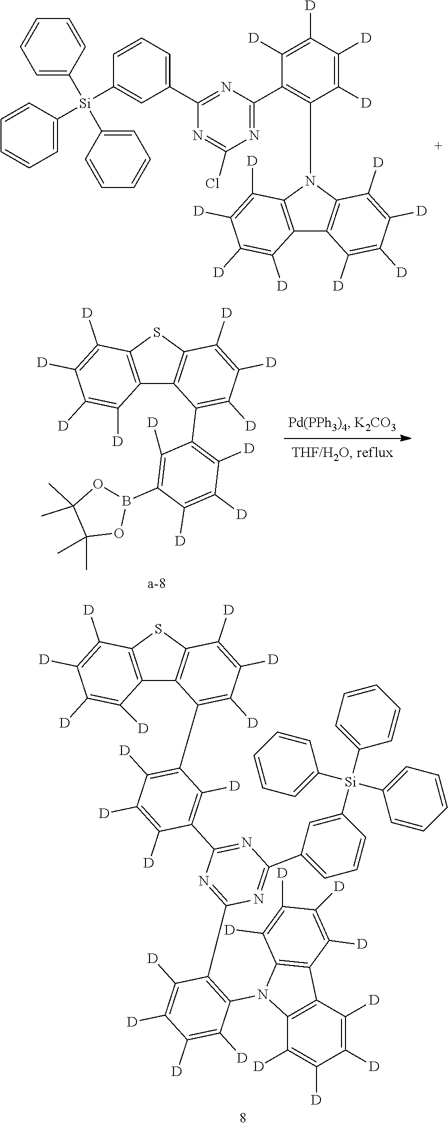

A compound 9-(2-(4-chloro-6-(3-(triphenylsilyl)-phenyl)-1,3,5-triazin-2-yl)phenyl-3, 4, 5, 6-d4)-9H-carbazole-1,2, 3, 4, 5, 6, 7,8-d8 (3.50 g, 4.99 mmol) and Compound a-8 (2.28 g, 7.74 mmol) were completely dissolved in 240 mL of tetrahydrofuran in a 500-mL round bottom flask under a nitrogen atmosphere, and then an aqueous 2 M potassium carbonate solution (120 mL) was added thereto, tetrakis-(triphenylphosphine) palladium (0.17 g, 0.15 mmol) was put thereinto, and then the resulting mixture was heated and stirred for 6 hours. The temperature was lowered to room temperature, the aqueous layer was removed, and the residue was dried over anhydrous magnesium sulfate, and then concentrated under reduced pressure, and recrystallized with 320 ml of ethyl acetate to prepare Compound 8 (2.77 g, 59%).

MS[M+H]⁺=939

### <Preparation Example 9> Synthesis of Compound 9

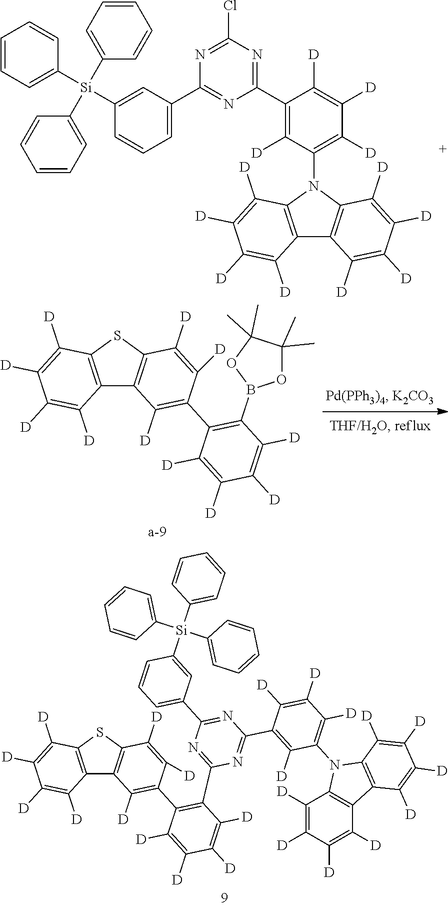

A compound 9-(3-(4-chloro-6-(3-(triphenylsilyl)phenyl)-1,3,5-triazin-2-yl)phenyl-2,4,5,6-d4)-9H-carbazole-1, 2, 3, 4, 5, 6,7,8-d8 (3.50 g, 4.99 mmol) and Compound a-9 (2.28 g, 5.74 mmol) were completely dissolved in 240 mL of tetrahydrofuran in a 500-mL round bottom flask under a nitrogen atmosphere, and then an aqueous 2 M potassium carbonate solution (120 mL) was added thereto, tetrakis-(triphenylphosphine) palladium (0.17 g, 0.15 mmol) was put thereinto, and then the resulting mixture was heated and stirred for 4 hours. The temperature was lowered to room temperature, the aqueous layer was removed, and the residue was dried over anhydrous magnesium sulfate, and then concentrated under reduced pressure, and recrystallized with 290 mL of ethyl acetate to prepare Compound 9 (2.88 g, 61%).

MS[M+H]⁺=939

### <Preparation Example 10> Synthesis of Compound 10

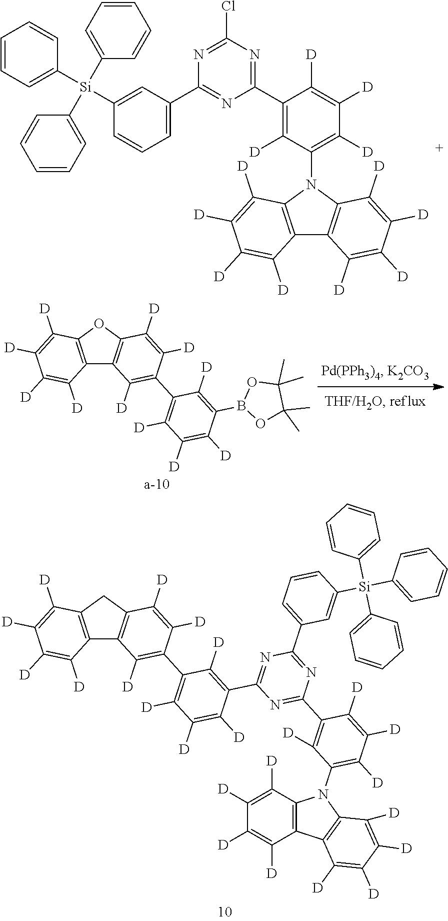

A compound 9-(3-(4-chloro-6-(3-(triphenylsilyl)phenyl)-1,3,5-triazin-2-yl)phenyl-2,4,5,6-d4)-9H-carbazole-1, 2, 3, 4, 5, 6,7,8-d8 (3.50 g, 4.99 mmol) and Compound a-10 (2.19 g, 5.74 mmol) were completely dissolved in 240 mL of tetrahydrofuran in a 500-mL round bottom flask under a nitrogen atmosphere, and then an aqueous 2 M potassium carbonate solution (120 mL) was added thereto, tetrakis-(triphenylphosphine) palladium (0.17 g, 0.15 mmol) was put thereinto, and then the resulting mixture was heated and stirred for 5 hours. The temperature was lowered to room temperature, the aqueous layer was removed, and the residue was dried over anhydrous magnesium sulfate, and then concentrated under reduced pressure, and recrystallized with 260 mL of ethyl acetate to prepare Compound 10 (3.02 g, 66%).

MS[M+H]⁺=923

### Example 1-1

A glass substrate thinly coated with indium tin oxide (ITO) to have a thickness of 800 Å was put into distilled water in which a detergent was dissolved, and ultrasonically washed. In this case, a product manufactured by the Fischer Co., was used as the detergent, and distilled water twice filtered using a filter manufactured by Millipore Co., was used as the distilled water. After the ITO was washed for 30 minutes, ultrasonic washing was repeated twice by using distilled water for 10 minutes. After the washing using distilled water was completed, ultrasonic washing was conducted by using isopropyl alcohol, acetone, and methanol solvents, and the resulting product was dried and then transported to a plasma washing machine. Furthermore, the substrate was cleaned by using oxygen plasma for 5 minutes, and then was transported to a vacuum deposition machine.

Compounds of the following Compound HT1 and the following Compound HI1 were thermally vacuum deposited to have a thickness of 100 Å at a ratio of 98:2 (molar ratio) on a transparent ITO electrode, which is the positive electrode thus prepared, thereby forming a hole injection layer. A compound of the following Chemical Formula HT1 (300 Å) was vacuum deposited on the hole injection layer, thereby forming a hole transport layer. Subsequently, a compound of the following Chemical Formula BH (p-type) was vacuum deposited to have a film thickness of 50 Å on the hole transport layer, thereby forming an electron blocking layer. Subsequently, a mixture in which the following Chemical Formula BH (p-type) used as a p-type host of the light emitting layer and Compound 1 synthesized in Preparation Example 1 used as an n-type host of the light emitting layer were mixed at a ratio of 1:1 (weight ratio), and a compound represented by the following Chemical Formula BD were vacuum deposited at a weight ratio of 88:12 on the electron blocking layer, thereby forming a light emitting layer. Compound 1 synthesized in Preparation Example 1 was vacuum deposited to have a film thickness of 50 Å on the light emitting layer, thereby forming a hole blocking layer. Subsequently, a compound represented by the following Chemical Formula ET1 and a compound represented by the following Chemical Formula LiQ were vacuum deposited at a weight ratio of 1:1 on the hole blocking layer, thereby forming an electron injection and transport layer having a thickness of 300 Å. Lithium fluoride (LiF) and aluminum were sequentially deposited on the electron injection and transport layer to have a thickness of 10 Å and 800 Å, respectively, thereby forming a negative electrode.

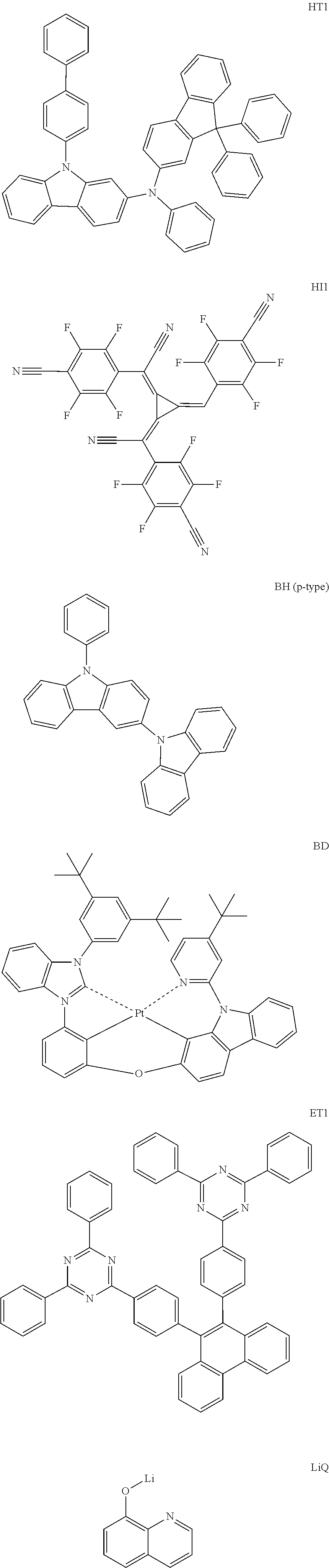

In the aforementioned procedure, the deposition rate of the organic material was maintained at 0.4 to 0.7 Å/see, the deposition rates of lithium fluoride and aluminum of the negative electrode were maintained at 0.3 Å/see and at 2 Å/see, respectively, and the degree of vacuum during the deposition was maintained at 2×10⁻⁷ to 5×10⁻⁶ torr, thereby manufacturing an organic light emitting device.

### Examples 1-2 to 1-10

Organic light emitting devices were manufactured in the same manner as in Example 1-1, except that Compounds 2 to 10 described in the following Table 1 were each used instead of the compound in Preparation Example 1.

### Comparative Examples 1-1 to 1-8

Organic light emitting devices were manufactured in the same manner as in Example 1-1, except that the compounds described in the following Table 1 were used instead of the compound in Preparation Example 1. The compounds of BH1 (n-type) to BH8 (n-type) used in the following Table 1 are as follows.

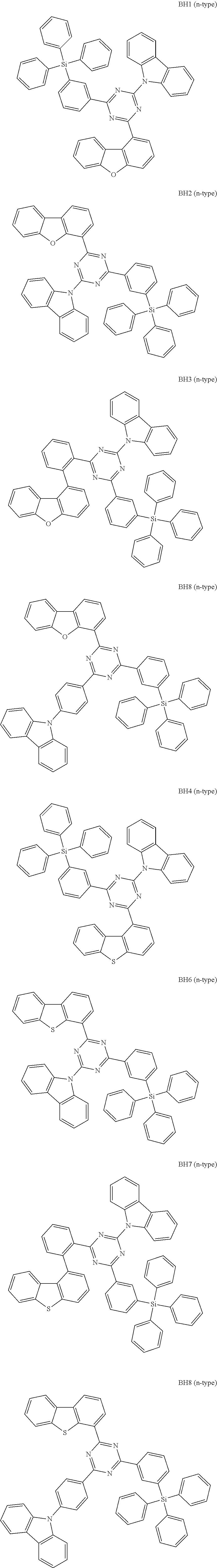

### Experimental Example 1

When a current was applied to each of the organic light emitting devices manufactured in the Examples and the Comparative Examples, the voltage, efficiency, color coordinate, and service life were measured, and the results thereof are shown in the following Table 1. T95 means the time taken for the luminance to be reduced to 95% of the initial luminance (1600 nit).

TABLE 1

| | | voltage | efficiency | Color | |
|---|---|---|---|---|---|
| | Compound | (V@10 | (cd/A@10 | coordinate | |
| | (Host) | mA/cm²) | mA/cm²) | (x, y) | T95 |
| Example 1-1 | Compound 1 | 3.79 | 19.2 | (0.137, | 159 |
| | | | | 0.155) | |
| Example 1-2 | Compound 2 | 3.78 | 19.0 | (0.136, | 153 |
| | | | | 0.154) | |
| Example 1-3 | Compound 3 | 3.85 | 18.6 | (0.137, | 148 |
| | | | | 0.155) | |
| Example 1-4 | Compound 4 | 3.86 | 18.7 | (0.136, | 146 |
| | | | | 0.154) | |
| Example 1-5 | Compound 5 | 3.77 | 19.1 | (0.136, | 153 |
| | | | | 0.155) | |
| Example 1-6 | Compound 6 | 3.78 | 19.3 | (0.136, | 157 |
| | | | | 0.154) | |
| Example 1-7 | Compound 7 | 3.75 | 19.8 | (0.137, | 189 |
| | | | | 0.155) | |
| Example 1-8 | Compound 8 | 3.83 | 19.5 | (0.136, | 174 |
| | | | | 0.155) | |
| Example 1-9 | Compound 9 | 3.82 | 19.4 | (0.136, | 176 |
| | | | | 0.154) | |
| Example 1- | Compound 10 | 3.73 | 19.9 | (0.136, | 185 |
| 10 | | | | 0.154) | |
| Comparative | BH1 | 4.03 | 17.7 | (0.135, | 114 |
| Example 1-1 | | | | 0.157) | |
| Comparative | BH2 | 4.14 | 17.0 | (0.136, | 103 |
| Example 1-2 | | | | 0.158) | |
| Comparative | BH3 | 4.09 | 17.9 | (0.137, | 127 |
| Example 1-3 | | | | 0.157) | |
| Comparative | BH4 | 4.12 | 17.3 | (0.136, | 109 |
| Example 1-4 | | | | 0.157) | |
| Comparative | BH5 | 4.18 | 17.4 | (0.137, | 101 |
| Example 1-5 | | | | 0.158) | |
| Comparative | BH6 | 4.27 | 16.8 | (0.136, | 92 |
| Example 1-6 | | | | 0.158) | |
| Comparative | BH7 | 4.22 | 17.6 | (0.137, | 112 |
| Example 1-7 | | | | 0.158) | |
| Comparative | BH8 | 4.25 | 17.0 | (0.136, | 95 |
| Example 1-8 | | | | 0.158) | |

As shown in Table 1, an organic light emitting device in which the compound of Chemical Formula 1 according to an exemplary embodiment of the present specification in which a triazine group is bonded to a carbazole group through a phenylene group and a triazine group is bonded to a dibenzofuran group (or a dibenzothiophene group) through a phenylene group was used as an n-type host of the hole blocking layer and the light emitting layer exhibited excellent characteristics in terms of the efficiency, driving voltage and stability of the organic light emitting device.

Specifically, Chemical Formula 1 according to an exemplary embodiment of the present specification is a compound including a phenylene linking group between dibenzofuran (or dibenzothiophene) and triazine and a phenyl group between carbazole and triazine, and Examples 1-1 to 1-10, which are organic light emitting devices including the compound, exhibited excellent characteristics in terms of efficiency, driving voltage, and stability compared to Comparative Examples 1-1, 1-2, 1-5, and 1-6 including a compound in which dibenzofuran (or dibenzothiophene) is directly bonded to triazine and carbazole is directly bonded to triazine, and Comparative Examples 1-3, 1-4, 1-7, and 1-8 including a compound in which dibenzofuran (or dibenzothiophene) is directly bonded to triazine, or carbazole is directly bonded to triazine.

Although the preferred exemplary embodiments (an n-type host of the hole blocking layer and the light emitting layer) of the present invention have been described above, the present invention is not limited thereto, and various modifications can be made and carried out within the scope of the claims and the detailed description of the invention, and also fall within the scope of the invention.

### EXPLANATION OF REFERENCE NUMERALS AND SYMBOLS

1: Substrate
2: First electrode
3: Second electrode
4: Organic material layer
5: Hole injection layer
6: Hole transport layer
7: Electron blocking layer
8: Light emitting layer
9: Hole blocking layer
10: Electron injection and transport layer

What is claimed is:

1. A compound of the following Chemical Formula 1: 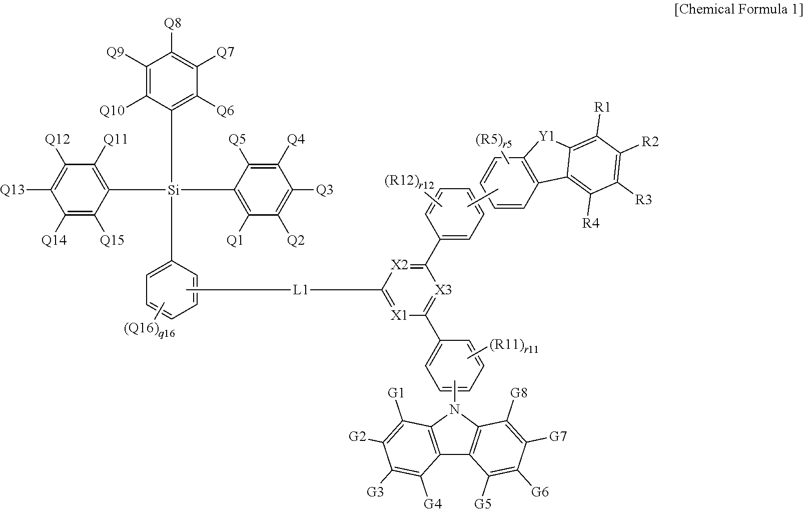
wherein, in Chemical Formula 1,
at least one of X1 to X3 is N, and the others are CR13,
Y1 is O or S,
L1 is a direct bond or a substituted or unsubstituted monocyclic arylene group,
R1 to R5, R11 to R13, G1 to G8 and Q1 to Q16 are the same as or different from each other, and are each independently hydrogen or deuterium,
r5 is an integer from 1 to 3, and when r5 is 2 or higher, two or more R5s are the same as or different from each other,
r11 is an integer from 1 to 4, and when r11 is 2 or higher, two or more R11s are the same as or different from each other,
r12 is an integer from 1 to 4, and when r12 is 2 or higher, two or more R12s are the same as or different from each other, and
q16 is an integer from 1 to 4, and when q16 is 2 or higher, two or more Q16s are the same as or different from each other.

2. The compound of claim 1, wherein Chemical Formula 1 is any one of the following Chemical Formulae 1-1 to 1-7: 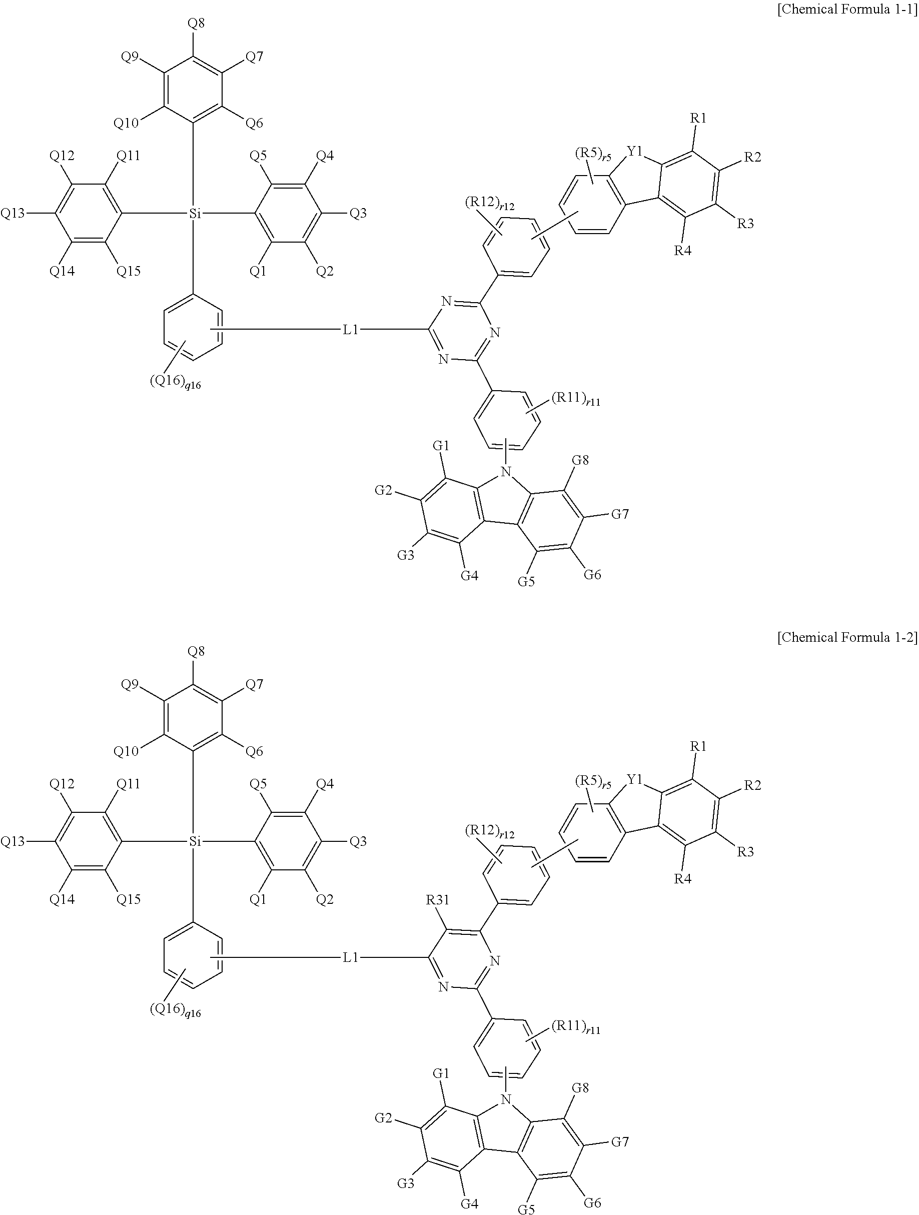 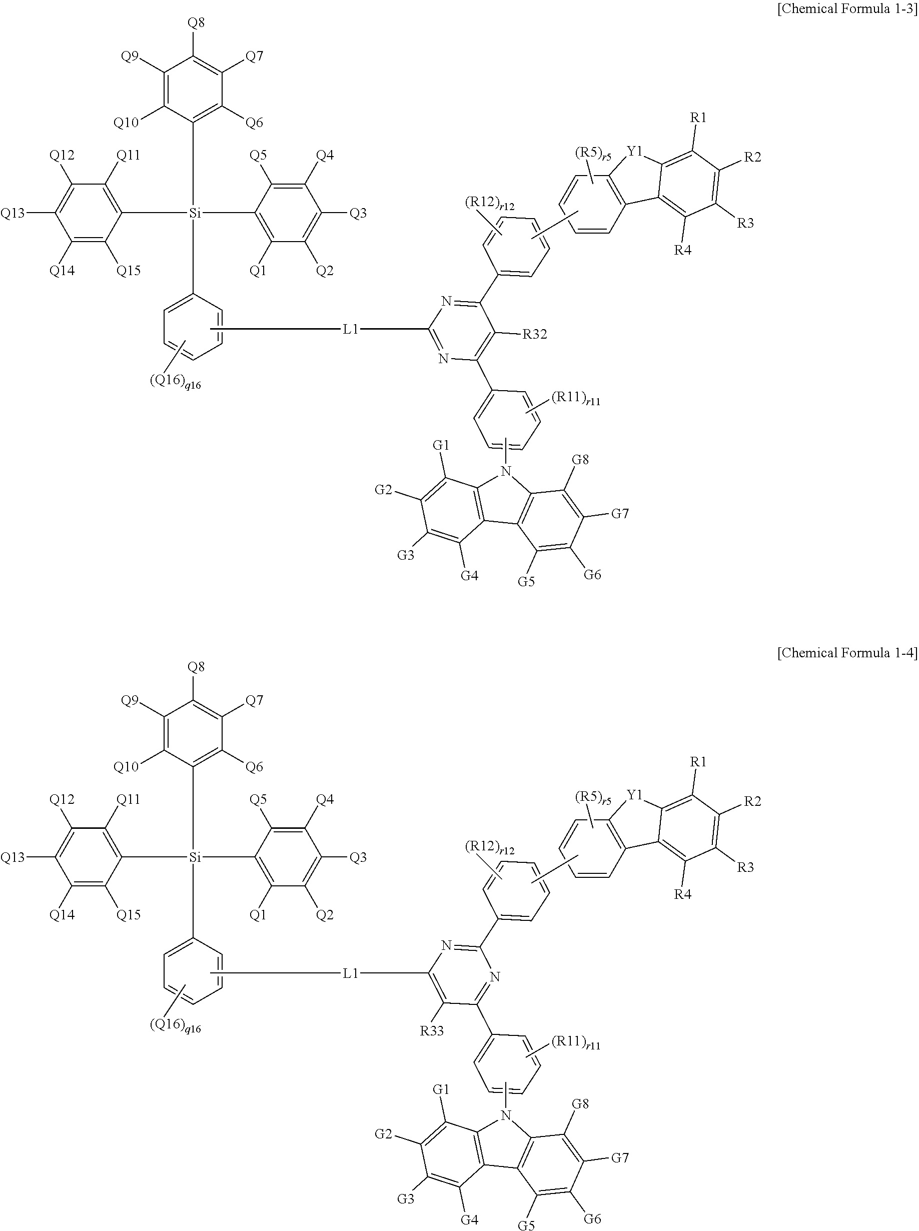 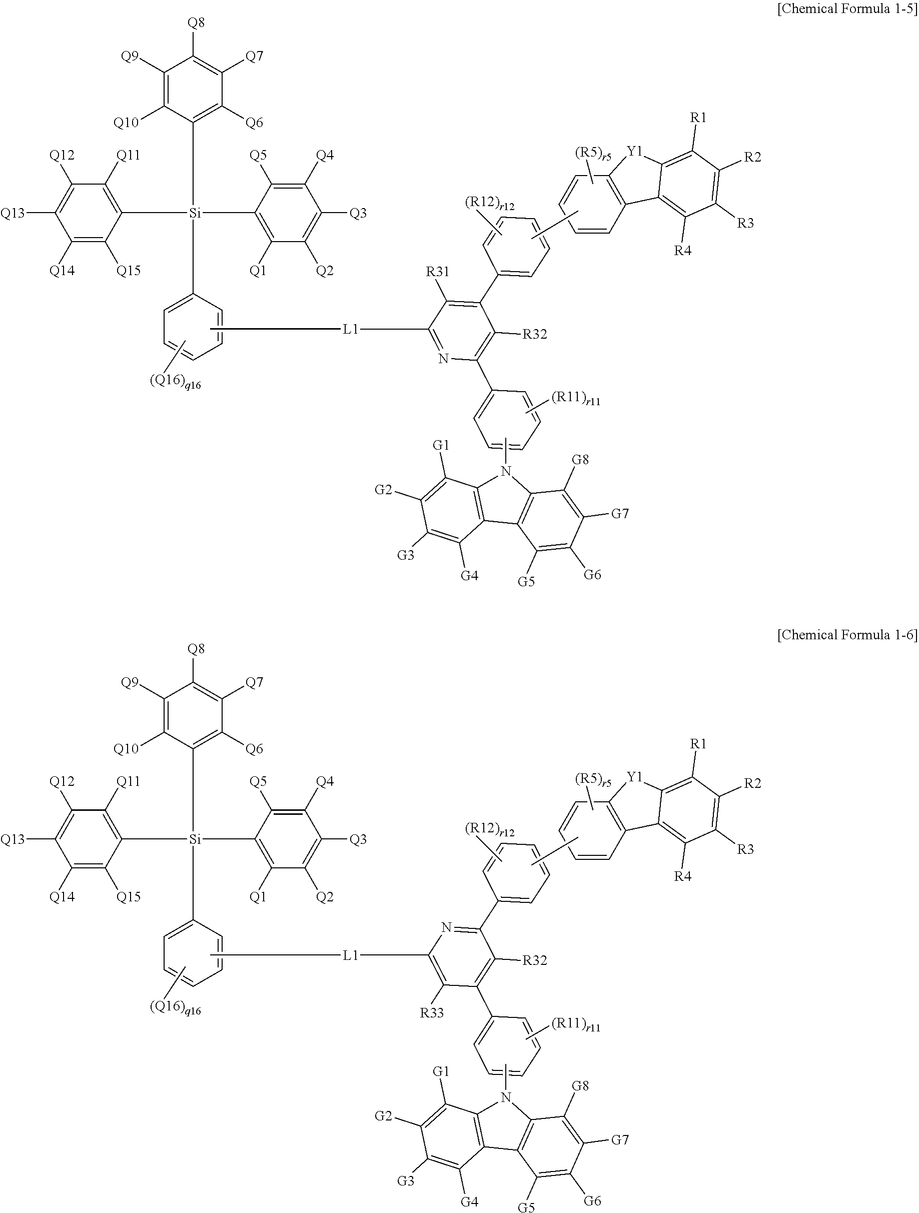 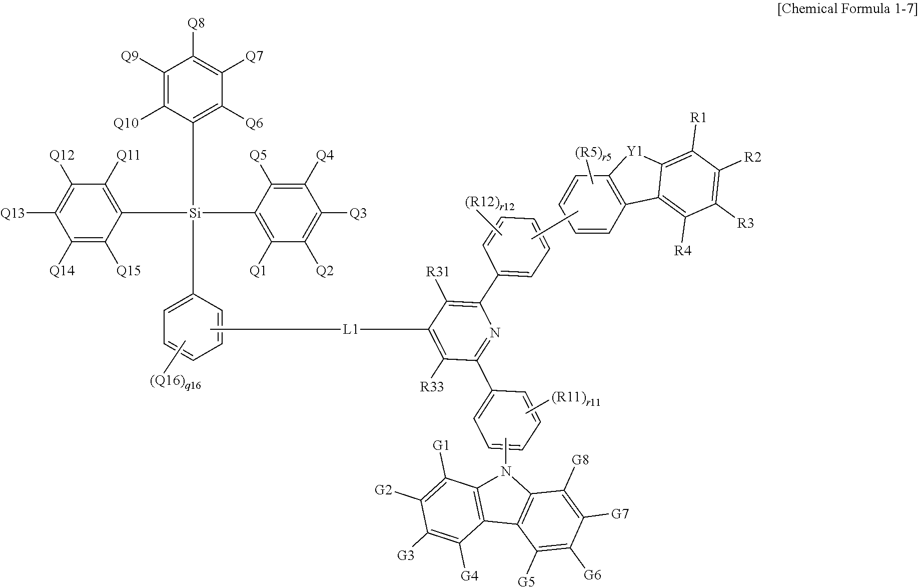
in Chemical Formulae 1-1 to 1-7,
Y1, L1, R1 to R5, R11, R12, G1 to G8, 01 to Q16, r5, r11, r12 and q16 are the same as those defined in Chemical Formula 1, and
R31 to R33 are the same as or different from each other, and are each independently hydrogen or deuterium.

3. The compound of claim 1, wherein Chemical Formula 1 is the following Chemical Formula 1-8 or 1-9: 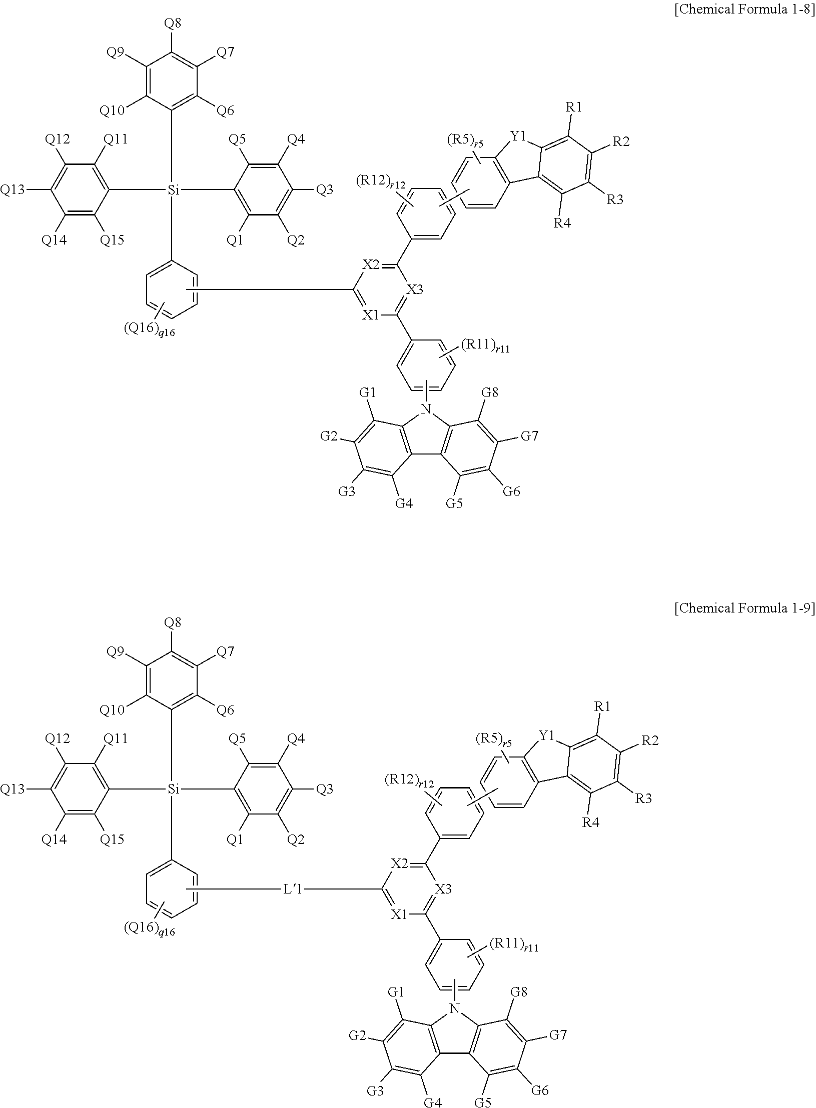
in Chemical Formulae 1-8 and 1-9,
X1 to X3, Y1, R1 to R5, R11, R12, G1 to G8, 01 to Q16, r5, r11, r12 and q16 are the same as those defined in Chemical Formula 1, and
L′1 is a substituted or unsubstituted monocyclic arylene group.

4. The compound of claim 1, wherein L1 is a direct bond or a monocyclic arylene group having 6 to 18 carbon atoms, which is unsubstituted or substituted with deuterium.

5. The compound of claim 1, wherein Chemical Formula 1 is any one of the following compounds:

[chemical structure]

[chemical structure]

[chemical structure]

[chemical structure]

[chemical structure]

[chemical structure]

[chemical structure]

[chemical structure]

[chemical structure]

[chemical structure]

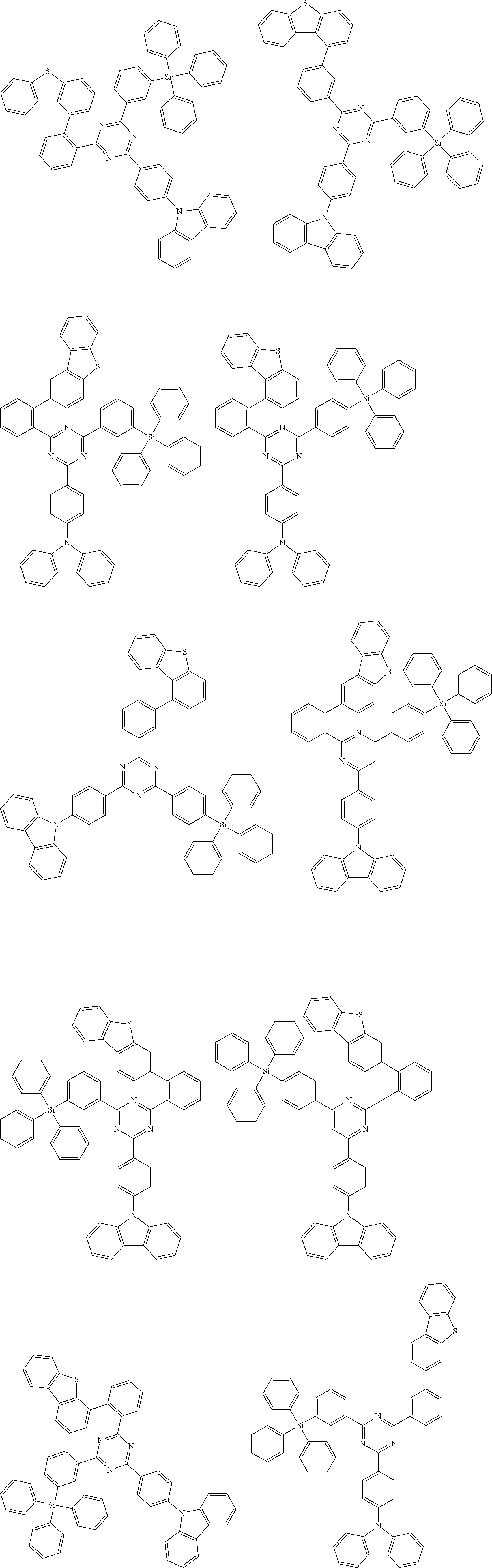

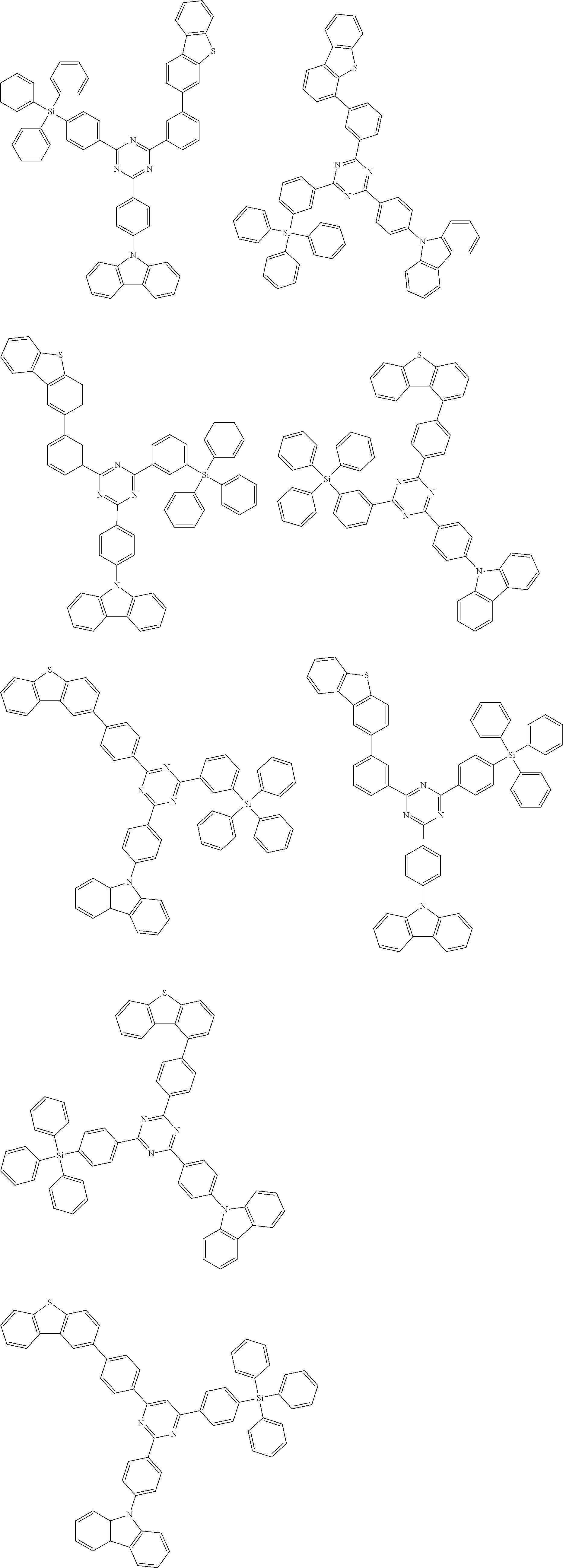

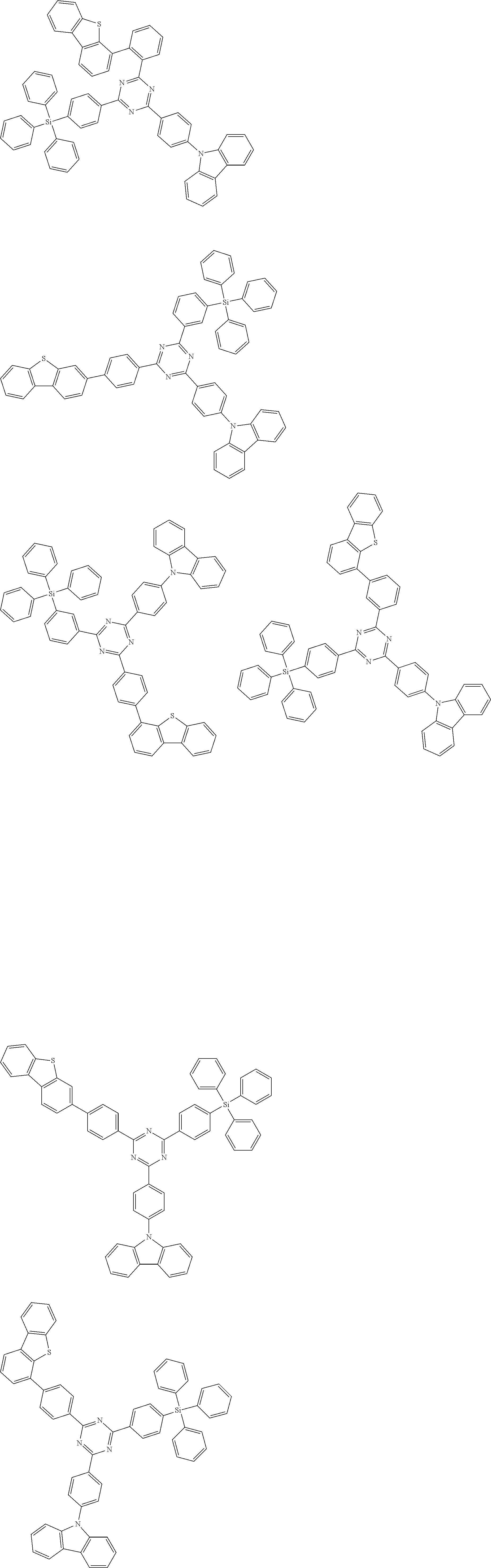

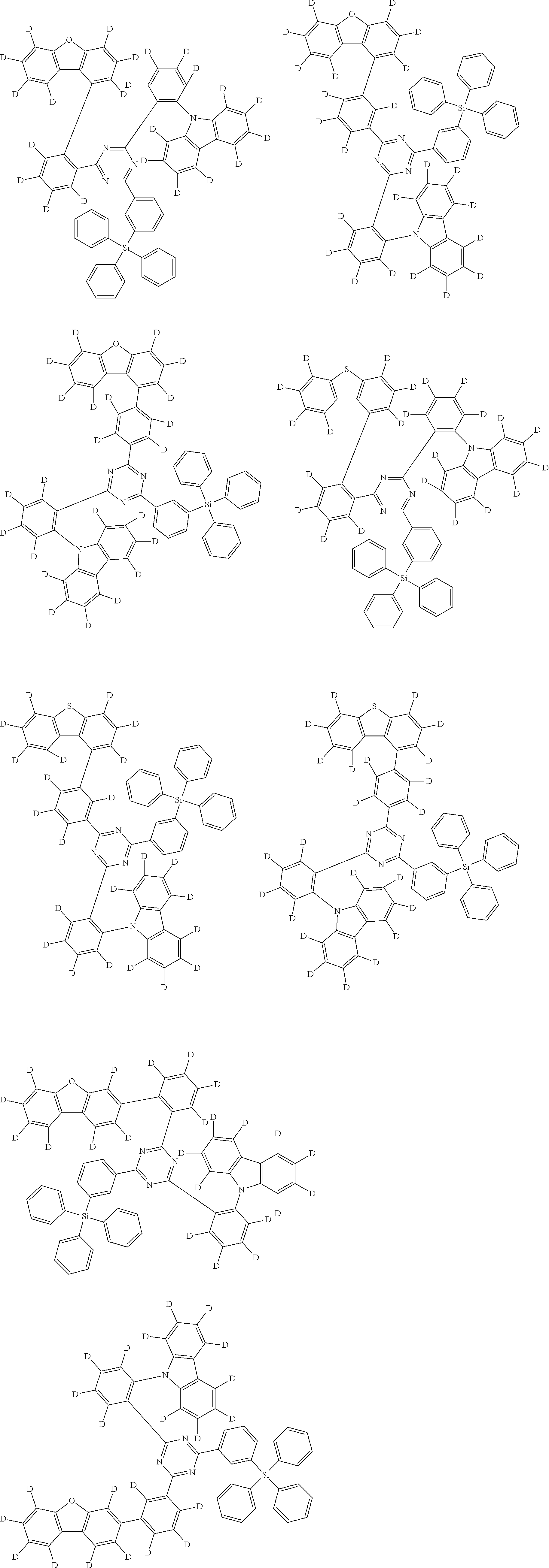

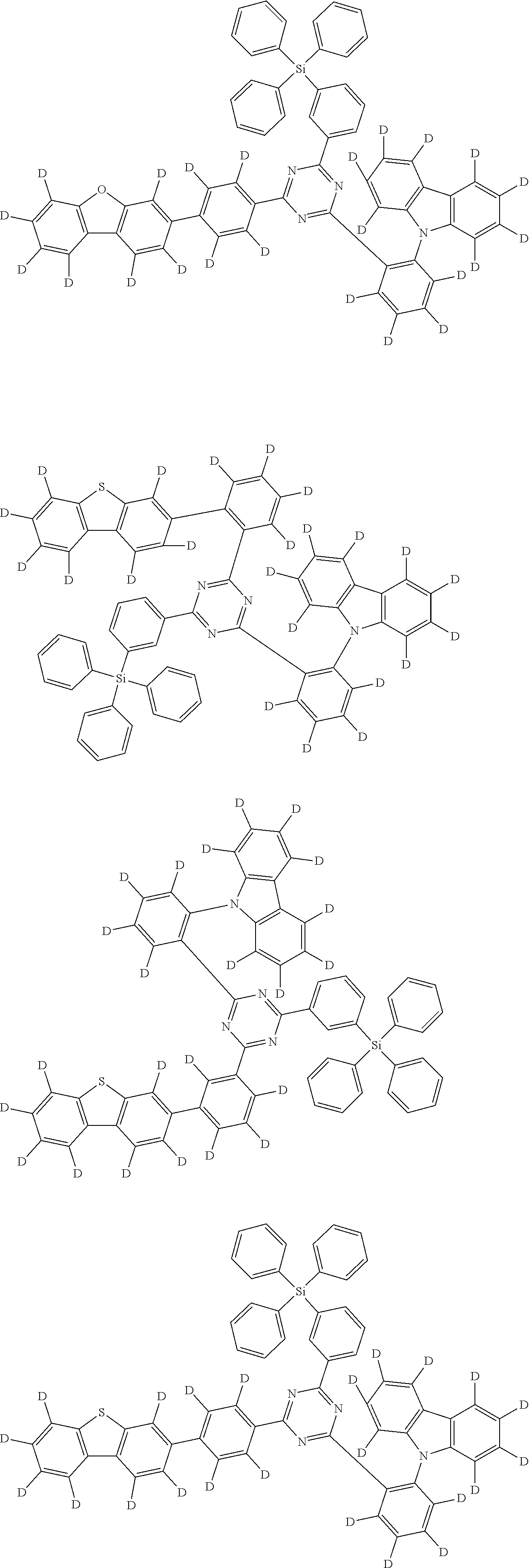

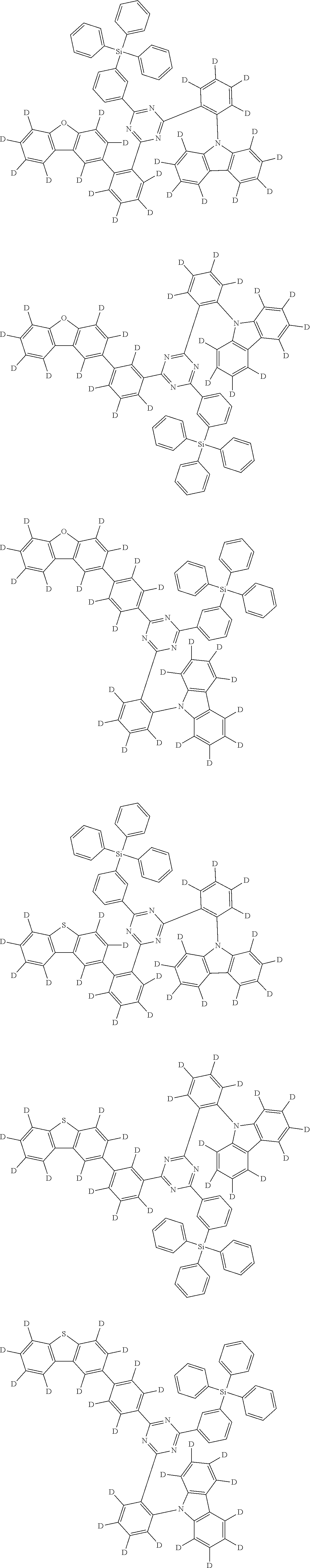

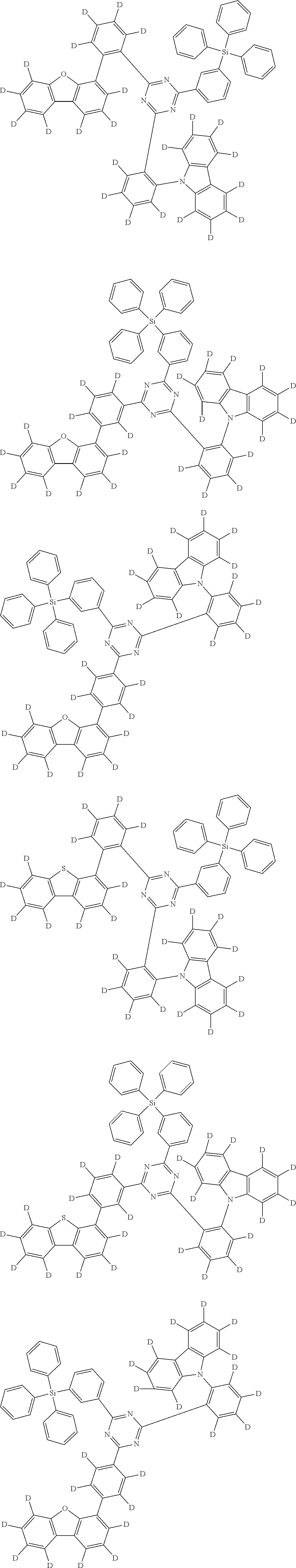

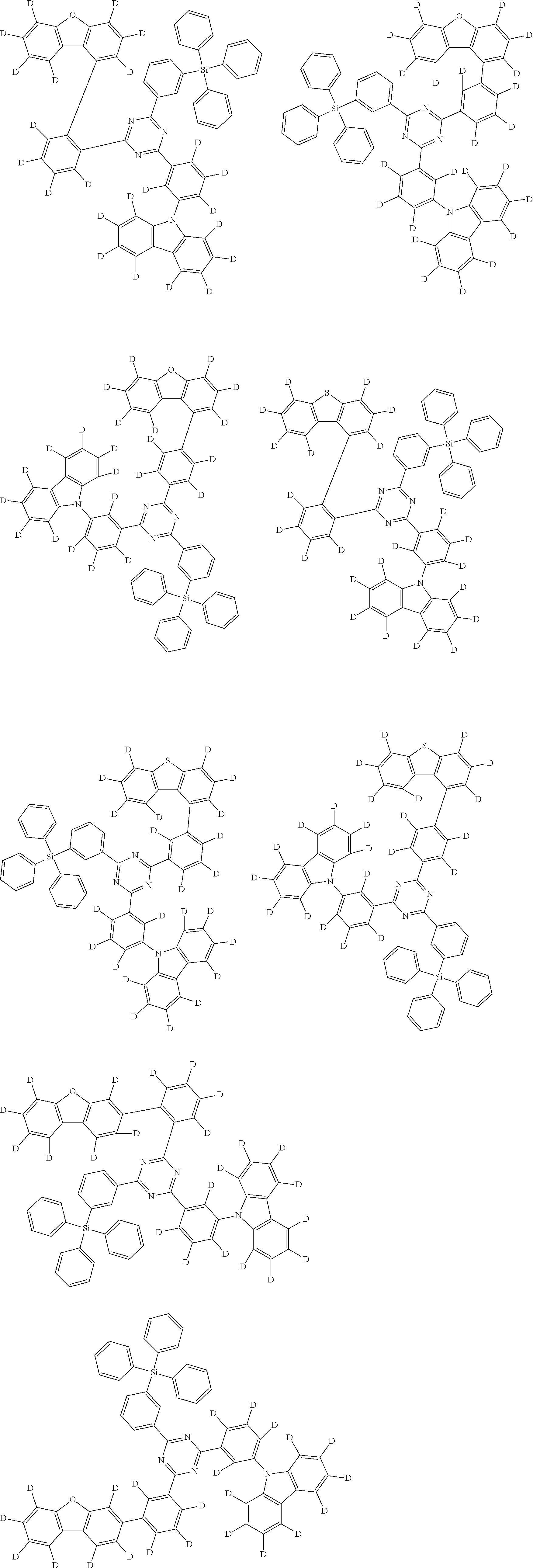

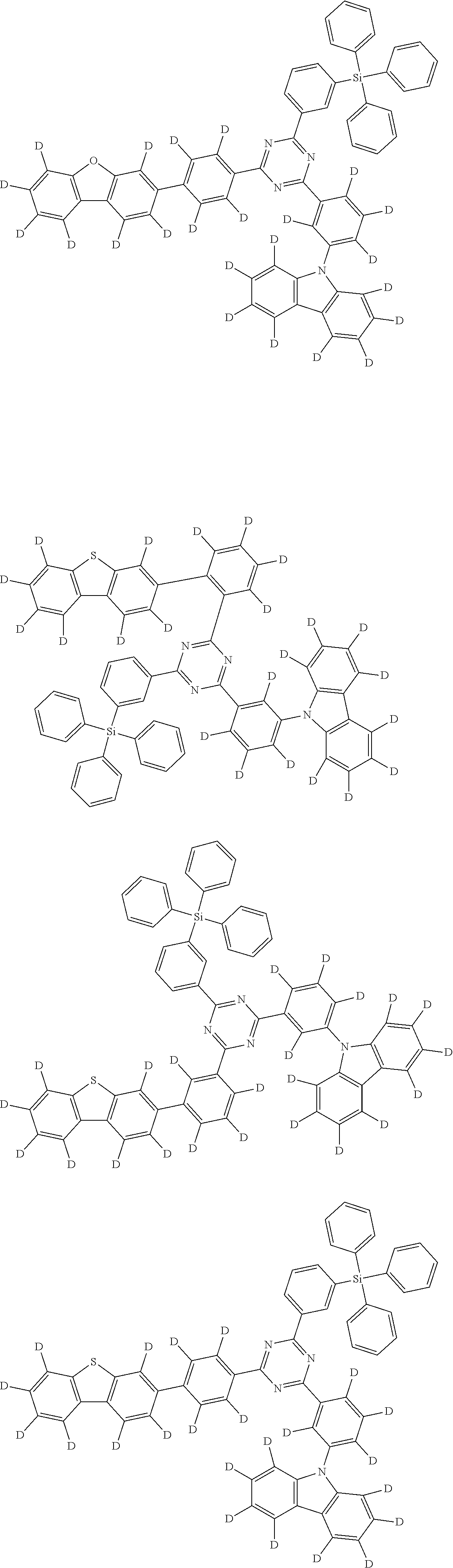

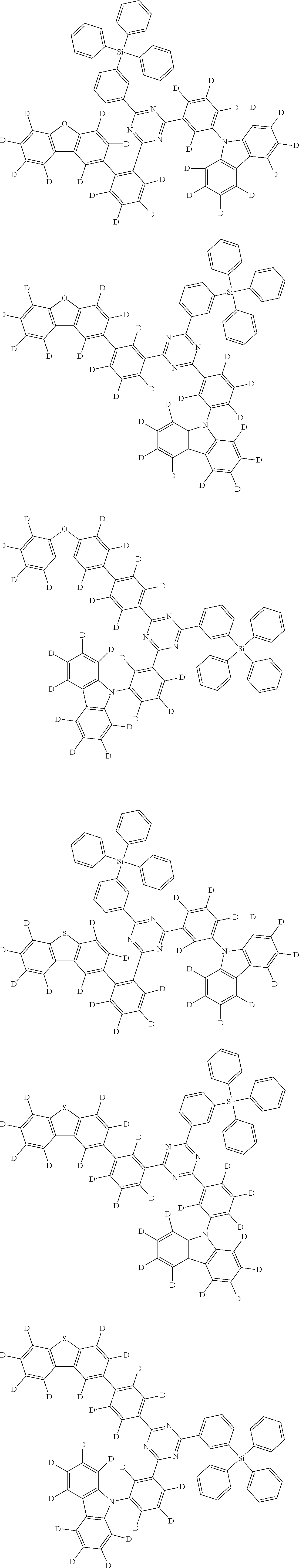

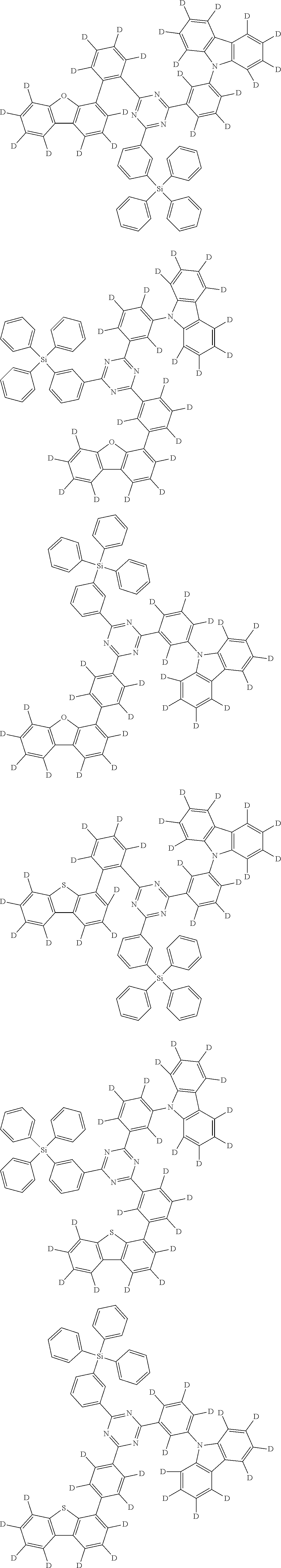

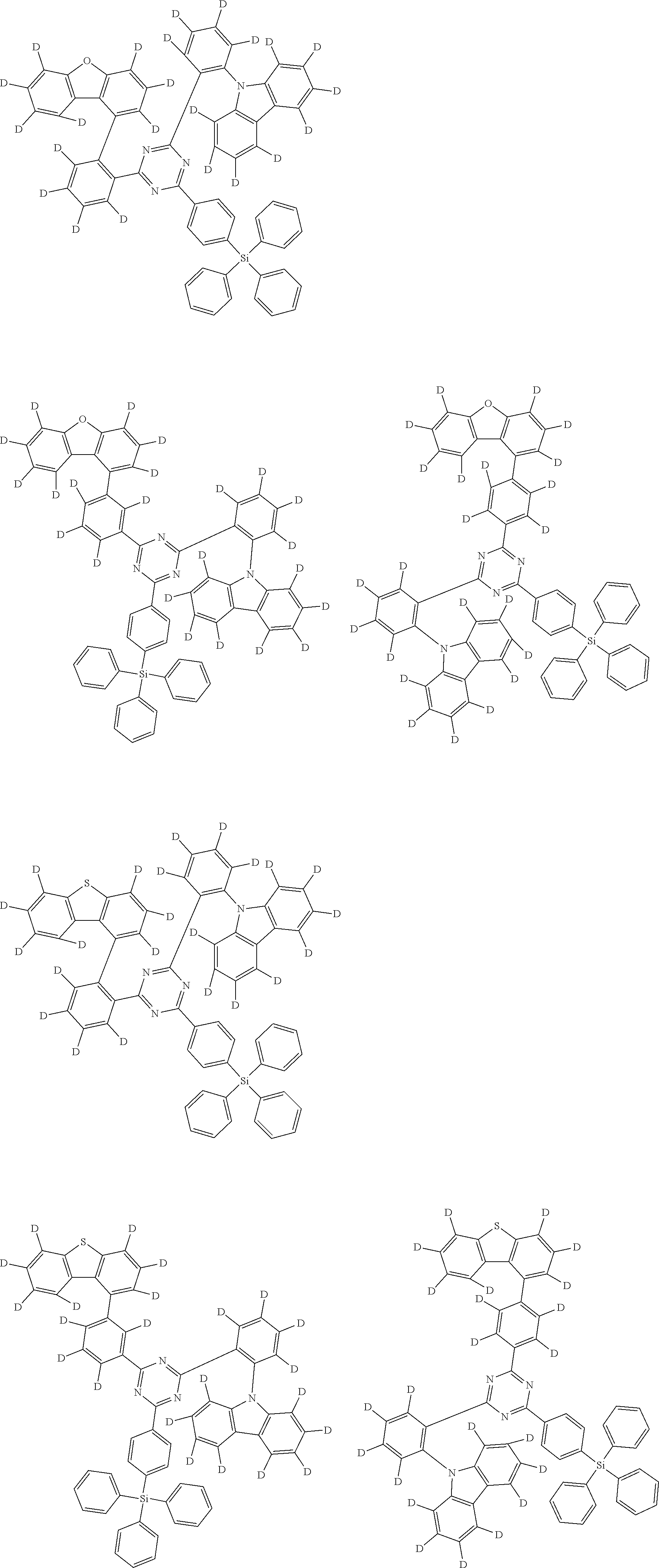

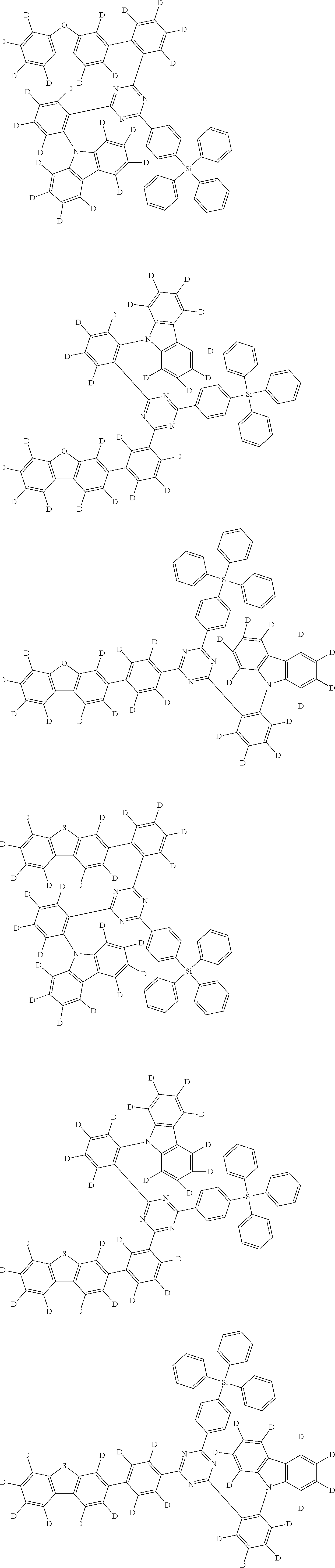

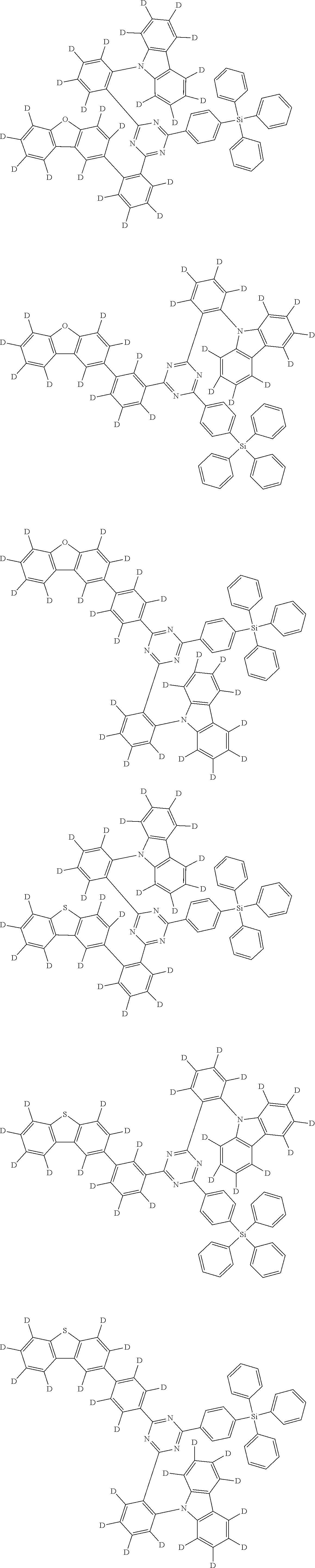

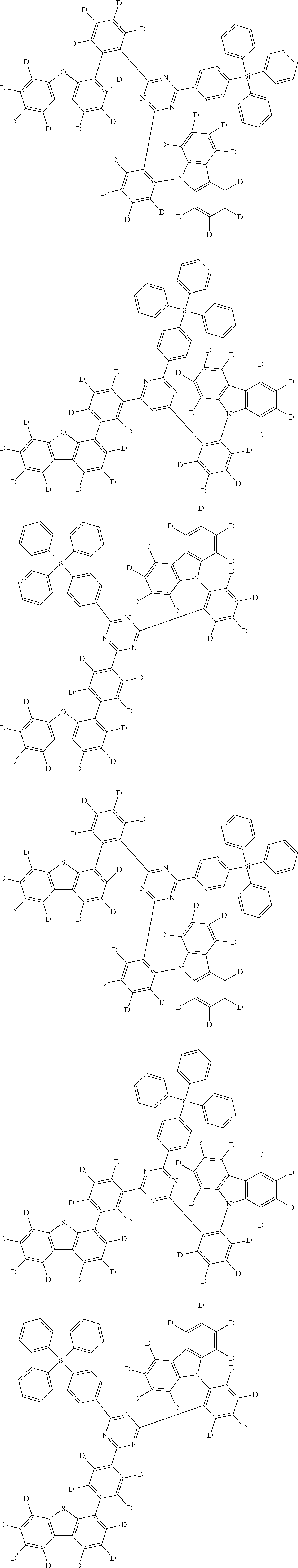

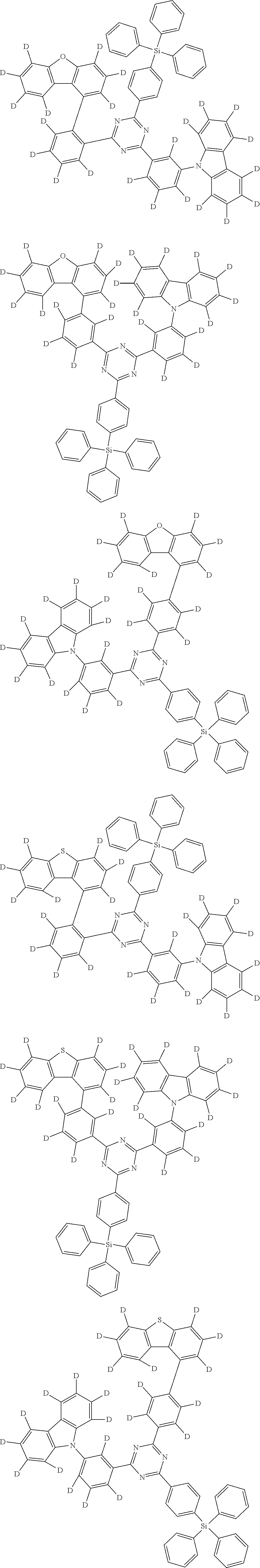

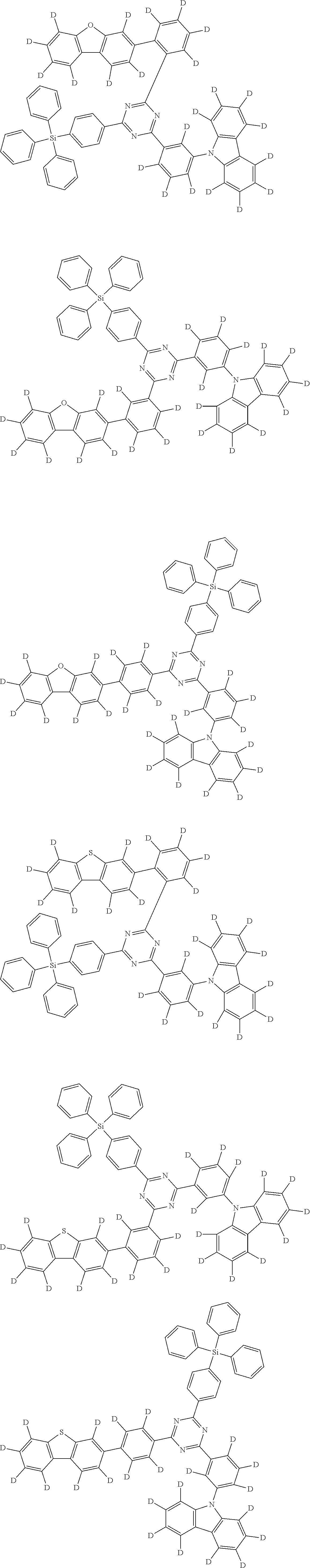

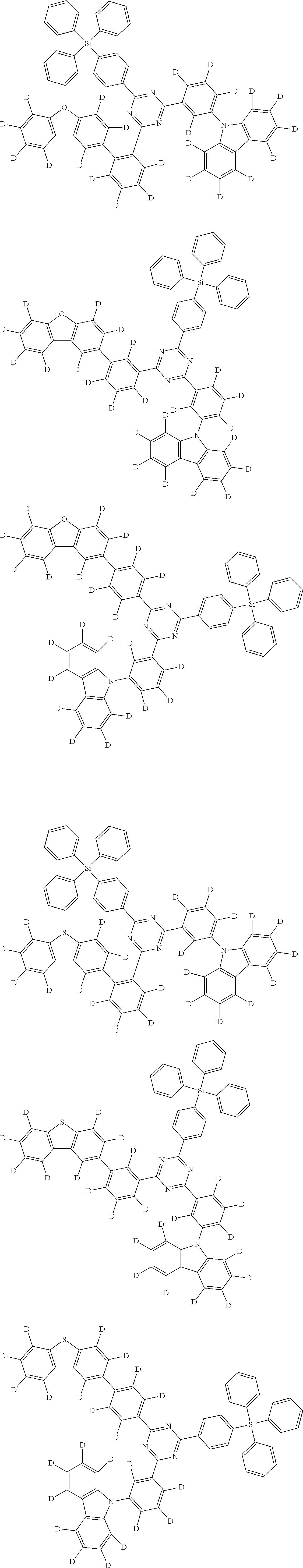

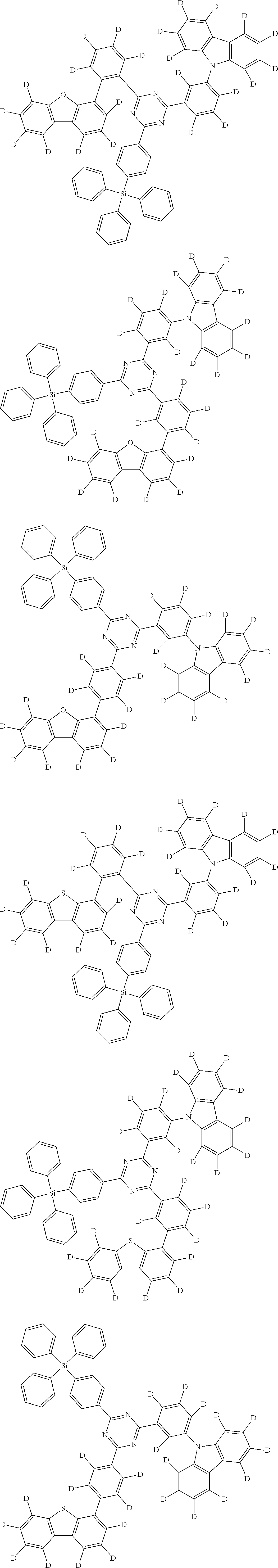

6. An organic light emitting device comprising:
a first electrode;
a second electrode; and
an organic material layer having one or more layers provided between the first electrode and the second electrode,
wherein one or more layers of the organic material layer comprise the compound of claim 1.

7. The organic light emitting device of claim 6, wherein the organic material layer comprises a light emitting layer, and the light emitting layer comprises the compound.

8. The organic light emitting device of claim 6, wherein the organic material layer comprises a light emitting layer, and the light emitting layer comprises the compound as a host of the light emitting layer.

9. The organic light emitting device of claim 7, wherein the light emitting layer comprises a dopant, and the dopant comprises a phosphorescent dopant.

10. The organic light emitting device of claim 7, wherein the light emitting layer is a blue light emitting layer.

11. The organic light emitting device of claim 6, wherein the organic material layer comprises an electron injection layer, an electron transport layer, or an electron injection and transport layer, and the electron injection layer, the electron transport layer, or the electron injection and transport layer comprises the compound.

12. The organic light emitting device of claim 6, wherein the organic material layer comprises a hole blocking layer, and the hole blocking layer comprises the compound.
